(19) United States
(12) Patent Application Publication
(10) Pub. No.: US 2026/0146756 A1
(43) Pub. Date: May 28, 2026

(54) DATA CENTER HVAC SYSTEM WITH HYBRID THERMAL CONTROL

(71) Applicant: Tyco Fire & Security GmbH, Neuhausen am Rheinfall (CH)

(72) Inventors: Michael J. Risbeck, West Chester, OH (US); Hoa L. Wilhelm, Neenah, WI (US)

(21) Appl. No.: 19/231,273

(22) Filed: Jun. 6, 2025

Related U.S. Application Data
(63) Continuation-in-part of application No. 18/961,373, filed on Nov. 26, 2024.

(51) Int. Cl. F24F 11/63; H05K 7/20

(52) U.S. Cl. CPC F24F 11/63; H05K 7/20745; H05K 7/20836

(57) ABSTRACT

A system for rejecting heat generated within a data center with a hybrid cooling system using liquid cooling and/or air-based cooling of the computers. The system allocates an amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system. The system can allocate heat rejection capacity from the first cooling system and second cooling system differentially to CPUs and GPUs. The system may generate constraints to ensure that the CPUs and GPUs receive heat rejection capacity from an appropriate system and at an appropriate temperature. Compute tasks are allocated to advantageously generate heat that can be efficiently rejected.

### CROSS-REFERENCE TO RELATED APPLICATIONS

This application is a Continuation-in-Part of U.S. application Ser. No. 18/961,373 filed on Nov. 26, 2024, the entire contents of which is herein incorporated by reference. This application is related to U.S. Pat. No. 11,497,144 granted on Nov. 8, 2022, the entire contents of which is herein incorporated by reference.

### BACKGROUND

The present disclosure relates to HVAC control for a data center. The computers, servers, power supplies, etc. of a data center generate significant heat that must be rejected by moving the heat out of the data center. Heat can be rejected using the refrigeration cycle to provided chilled water or cooled air to the computers maintaining the temperature of the processors.

### SUMMARY

At least one embodiment of the techniques described herein relate to a controller configured to serve a cooling load of a data center facility including one or more computers in a rack group of one or more computer racks, the controller including one or more processing circuits configured to: allocate an amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system, wherein the first cooling system and the second cooling system operate in parallel to provide both the first coolant and the second coolant to the rack group; operate the first cooling system to reject the first amount of heat from the rack group into the first coolant; and operate the second cooling system to reject the second amount of heat from the rack group into the second coolant.

In some embodiments, the second cooling system includes a chiller and the first cooling system includes at least one of: a computer room air conditioner; or a computer room air handler.

In some embodiments, the chiller is configured to provide cooling to the rack group and to the first cooling system.

In some embodiments, the one or more processing circuits further configured to: obtain a load balance constraint that requires balance between (i) a heat production including the amount of heat generated by the one or more computers of the rack group and (ii) a heat rejection including the first amount of heat to be rejected from the rack group into the first coolant provided by the first cooling system and the second amount of heat to be rejected from the rack group into the second coolant provided by the second cooling system; and allocate the amount of heat generated into the first amount of heat to be rejected and the second amount of heat to be rejected using the load balance constraint.

In some embodiments, the first cooling system is of a plurality of first cooling systems, the second cooling system is of a plurality of second cooling systems, the rack group is of a plurality of rack groups, wherein the one or more processing circuits are further configured to: obtain a first indication of interconnections between the plurality of first cooling systems and the plurality of rack groups; obtain a second indication of interconnections between the plurality of second cooling systems and the plurality of rack groups; generate a plurality of load balance constraints that require for each connected rack group of the plurality of rack groups balance between (i) a respective heat production including an amount of heat generated by one or more computers of the connected rack group and (ii) a respective heat rejection including a first respective amount of heat to be rejected from the connected rack group into the first coolant provided by connected first cooling systems of the plurality of first cooling systems rack group and a second respective amount of heat rejected from the connected rack group into the second coolant provided by connected second cooling systems of the plurality of second cooling systems; and allocate the amount of heat generated by the one or more computers of each of the connected rack group into the first respective amount of heat to be rejected and the second respective amount of heat to be rejected using the plurality of load balance constraints.

In some embodiments, the amount of heat generated, the first amount of heat to be rejected, and the second amount of heat to be rejected are specific to a time instance and the controller is configured to determine values of the amount of heat generated, the first amount of heat to be rejected, and the second amount of heat to be rejected at a plurality of future time instances.

In some embodiments, the amount of heat generated at the plurality of future time instances is determined using a computer utilization ratio of the rack group and a model trained with training data including training samples including a total cooling load of the second cooling system and the first cooling system and computer utilization ratios of a plurality of rack groups including the rack group.

In some embodiments, allocating the amount of heat generated into the first amount of heat to be rejected and the second amount of heat to be rejected includes finding a solution to an optimization problem subjected to a load balance constraint that requires balance between (i) the amount of heat generated and (ii) the first amount of heat to be rejected and the second amount of heat to be rejected.

In some embodiments, the optimization problem is to minimize an objective function including at least one of: a first amount of electrical energy consumed by the first cooling system and a second amount of electrical energy consumed by the second cooling system; a first amount of water consumed by the first cooling system and a second amount of water consumed by the second cooling system; or a first amount of greenhouse gas emissions caused by operating the first cooling system and second amount of greenhouse gas emissions caused by operating the second cooling system.

In some embodiments, the one or more processing circuits are further configured to: generate a reserve capacity constraint that requires an amount of heat rejection capability be available; generate a timer constraint that requires at least one of: a currently operating equipment of the second cooling system or the first cooling system remain operating for a first period of time; or an equipment currently not operating of the second cooling system or the first cooling system remain not operating for a second period of time; generate a switching constraint that, for an equipment of the second cooling system or the first cooling system, requires at least one of: the equipment of the second cooling system or the first cooling system transitions from operating to not operating a first number of times less than a switching threshold during a third time period; or the equipment of the second cooling system or the first cooling system transitions from not operating to operating a second number of times less than the switching threshold during the third time period; and allocate the amount of heat generated into the first amount of heat to be rejected and the second amount of heat to be rejected using the reserve capacity constraint, the timer constraint, and the switching constraint.

In some embodiments, the rack group is of a plurality of rack groups, the one or more processing circuits further configured to generate a user interface including an indication of heat rejected from each rack group of the plurality of rack groups.

In some embodiments, a computer rack of the rack group includes: an immersion system, wherein computers of the computer rack are submerged in a non-conductive liquid and the second cooling system rejects heat via a heat exchange between the second coolant and the non-conductive liquid; a direct liquid system, wherein the second coolant is circulated through a heat exchanger connected to a computer of the computer rack; an indirect liquid system, wherein the second cooling system rejects heat via a heat exchange between the second coolant and a secondary fluid circulated through the heat exchanger connected to the computers of the computer rack; or a liquid to air system, wherein the second cooling system rejects heat via a water to air heat exchanger disposed in the computer rack.

At least one embodiment of the techniques described herein relate to a method to serve a cooling load of a data center facility including one or more computers in a rack group of one or more computer racks, the method including: allocating, by one or more remote servers, an amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system, wherein the first cooling system and the second cooling system operate in parallel to provide both the first coolant and the second coolant to the rack group; communicating, by the one or more remote servers, the first amount of heat to be rejected from the rack group into the first coolant provided by the first cooling system the second amount of heat to be rejected from the rack group into the second coolant provided by the second cooling system to a local controller configured to: operate the first cooling system to reject the first amount of heat from the rack group into the first coolant; and operate the second cooling system to reject the second amount of heat from the rack group into the second coolant.

In some embodiments, the second cooling system includes a chiller and the first cooling system includes at least one of: a computer room air conditioner; or a computer room air handler.

In some embodiments, the method further includes: obtaining, by the one or more remote servers, a load balance constraint that requires balance between (i) a heat production including the amount of heat generated by the one or more computers of the rack group and (ii) a heat rejection including the first amount of heat to be rejected from the rack group into the first coolant provided by the first cooling system and the second amount of heat to be rejected from the rack group into the second coolant provided by the second cooling system; and allocating, by the one or more remote servers, the amount of heat generated into the first amount of heat to be rejected and the second amount of heat to be rejected using the load balance constraint.

In some embodiments, allocating the amount of heat generated into the first amount of heat to be rejected and the second amount of heat to be rejected includes finding a solution to an optimization problem minimizing an objective function and subjected to a load balance constraint, the objective function including at least one of: a first amount of electrical energy consumed by the first cooling system and a second amount of electrical energy consumed by the second cooling system; a first amount of water consumed by the first cooling system and a second amount of water consumed by the second cooling system; or a first amount of greenhouse gas emissions caused by operating the first cooling system and second amount of greenhouse gas emissions caused by operating the second cooling system.

At least one embodiment of the techniques described herein relate to a method to serve a cooling load of a data center facility including one or more computers in a rack group of one or more computer racks, the method including: allocating an amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system, wherein the first cooling system and the second cooling system operate in parallel to provide both the first coolant and the second coolant to the rack group; causing a user interface to be generated, the user interface including an indication of at least one of the amount of heat generated, the first amount of heat to be rejected, or the second amount of heat to be rejected; operating the first cooling system to reject the first amount of heat from the rack group into the first coolant; and operating the second cooling system to reject the second amount of heat from the rack group into the second coolant.

In some embodiments, the first cooling system is of one or more first cooling systems, the second cooling system is of one or more second cooling systems, and the rack group is of a plurality of rack groups, and wherein the method further includes: obtaining a first indication of interconnections between the one or more first cooling systems and the plurality of rack groups; obtaining a second indication of interconnections between the one or more second cooling systems and the plurality of rack groups; generating a plurality of load balance constraints that require for each connected rack group of the plurality of rack groups balance between (i) a respective heat production including an amount of heat generated by one or more computers of the connected rack group and (ii) a respective heat rejection including a first respective amount of heat to be rejected from the connected rack group into the first coolant provided by connected first cooling systems of the plurality of first cooling systems rack group and a second respective amount of heat rejected from the connected rack group into the second coolant provided by connected second cooling systems of the plurality of second cooling systems; and allocating the amount of heat generated by the one or more computers of each connected rack group into the first respective amount of heat to be rejected and the second respective amount of heat to be rejected using the plurality of load balance constraints.

In some embodiments, the user interface further including at least one of: an indication of the amount of heat generated by the one or more computers of each connected rack group; an indication of a first total amount of heat rejected by the one or more first cooling systems; or an indication of a second total amount of heat rejected by the one or more second cooling systems.

In some embodiments, allocating the amount of heat generated into the first amount of heat to be rejected and the second amount of heat to be rejected includes finding a solution to an optimization problem minimizing an objective function and subjected to a load balance constraint that requires balance between (i) the amount of heat generated and (ii) the first amount of heat to be rejected and the second amount of heat to be rejected at a plurality of future time instances, the objective function including at least one of: a first amount of electrical energy consumed by the first cooling system and a second amount of electrical energy consumed by the second cooling system; a first amount of water consumed by the first cooling system and a second amount of water consumed by the second cooling system; or a first amount of greenhouse gas emissions caused by operating the first cooling system and second amount of greenhouse gas emissions caused by operating the second cooling system.

This summary is illustrative only and should not be regarded as limiting.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a schematic diagram of a central plant having a plurality of subplants including a heater subplant, heat recovery chiller subplant, a chiller subplant, a hot thermal energy storage subplant, and a cold thermal energy storage subplant, according to an exemplary embodiment.

FIG. 2 is a block diagram illustrating a central plant system including a central plant controller that may be used to control the central plant of FIG. 1, according to an exemplary embodiment.

FIG. 3 is a block diagram illustrating a portion of central plant system of FIG. 2 in greater detail, showing a load/rate prediction circuit, a high level optimization circuit, a low level optimization circuit, a building automation system, and central plant equipment, according to an exemplary embodiment.

FIG. 4, a block diagram illustrating the high level optimization circuit of FIG. 3 in greater detail, according to an exemplary embodiment.

FIG. 5A is a subplant curve illustrating a relationship between the resource consumption of a subplant and the subplant load and which may be used by the high level optimization circuit of FIG. 4 to optimize the performance of the central plant of FIG. 1, according to an exemplary embodiment.

FIG. 5B is another subplant curve illustrating a relationship between the resource consumption of a subplant and the subplant load and which may be used by the high level optimization circuit of FIG. 4 to optimize the performance of the central plant of FIG. 1, according to an exemplary embodiment.

FIG. 6 is a non-convex and nonlinear subplant curve that may be generated from experimental data or by combining equipment curves for individual devices of the central plant, according to an exemplary embodiment.

FIG. 7 is a linearized subplant curve that may be generated from the subplant curve of FIG. 6 by converting the non-convex and nonlinear subplant curve into piecewise linear segments, according to an exemplary embodiment.

FIG. 8 is a graph illustrating a set of subplant curves that may be generated by the high level optimization circuit of FIG. 3 based on experimental data from a low level optimization circuit for multiple different environmental conditions, according to an exemplary embodiment.

FIG. 9 is a block diagram of a planning system that incorporates the high level optimization circuit of FIG. 3, according to an exemplary embodiment.

FIG. 10 is a drawing illustrating the operation of the planning system of FIG. 9, according to an exemplary embodiment.

FIG. 11 is a flowchart of a process for optimizing cost in a central plant that may be performed by the central plant controller of FIG. 2 or the planning system of FIG. 9, according to an exemplary embodiment.

FIG. 12 is a schematic illustration of a liquid cooling system for a data center, according to an exemplary embodiment.

FIG. 13 is an illustration of a heat map for a data center and associated approaches for managing the heat equilibrium, according to an exemplary embodiment.

FIG. 14 is a schematic illustration of a data center air cooling system, according to an exemplary embodiment.

FIG. 15 is a schematic drawing of a data center cooling system including hybrid computer racks cooled by both an air cooling system and a water cooling system, according to an exemplary embodiment.

FIG. 16 is a block diagram of a data center cooling control system disposed on a remote server and on an edge controller, according to an exemplary embodiment.

FIG. 17 is a block diagram of the heat allocator of FIG. 16, according to an exemplary embodiment.

FIG. 18 is a flow diagram for operating an air cooling system and a water cooling system according to allocations of heat generated by computers, according to an exemplary embodiment.

FIG. 19 is a flow diagram for allocating heat generation between air and water cooling systems using load balance constraints, according to an exemplary embodiment.

FIG. 20 is a flow diagram for allocating heat generation according to alternative heat generations that ensure reserve capacity, according to an exemplary embodiment.

FIG. 21 is a flow diagram for operating an air cooling system and a water cooling system according to allocations of heat generated by computers using an edge controller, according to an exemplary embodiment.

FIG. 22 is a flow diagram for operating an air cooling system and a water cooling system according to allocations of heat generated by computers and generating a user interface indicating the allocations, according to an exemplary embodiment.

### DETAILED DESCRIPTION

### Overview

Referring generally to the FIGURES, systems and methods for controlling HVAC equipment to heat or cool a data room (data center) are shown, according to exemplary embodiments. In some embodiments, systems and methods for optimizing control of a central plant and/or an HVAC system are shown, according to an exemplary embodiment. The systems and methods of the present disclosure are particularly suited for optimizing a central plant and/or an HVAC system that serves a data center, i.e., a space of a building that stores data center equipment (e.g., servers, computers, processors, routers, network components, etc.), in some embodiments. Data center equipment generates heat via electrical resistance while operating to execute various computing functions. This heat contributes to a disturbance load on the data center, thereby affecting the behavior of the central plant and/or HVAC system. The systems and methods described herein allow for coordination between a central plant and/or HVAC system and the data center equipment to improve optimization of the operation of both the central plant/HVAC system and the data center equipment, in some embodiments. For example, predictions of the heat generated by the data center equipment may be used in high level optimization, low level optimization, and/or model predictive control of a central plant and/or HVAC system. In some embodiments, a data center HVAC system which is not a central plant operates to heat or cool the data center. For example, a dedicated HVAC unit or series of units could provide heating and cooling for the data center.

A central plant is one type of system that could be used to heat or cool a data center. A central plant may include various types of equipment configured to serve the thermal energy loads of a building or campus (i.e., a system of buildings). For example, a central plant may include heaters, chillers, heat recovery chillers, cooling towers, or other types of equipment configured to provide heating or cooling for the building or campus. The central plant equipment may be divided into various groups configured to perform a particular function. Such groups of central plant equipment are referred to herein as subplants. For example, a central plant may include a heater subplant, a chiller subplant, a heat recovery chiller subplant, a cold thermal energy storage subplant, a hot thermal energy storage subplant, etc. The subplants may consume resources from one or more utilities (e.g., water, electricity, natural gas, etc.) to serve the energy loads of the building or campus. Optimizing the central plant may include operating the various subplants in such a way that results in a minimum monetary cost to serve the building energy loads.

In some embodiments, the central plant optimization is a cascaded optimization process including a high level optimization and a low level optimization. The high level optimization may determine an optimal distribution of energy loads across the various subplants. For example, the high level optimization may determine a thermal energy load to be produced by each of the subplants at each time element in an optimization period. In some embodiments, the high level optimization includes optimizing a high level cost function that expresses the monetary cost of operating the subplants as a function of the resources consumed by the subplants at each time element of the optimization period. The low level optimization may use the optimal load distribution determined by the high level optimization to determine optimal operating statuses for individual devices within each subplant. Optimal operating statuses may include, for example, on/off states and/or operating setpoints for individual devices of each subplant. The low level optimization may include optimizing a low level cost function that expresses the energy consumption of a subplant as a function of the on/off states and/or operating setpoints for the individual devices of the subplant.

In some embodiments, high level optimization systems and methods are provided for controlling HVAC equipment. A high level optimization circuit may perform the high level optimization. In various embodiments, the high level optimization circuit may be a component of a central plant controller configured for real-time control of a physical plant or a component of a planning tool configured to optimize a simulated plant (e.g., for planning or design purposes).

In some embodiments, the high level optimization circuit uses a linear programming framework to perform the high level optimization. Advantageously, linear programming can efficiently handle complex optimization scenarios and can optimize over a relatively long optimization period (e.g., days, weeks, years, etc.) in a relatively short timeframe (e.g., seconds, milliseconds, etc.). In other embodiments, the high level optimization circuit may use any of a variety of other optimization frameworks (e.g., quadratic programming, linear-fractional programming, nonlinear programming, combinatorial algorithms, etc.).

An objective function defining the high level optimization problem can be expressed in the linear programming framework as:

$${arg min}_{x} {c}^{T} x ; subject to Ax \leq b , Hx = g$$

where c is a cost vector, x is a decision matrix, A and b are a matrix and vector (respectively) which describe inequality constraints on the variables in the decision matrix x, and H and g are a matrix and vector (respectively) which describe equality constraints on the variables in the decision matrix x. The variables in the decision matrix x may include the subplant loads assigned to the various subplants and/or an amount of resource consumption by the subplants at each time element in the optimization period. The high level optimization circuit may define the cost vector c and the optimization constraints (e.g., the matrices A and H and the vectors b and g) and solve the optimization problem to determine optimal subplant load values for the variables in the decision matrix x.

The high level optimization circuit may receive, as an input, predicted or planned energy loads for the building or campus for each of the time elements in the optimization period. The high level optimization circuit may use the predicted or planned loads to formulate the constraints on the high level optimization problem (e.g., to define the matrices A and H and the vectors b and g). The high level optimization circuit may also receive utility rates (e.g., energy prices, water prices, demand charges, etc.) defining the cost of each resource consumed by the central plant to serve the energy loads. The utility rates may be time-variable rates (e.g., defining different rates at different times) and may include demand charges for various time periods. The high level optimization circuit may use the utility rates to define the cost vector c.

The high level optimization circuit may receive or generate subplant curves for each of the subplants. A subplant curve defines the resource consumption of a subplant as a function of the load produced by the subplant. The subplant curves may be generated by a low level optimization circuit or by the high level optimization circuit based on operating data points received from the low level optimization circuit. The high level optimization circuit may use the subplant curves to constrain the resource consumption of each subplant to a value along the corresponding subplant curve (e.g., based on the load produced by the subplant). For example, the high level optimization circuit may use the subplant curves to define the optimization constraints (e.g., the matrices A and H and the vectors b and g) on the high level optimization problem.

In some embodiments, the high level optimization circuit is configured to incorporate a demand charge into the high level optimization process. The demand charge is an additional charge imposed by some utility providers based on the maximum rate of resource consumption during an applicable demand charge period. For example, an electric demand charge may be provided as a cost c_{demand} per unit power and may be multiplied by the peak electricity usage max (P_{elec,k}) during a demand charge period to determine the demand charge. Conventional systems have been unable to incorporate a demand charge into a linear optimization framework due to the nonlinear max( ) function used to calculate the demand charge.

Advantageously, the high level optimization circuit of the present disclosure may be configured to incorporate the demand charge into the linear optimization framework by modifying the decision matrix x, the cost vector c, and/or the A matrix and the b vector which describe the inequality constraints. For example, the high level optimization circuit may modify the decision matrix x by adding a new decision variable xₚₑₐₖ representing the peak power consumption within the optimization period. The high level optimization circuit may modify the cost vector c with the demand charge rate c_{demand} such that the demand charge rate c_{demand} is multiplied by the peak power consumption xₚₑₐₖ. The high level optimization circuit may generate and/or impose constraints to ensure that the peak power consumption xₚₑₐₖ is greater than or equal to the electric demand for each time step in the demand charge period and greater than or equal to its previous value during the demand charge period.

In some embodiments, the high level optimization circuit is configured to incorporate a load change penalty into the high level optimization process. The load change penalty may represent an increased cost (e.g., equipment degradation, etc.) resulting from a rapid change in the load assigned to a subplant. The high level optimization circuit may incorporate the load change penalty by modifying the decision matrix x, the cost vector c, and/or the optimization constraints. For example, the high level optimization circuit may modify the decision matrix x by adding load change variables δ for each subplant. The load change variables may represent the change in subplant load for each subplant from one time element to the next. The high level optimization circuit may modify the cost vector c to add a cost associated with changing the subplant loads. In some embodiments, the high level optimization circuit adds constraints that constrain the load change variables δ to the corresponding change in the subplant load. These and other enhancements to the high level optimization process may be incorporated into the linear optimization framework, as described in greater detail below.

In some embodiments, central plants are used to cool data centers. The central plant may provide chilled water to racks of computers (e.g., for direct-liquid cooling of processing components) or they may provide chilled water to computer room air handlers (CRAHs) so that cooled air can be delivered to the rack. A hybrid computer rack may use both chilled water and/or cooled air to cool the computers included in the rack. In some embodiments, the cooling can be provided simultaneously by both air and water.

### Central Plant Optimization

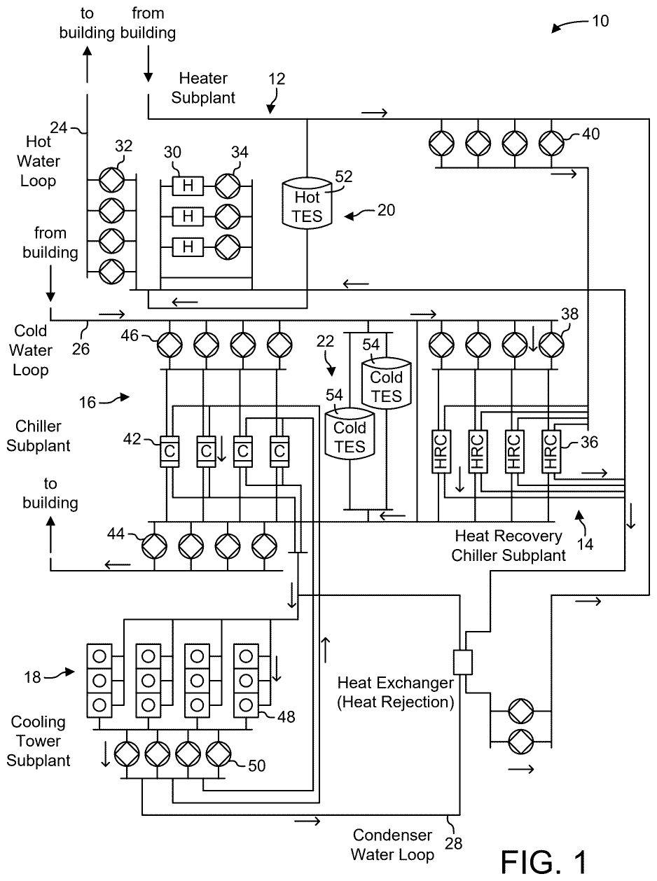

Referring now to FIG. 1, a diagram of a central plant 10 is shown, according to an exemplary embodiment. The central plant 10 is one type of system that may be used to heat or cool a data center. In some embodiments, an HVAC system is used instead or in addition to the central plant 10. Central plant 10 is shown to include a plurality of subplants including a heater subplant 12, a heat recovery chiller subplant 14, a chiller subplant 16, a cooling tower subplant 18, a hot thermal energy storage (TES) subplant 20, and a cold thermal energy storage (TES) subplant 22. Subplants 12-22 consume resources (e.g., water, natural gas, electricity, etc.) from utilities to serve the thermal energy loads (e.g., hot water, cold water, heating, cooling, etc.) of a building or campus. For example, heater subplant 12 may be configured to heat water in a hot water loop 24 that circulates the hot water between central plant 10 and a building (not shown). Chiller subplant 16 may be configured to chill water in a cold water loop 26 that circulates the cold water between central plant 10 and the building. Heat recovery chiller subplant 14 may be configured to transfer heat from cold water loop 26 to hot water loop 24 to provide additional heating for the hot water and additional cooling for the cold water. Condenser water loop 28 may absorb heat from the cold water in chiller subplant 16 and reject the absorbed heat in cooling tower subplant 18 or transfer the absorbed heat to hot water loop 24. Hot TES subplant 20 and cold TES subplant 22 store hot and cold thermal energy, respectively, for subsequent use.

Hot water loop 24 and cold water loop 26 may deliver the heated and/or chilled water to air handlers located on the rooftop of a building or to individual floors or zones of the building. The air handlers push air past heat exchangers (e.g., heating coils or cooling coils) through which the water flows to provide heating or cooling for the air. The heated or cooled air may be delivered to individual zones of the building to serve the thermal energy loads of the building. The water then returns to central plant 10 to receive further heating or cooling in subsystems 12-22.

Although central plant 10 is shown and described as heating and cooling water for circulation to a building, it is understood that any other type of working fluid (e.g., glycol, CO2, etc.) may be used in place of or in addition to water to serve the thermal energy loads. In other embodiments, central plant 10 may provide heating and/or cooling directly to the building or campus (e.g., at a data center) without requiring an intermediate heat transfer fluid. Central plant 10 may be physically separate from a building served by subplants 12-22 or physically integrated with the building (e.g., located within the building).

Each of subplants 12-22 may include a variety of equipment configured to facilitate the functions of the subplant. For example, heater subplant 12 is shown to include a plurality of heating elements 30 (e.g., boilers, electric heaters, etc.) configured to add heat to the hot water in hot water loop 24. Heater subplant 12 is also shown to include several pumps 32 and 34 configured to circulate the hot water in hot water loop 24 and to control the flow rate of the hot water through individual heating elements 30. Heat recovery chiller subplant 14 is shown to include a plurality of heat recovery heat exchangers 36 (e.g., refrigeration circuits) configured to transfer heat from cold water loop 26 to hot water loop 24. Heat recovery chiller subplant 14 is also shown to include several pumps 38 and 40 configured to circulate the hot water and/or cold water through heat recovery heat exchangers 36 and to control the flow rate of the water through individual heat recovery heat exchangers 36.

Chiller subplant 16 is shown to include a plurality of chillers 42 configured to remove heat from the cold water in cold water loop 26. Chiller subplant 16 is also shown to include several pumps 44 and 46 configured to circulate the cold water in cold water loop 26 and to control the flow rate of the cold water through individual chillers 42. Cooling tower subplant 18 is shown to include a plurality of cooling towers 48 configured to remove heat from the condenser water in condenser water loop 28. Cooling tower subplant 18 is also shown to include several pumps 50 configured to circulate the condenser water in condenser water loop 28 and to control the flow rate of the condenser water through individual cooling towers 48.

Hot TES subplant 20 is shown to include a hot TES tank 52 configured to store the hot water for later use. Hot TES subplant 20 may also include one or more pumps or valves configured to control the flow rate of the hot water into or out of hot TES tank 52. Cold TES subplant 22 is shown to include cold TES tanks 54 configured to store the cold water for later use. Cold TES subplant 22 may also include one or more pumps or valves configured to control the flow rate of the cold water into or out of cold TES tanks 54. In some embodiments, one or more of the pumps in central plant 10 (e.g., pumps 32, 34, 38, 40, 44, 46, and/or 50) or pipelines in central plant 10 includes an isolation valve associated therewith. In various embodiments, isolation valves may be integrated with the pumps or positioned upstream or downstream of the pumps to control the fluid flows in central plant 10. In other embodiments, more, fewer, or different types of devices may be included in central plant 10.

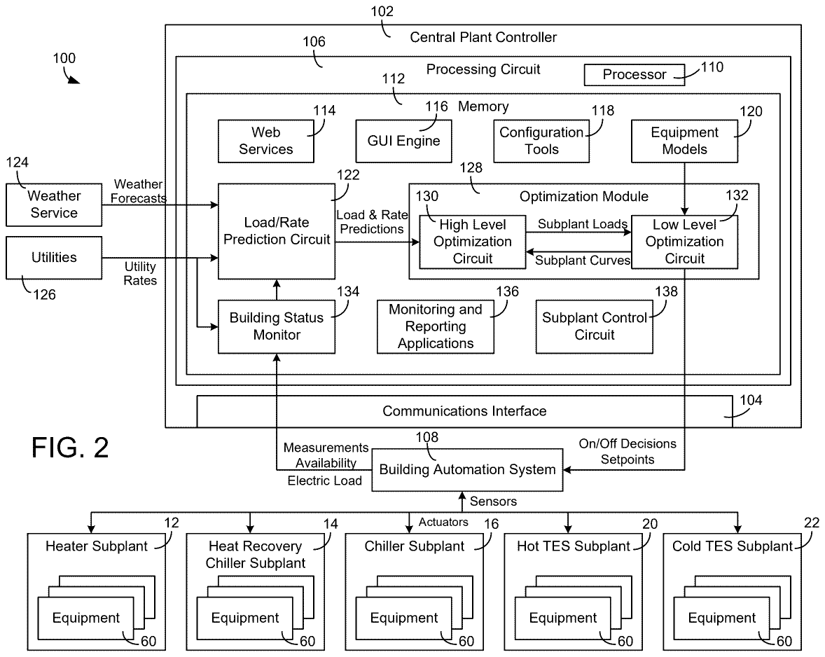

Referring now to FIG. 2, a block diagram illustrating a central plant system 100 is shown, according to an exemplary embodiment. System 100 is shown to include a central plant controller 102, a building automation system 108, and a plurality of subplants 12-22. Subplants 12-22 may be the same as previously described with reference to FIG. 1. For example, subplants 12-22 are shown to include a heater subplant 12, a heat recovery chiller subplant 14, a chiller subplant 16, a hot TES subplant 20, and a cold TES subplant 22.

Each of subplants 12-22 is shown to include equipment 60 that can be controlled by central plant controller 102 and/or building automation system 108 to optimize the performance of central plant 10. Equipment 60 may include, for example, heating devices 30, chillers 42, heat recovery heat exchangers 36, cooling towers 48, thermal energy storage devices 52, 54, pumps 32, 44, 50, valves 34, 38, 46, and/or other devices of subplants 12-22. Individual devices of equipment 60 can be turned on or off to adjust the thermal energy load served by each of subplants 12-22. In some embodiments, individual devices of equipment 60 can be operated at variable capacities (e.g., operating a chiller at 10% capacity or 60% capacity) according to an operating setpoint received from central plant controller 102.

In some embodiments, one or more of subplants 12-22 includes a subplant level controller configured to control the equipment 60 of the corresponding subplant. For example, central plant controller 102 may determine an on/off configuration and global operating setpoints for equipment 60. In response to the on/off configuration and received global operating setpoints, the subplant controllers may turn individual devices of equipment 60 on or off, and implement specific operating setpoints (e.g., damper position, vane position, fan speed, pump speed, etc.) to reach or maintain the global operating setpoints.

Building automation system (BAS) 108 may be configured to monitor conditions within a controlled building or building zone. For example, BAS 108 may receive input from various sensors (e.g., temperature sensors, humidity sensors, airflow sensors, voltage sensors, etc.) distributed throughout the building and may report building conditions to central plant controller 102. Building conditions may include, for example, a temperature of the building or a zone of the building, a power consumption (e.g., electric load) of the building, a state of one or more actuators configured to affect a controlled state within the building, or other types of information relating to the controlled building. BAS 108 may operate subplants 12-22 to affect the monitored conditions within the building and to serve the thermal energy loads of the building.

BAS 108 may receive control signals from central plant controller 102 specifying on/off states and/or setpoints for equipment 60. BAS 108 may control equipment 60 (e.g., via actuators, power relays, etc.) in accordance with the control signals provided by central plant controller 102. For example, BAS 108 may operate equipment 60 using closed loop control to achieve the setpoints specified by central plant controller 102. In various embodiments, BAS 108 may be combined with central plant controller 102 or may be part of a separate building management system. According to an exemplary embodiment, BAS 108 is a METASYS® brand building management system, as sold by Johnson Controls, Inc.

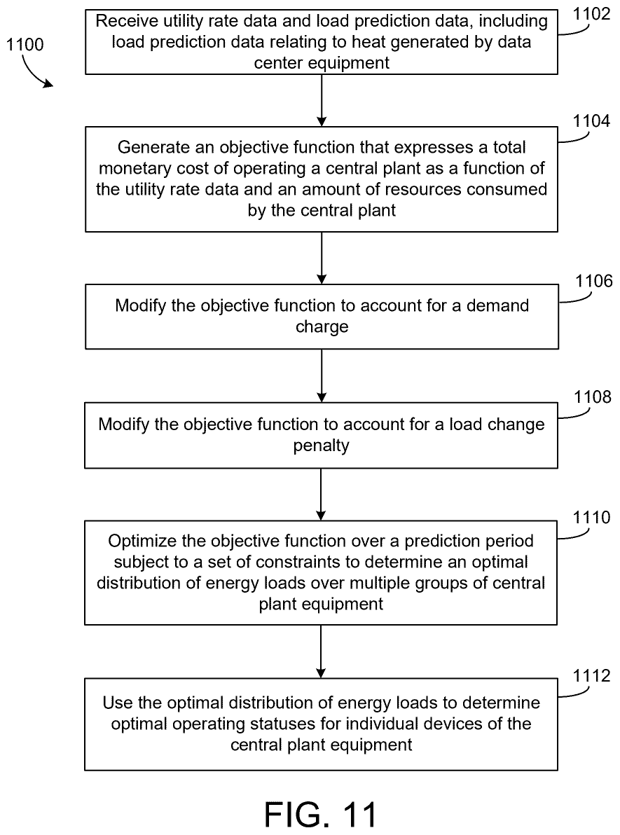

Central plant controller 102 may monitor the status of the controlled building using information received from BAS 108. Central plant controller 102 may be configured to predict the thermal energy loads (e.g., heating loads, cooling loads, etc.) of the building for plurality of time steps in a prediction window (e.g., using weather forecasts from a weather service). Central plant controller 102 may generate on/off decisions and/or setpoints for equipment 60 to minimize the cost of energy consumed by subplants 12-22 to serve the predicted heating and/or cooling loads for the duration of the prediction window. Central plant controller 102 may be configured to carry out process 1100 (FIG. 11) and other processes described herein. According to an exemplary embodiment, central plant controller 102 is integrated within a single computer (e.g., one server, one housing, etc.). In various other exemplary embodiments, central plant controller 102 can be distributed across multiple servers or computers (e.g., that can exist in distributed locations). In another exemplary embodiment, central plant controller 102 may integrated with a smart building manager that manages multiple building systems and/or combined with BAS 108.

Central plant controller 102 is shown to include a communications interface 104 and a processing circuit 106. Communications interface 104 may include wired or wireless interfaces (e.g., jacks, antennas, transmitters, receivers, transceivers, wire terminals, etc.) for conducting data communications with various systems, devices, or networks. For example, communications interface 104 may include an Ethernet card and port for sending and receiving data via an Ethernet-based communications network and/or a Wi-Fi transceiver for communicating via a wireless communications network. Communications interface 104 may be configured to communicate via local area networks or wide area networks (e.g., the Internet, a building WAN, etc.) and may use a variety of communications protocols (e.g., BACnet, IP, LON, etc.).

Communications interface 104 may be a network interface configured to facilitate electronic data communications between central plant controller 102 and various external systems or devices (e.g., BAS 108, subplants 12-22, etc.). For example, central plant controller 102 may receive information from BAS 108 indicating one or more measured states of the controlled building (e.g., temperature, humidity, electric loads, etc.) and one or more states of subplants 12-22 (e.g., equipment status, power consumption, equipment availability, etc.). Communications interface 104 may receive inputs from BAS 108 and/or subplants 12-22 and may provide operating parameters (e.g., on/off decisions, setpoints, etc.) to subplants 12-22 via BAS 108. The operating parameters may cause subplants 12-22 to activate, deactivate, or adjust a setpoint for various devices of equipment 60.

Still referring to FIG. 2, processing circuit 106 is shown to include a processor 110 and memory 112. Processor 110 may be a general purpose or specific purpose processor, an application specific integrated circuit (ASIC), one or more field programmable gate arrays (FPGAs), a group of processing components, or other suitable processing components. Processor 110 may be configured to execute computer code or instructions stored in memory 112 or received from other computer readable media (e.g., CDROM, network storage, a remote server, etc.).

Memory 112 may include one or more devices (e.g., memory units, memory devices, storage devices, etc.) for storing data and/or computer code for completing and/or facilitating the various processes described in the present disclosure. Memory 112 may include random access memory (RAM), read-only memory (ROM), hard drive storage, temporary storage, non-volatile memory, flash memory, optical memory, or any other suitable memory for storing software objects and/or computer instructions. Memory 112 may include database components, object code components, script components, or any other type of information structure for supporting the various activities and information structures described in the present disclosure. Memory 112 may be communicably connected to processor 110 via processing circuit 106 and may include computer code for executing (e.g., by processor 106) one or more processes described herein.

Still referring to FIG. 2, memory 112 is shown to include a building status monitor 134. Central plant controller 102 may receive data regarding the overall building or building space to be heated or cooled with central plant 10 via building status monitor 134. In an exemplary embodiment, building status monitor 134 may include a graphical user interface component configured to provide graphical user interfaces to a user for selecting building requirements (e.g., overall temperature parameters, selecting schedules for the building, selecting different temperature levels for different building zones, etc.).

Central plant controller 102 may determine on/off configurations and operating setpoints to satisfy the building requirements received from building status monitor 134. In some embodiments, building status monitor 134 receives, collects, stores, and/or transmits cooling load requirements, building temperature setpoints, occupancy data, weather data, energy data, schedule data, and other building parameters. In some embodiments, building status monitor 134 stores data regarding energy costs, such as pricing information available from utilities 126 (energy charge, demand charge, etc.).

Still referring to FIG. 2, memory 112 is shown to include a load/rate prediction circuit 122. Load/rate prediction circuit 122 may be configured to predict the thermal energy loads ( [symbol] ) of the building or campus for each time step k (e.g., k=1 . . . n) of an optimization period. Load/rate prediction circuit 122 is shown receiving weather forecasts from a weather service 124. In some embodiments, load/rate prediction circuit 122 predicts the thermal energy loads [symbol] as a function of the weather forecasts. In some embodiments, load/rate prediction circuit 122 uses feedback from BAS 108 to predict loads [symbol] . Feedback from BAS 108 may include various types of sensory inputs (e.g., temperature, flow, humidity, enthalpy, etc.) or other data relating to the controlled building (e.g., inputs from a HVAC system, a lighting control system, a security system, a water system, etc.).

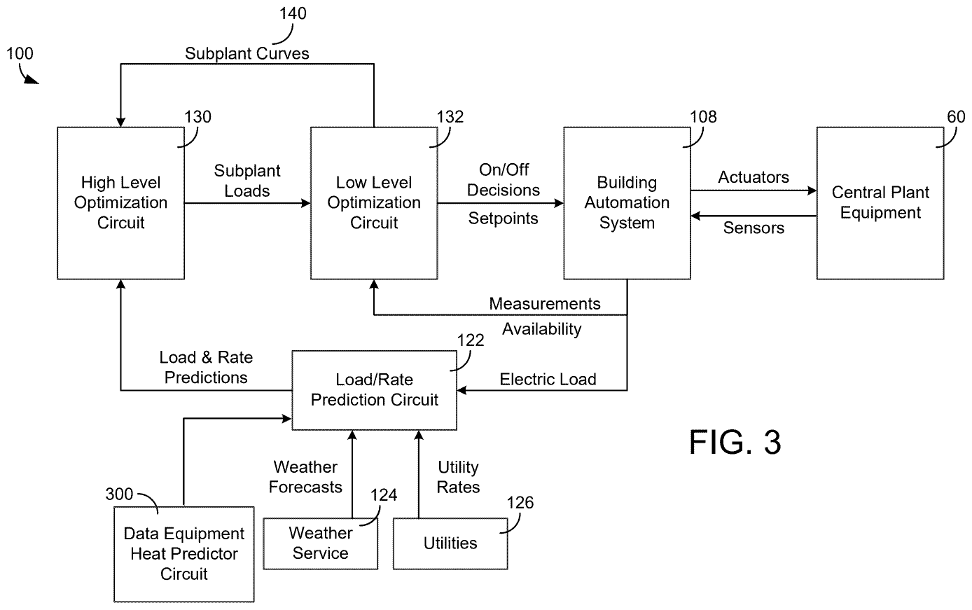

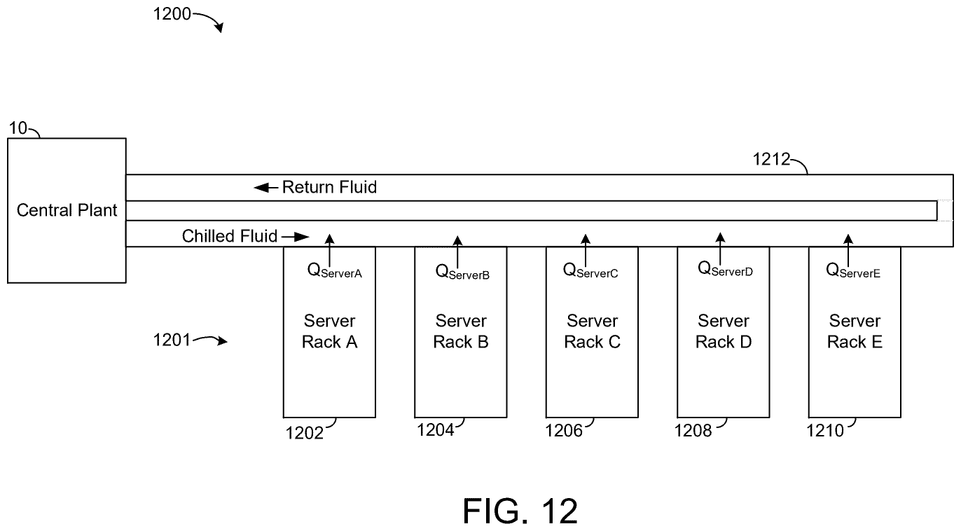

In an embodiment where the central plant and/or an HVAC system serves a data center, the load/rate prediction circuit 122 receives a prediction of heat generated by data center equipment in the data center from a data equipment heat predictor circuit 300 (shown in FIG. 3). The data equipment heat predictor circuit 300 is described in more detail with reference to FIG. 12. Because a significant amount of heat may be generated by the operation of data center equipment in a data center, the heat from the data center equipment may substantially alter the load on the HVAC system and/or central plant that is configured to maintain the data center at or around a desired temperature setpoint. Accordingly, data equipment heat predictor circuit 300 is configured to incorporate the predicted heat generated by the data center equipment from the data equipment heat predictor circuit 300 in generating the thermal energy loads ( [symbol] ) of the building or campus for each time step k of the optimization period. The predicted heat generated by the data center equipment from the data equipment heat predictor circuit 300 may thereby be propagated through and influence the operation of the central plant controller 102 including the high level optimization circuit 130 and the low level optimization circuit 132 to cause the subplants 12-22 to be controlled based in part on the predicted heat generated by the data center equipment.

In some embodiments, load/rate prediction circuit 122 receives a measured electric load and/or previous measured load data from BAS 108 (e.g., via building status monitor 134). Load/rate prediction circuit 122 may predict loads [symbol] as a function of a given weather forecast (\hat{φ}_{w}), a day type (day), the time of day (t), and previous measured load data (Yₖ₋₁). Such a relationship is expressed in the following equation:

$${\hat{ℓ}}_{k} = f ( {\hat{ϕ}}_{w} , day , t \vert {Y}_{k - 1} )$$

In some embodiments, load/rate prediction circuit 122 uses a deterministic plus stochastic model trained from historical load data to predict loads [symbol] . Load/rate prediction circuit 122 may use any of a variety of prediction methods to predict loads [symbol] (e.g., linear regression for the deterministic portion and an AR model for the stochastic portion). Load/rate prediction circuit 122 may predict one or more different types of loads for the building or campus. For example, load/rate prediction circuit 122 may predict a hot water load [symbol] and a cold water load [symbol] for each time step k within the prediction window.

Load/rate prediction circuit 122 is shown receiving utility rates from utilities 126. Utility rates may indicate a cost or price per unit of a resource (e.g., electricity, natural gas, water, etc.) provided by utilities 126 at each time step k in the prediction window. In some embodiments, the utility rates are time-variable rates. For example, the price of electricity may be higher at certain times of day or days of the week (e.g., during high demand periods) and lower at other times of day or days of the week (e.g., during low demand periods). The utility rates may define various time periods and a cost per unit of a resource during each time period. Utility rates may be actual rates received from utilities 126 or predicted utility rates estimated by load/rate prediction circuit 122.

In some embodiments, the utility rates include demand charges for one or more resources provided by utilities 126. A demand charge may define a separate cost imposed by utilities 126 based on the maximum usage of a particular resource (e.g., maximum energy consumption) during a demand charge period. The utility rates may define various demand charge periods and one or more demand charges associated with each demand charge period. In some instances, demand charge periods may overlap partially or completely with each other and/or with the prediction window. Advantageously, optimization circuit 128 may be configured to account for demand charges in the high level optimization process performed by high level optimization circuit 130. Utilities 126 may be defined by time-variable (e.g., hourly) prices, a maximum service level (e.g., a maximum rate of consumption allowed by the physical infrastructure or by contract) and, in the case of electricity, a demand charge or a charge for the peak rate of consumption within a certain period.

Load/rate prediction circuit 122 may store the predicted loads [symbol] and the utility rates in memory 112 and/or provide the predicted loads [symbol] and the utility rates to optimization circuit 128. Optimization circuit 128 may use the predicted loads [symbol] and the utility rates to determine an optimal load distribution for subplants 12-22 and to generate on/off decisions and setpoints for equipment 60.

Still referring to FIG. 2, memory 112 is shown to include an optimization circuit 128. Optimization circuit 128 may perform a cascaded optimization process to optimize the performance of central plant 10. For example, optimization circuit 128 is shown to include a high level optimization circuit 130 and a low level optimization circuit 132. High level optimization circuit 130 may control an outer (e.g., subplant level) loop of the cascaded optimization. High level optimization circuit 130 may determine an optimal distribution of thermal energy loads across subplants 12-22 for each time step in the prediction window in order to optimize (e.g., minimize) the cost of energy consumed by subplants 12-22. Low level optimization circuit 132 may control an inner (e.g., equipment level) loop of the cascaded optimization. Low level optimization circuit 132 may determine how to best run each subplant at the load setpoint determined by high level optimization circuit 130. For example, low level optimization circuit 132 may determine on/off states and/or operating setpoints for various devices of equipment 60 in order to optimize (e.g., minimize) the energy consumption of each subplant while meeting the thermal energy load setpoint for the subplant. The cascaded optimization process is described in greater detail with reference to FIG. 3.

Still referring to FIG. 2, memory 112 is shown to include a subplant control circuit 138. Subplant control circuit 138 may store historical data regarding past operating statuses, past operating setpoints, and instructions for calculating and/or implementing control parameters for subplants 12-22. Subplant control circuit 138 may also receive, store, and/or transmit data regarding the conditions of individual devices of equipment 60, such as operating efficiency, equipment degradation, a date since last service, a lifespan parameter, a condition grade, or other device-specific data. Subplant control circuit 138 may receive data from subplants 12-22 and/or BAS 108 via communications interface 104. Subplant control circuit 138 may also receive and store on/off statuses and operating setpoints from low level optimization circuit 132.

Data and processing results from optimization circuit 128, subplant control circuit 138, or other circuits of central plant controller 102 may be accessed by (or pushed to) monitoring and reporting applications 136. Monitoring and reporting applications 136 may be configured to generate real time “system health” dashboards that can be viewed and navigated by a user (e.g., a central plant engineer). For example, monitoring and reporting applications 136 may include a web-based monitoring application with several graphical user interface (GUI) elements (e.g., widgets, dashboard controls, windows, etc.) for displaying key performance indicators (KPI) or other information to users of a GUI. In addition, the GUI elements may summarize relative energy use and intensity across central plants in different buildings (real or modeled), different campuses, or the like. Other GUI elements or reports may be generated and shown based on available data that allow users to assess performance across one or more central plants from one screen. The user interface or report (or underlying data engine) may be configured to aggregate and categorize operating conditions by building, building type, equipment type, and the like. The GUI elements may include charts or histograms that allow the user to visually analyze the operating parameters and power consumption for the devices of the central plant.

Still referring to FIG. 2, central plant controller 102 may include one or more GUI servers, web services 114, or GUI engines 116 to support monitoring and reporting applications 136. In various embodiments, applications 136, web services 114, and GUI engine 116 may be provided as separate components outside of central plant controller 102 (e.g., as part of a smart building manager). Central plant controller 102 may be configured to maintain detailed historical databases (e.g., relational databases, XML databases, etc.) of relevant data and includes computer code circuits that continuously, frequently, or infrequently query, aggregate, transform, search, or otherwise process the data maintained in the detailed databases. Central plant controller 102 may be configured to provide the results of any such processing to other databases, tables, XML files, or other data structures for further querying, calculation, or access by, for example, external monitoring and reporting applications.

Central plant controller 102 is shown to include configuration tools 118. Configuration tools 118 can allow a user to define (e.g., via graphical user interfaces, via prompt-driven “wizards,” etc.) how central plant controller 102 should react to changing conditions in the central plant subsystems. In an exemplary embodiment, configuration tools 118 allow a user to build and store condition-response scenarios that can cross multiple central plant devices, multiple building systems, and multiple enterprise control applications (e.g., work order management system applications, entity resource planning applications, etc.). For example, configuration tools 118 can provide the user with the ability to combine data (e.g., from subsystems, from event histories) using a variety of conditional logic. In varying exemplary embodiments, the conditional logic can range from simple logical operators between conditions (e.g., AND, OR, XOR, etc.) to pseudo-code constructs or complex programming language functions (allowing for more complex interactions, conditional statements, loops, etc.). Configuration tools 118 can present user interfaces for building such conditional logic. The user interfaces may allow users to define policies and responses graphically. In some embodiments, the user interfaces may allow a user to select a pre-stored or pre-constructed policy and adapt it or enable it for use with their system.

Referring now to FIG. 3, a block diagram illustrating a portion of central plant system 100 in greater detail is shown, according to an exemplary embodiment. FIG. 3 illustrates the cascaded optimization process performed by optimization circuit 128 to optimize the performance of central plant 10. In the cascaded optimization process, high level optimization circuit 130 performs a subplant level optimization that determines an optimal distribution of thermal energy loads across subplants 12-22 for each time step in the prediction window in order to minimize the cost of energy consumed by subplants 12-22. Low level optimization circuit 132 performs an equipment level optimization that determines how to best run each subplant at the subplant load setpoint determined by high level optimization circuit 130. For example, low level optimization circuit 132 may determine on/off states and/or operating setpoints for various devices of equipment 60 in order to optimize the energy consumption of each subplant while meeting the thermal energy load setpoint for the subplant.

One advantage of the cascaded optimization process performed by optimization circuit 128 is the optimal use of computational time. For example, the subplant level optimization performed by high level optimization circuit 130 may use a relatively long time horizon due to the operation of the thermal energy storage. However, the equipment level optimization performed by low level optimization circuit 132 may use a much shorter time horizon or no time horizon at all since the low level system dynamics are relatively fast (compared to the dynamics of the thermal energy storage) and the low level control of equipment 60 may be handled by BAS 108. Such an optimal use of computational time makes it possible for optimization circuit 128 to perform the central plant optimization in a short amount of time, allowing for real-time predictive control. For example, the short computational time enables optimization circuit 128 to be implemented in a real-time planning tool with interactive feedback.

Another advantage of the cascaded optimization performed by optimization circuit 128 is that the central plant optimization problem can be split into two cascaded subproblems. The cascaded configuration provides a layer of abstraction that allows high level optimization circuit 130 to distribute the thermal energy loads across subplants 12-22 without requiring high level optimization circuit 130 to know or use any details regarding the particular equipment configuration within each subplant. The interconnections between equipment 60 within each subplant may be hidden from high level optimization circuit 130 and handled by low level optimization circuit 132. For purposes of the subplant level optimization performed by high level optimization circuit 130, each subplant may be completely defined by one or more subplant curves 140.

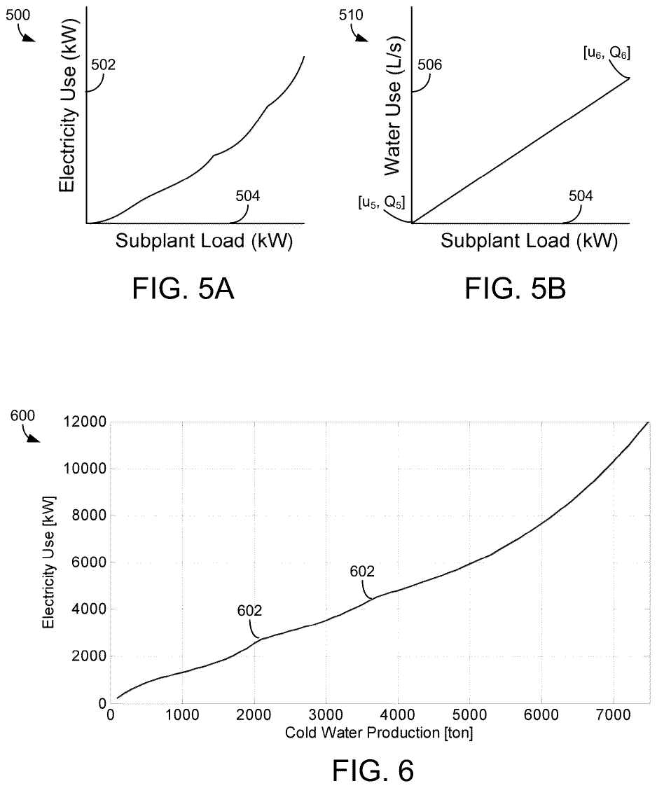

Still referring to FIG. 3, low level optimization circuit 132 may generate and provide subplant curves 140 to high level optimization circuit 130. Subplant curves 140 may indicate the rate of utility use by each of subplants 12-22 (e.g., electricity use measured in kW, water use measured in L/s, etc.) as a function of the subplant load. Exemplary subplant curves are shown and described in greater detail with reference to FIGS. 5A-8. In some embodiments, low level optimization circuit 132 generates subplant curves 140 based on equipment models 120 (e.g., by combining equipment models 120 for individual devices into an aggregate curve for the subplant). Low level optimization circuit 132 may generate subplant curves 140 by running the low level optimization process for several different loads and weather conditions to generate multiple data points. Low level optimization circuit 132 may fit a curve to the data points to generate subplant curves 140. In other embodiments, low level optimization circuit 132 provides the data points to high level optimization circuit 132 and high level optimization circuit 132 generates the subplant curves using the data points.

High level optimization circuit 130 may receive the load and rate predictions from load/rate prediction circuit 122 and the subplant curves 140 from low level optimization circuit 132. The load predictions may be based on weather forecasts from weather service 124 and/or information from building automation system 108 (e.g., a current electric load of the building, measurements from the building, a history of previous loads, a setpoint trajectory, etc.). The utility rate predictions may be based on utility rates received from utilities 126 and/or utility prices from another data source. High level optimization circuit 130 may determine the optimal load distribution for subplants 12-22 (e.g., a subplant load for each subplant) for each time step the prediction window and provide the subplant loads as setpoints to low level optimization circuit 132. In some embodiments, high level optimization circuit 130 determines the subplant loads by minimizing the total operating cost of central plant 10 over the prediction window. In other words, given a predicted load and utility rate information from load/rate prediction circuit 122, high level optimization circuit 130 may distribute the predicted load across subplants 12-22 over the optimization period to minimize operating cost.

In some instances, the optimal load distribution may include using TES subplants 20 and/or 22 to store thermal energy during a first time step for use during a later time step. Thermal energy storage may advantageously allow thermal energy to be produced and stored during a first time period when energy prices are relatively low and subsequently retrieved and used during a second time period when energy proves are relatively high. The high level optimization may be different from the low level optimization in that the high level optimization has a longer time constant due to the thermal energy storage provided by TES subplants 20-22. The high level optimization may be described by the following equation:

$${θ}_{HL}^{*} = arg {min}_{{θ}_{HL}} {J}_{HL} ( {θ}_{HL} )$$

where

$${θ}_{HL}^{*}$$

contains the optimal high level decisions (e.g., the optimal load for each of subplants 12-22) for the entire optimization period and JAL is the high level cost function.

To find the optimal high level decisions

$${θ}_{HL}^{*} ,$$

high level optimization circuit 132 may minimize the high level cost function J_{HL}. The high level cost function J_{HL} may be the sum of the economic costs of each utility consumed by each of subplants 12-22 for the duration of the optimization period. In some embodiments, the high level cost function J_{HL} may be described using the following equation:

$${J}_{HL} ( {θ}_{HL} ) = {\sum }_{k = 1}^{{n}_{h}} {\sum }_{i = 1}^{{n}_{s}} [ {\sum }_{j = 1}^{{n}_{u}} {t}_{s} \cdot {c}_{jk} {u}_{jik} ( {θ}_{HL} ) ]$$

where nₕ is the number of time steps k in the optimization period, nₛ is the number of subplants, tₛ is the duration of a time step, cⱼₖ is the economic cost of utility j at a time step k of the optimization period, and uⱼᵢₖ is the rate of use of utility j by subplant i at time step k.

In some embodiments, the cost function J_{HL} includes an additional demand charge term such as:

$${w}_{d} {c}_{demand} {max}_{{n}_{h}} ( {u}_{elec} ( {θ}_{HL} ) , {u}_{max , ele} )$$

where w_{d} is a weighting term, c_{demand} is the demand cost, and the max( ) term selects the peak electricity use during the applicable demand charge period. Accordingly, the high level cost function J_{HL} may be described by the equation:

$${J}_{HL} ( {θ}_{HL} ) = {\sum }_{k = 1}^{{n}_{h}} {\sum }_{i = 1}^{{n}_{s}} [ {\sum }_{j = 1}^{{n}_{u}} {t}_{s} \cdot {c}_{jk} {u}_{jik} ( {θ}_{HL} ) ] + {w}_{d} {c}_{demand} {max}_{{n}_{h}} ( {u}_{elec} ( {θ}_{HL} ) , {u}_{max , ele} )$$

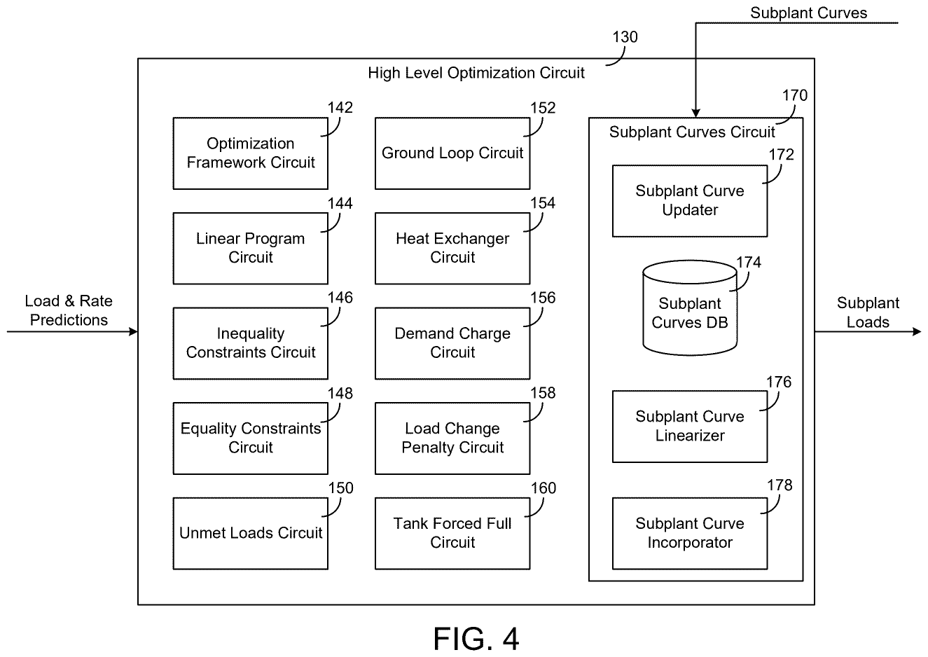

The decision vector OHL may be subject to several constraints. For example, the constraints may require that the subplants not operate at more than their total capacity, that the thermal storage not charge or discharge too quickly or under/over flow for the tank, and that the thermal energy loads for the building or campus are met. These restrictions lead to both equality and inequality constraints on the high level optimization problem, as described in greater detail with reference to FIG. 4.

Still referring to FIG. 3, low level optimization circuit 132 may use the subplant loads determined by high level optimization circuit 130 to determine optimal low level decisions

$${θ}_{LL}^{*}$$

(e.g. binary on/off decisions, flow setpoints, temperature setpoints, etc.) for equipment 60. The low level optimization process may be performed for each of subplants 12-22. Low level optimization circuit 132 may be responsible for determining which devices of each subplant to use and/or the operating setpoints for such devices that will achieve the subplant load setpoint while minimizing energy consumption. The low level optimization may be described using the following equation:

$${θ}_{LL}^{*} = arg {min}_{{θ}_{LL}} {J}_{LL} ( {θ}_{LL} )$$

where

$${θ}_{LL}^{*}$$

contains the optimal low level decisions and J_{LL} is the low level cost function.

To find the optimal low level decisions

$${θ}_{LL}^{*} ,$$

low level optimization circuit 132 may minimize the low level cost function J_{LL}. The low level cost function J_{LL} may represent the total energy consumption for all of equipment 60 in the applicable subplant. The low level cost function J_{LL} may be described using the following equation:

$${J}_{LL} ( {θ}_{LL} ) = {\sum }_{j = 1}^{N} {t}_{s} \cdot {b}_{j} \cdot {u}_{j} ( {θ}_{LL} )$$

where N is the number of devices of equipment 60 in the subplant, tₛ is the duration of a time step, bⱼ is a binary on/off decision (e.g., 0=off, 1=on), and uⱼ is the energy used by device j as a function of the setpoint θ_{LL}. Each device may have continuous variables which can be changed to determine the lowest possible energy consumption for the overall input conditions.

Low level optimization circuit 132 may minimize the low level cost function J_{LL} subject to inequality constraints based on the capacities of equipment 60 and equality constraints based on energy and mass balances. In some embodiments, the optimal low level decisions

$${θ}_{L L}^{*}$$

are constrained by switching constraints defining a short horizon for maintaining a device in an on or off state after a binary on/off switch. The switching constraints may prevent devices from being rapidly cycled on and off. In some embodiments, low level optimization circuit 132 performs the equipment level optimization without considering system dynamics. The optimization process may be slow enough to safely assume that the equipment control has reached its steady-state. Thus, low level optimization circuit 132 may determine the optimal low level decisions

$${θ}_{L L}^{*}$$

at an instance of time rather than over a long horizon.

Low level optimization circuit 132 may determine optimum operating statuses (e.g., on or off) for a plurality of devices of equipment 60. According to an exemplary embodiment, the on/off combinations may be determined using binary optimization and quadratic compensation. Binary optimization may minimize a cost function representing the power consumption of devices in the applicable subplant. In some embodiments, non-exhaustive (i.e., not all potential combinations of devices are considered) binary optimization is used. Quadratic compensation may be used in considering devices whose power consumption is quadratic (and not linear). Low level optimization circuit 132 may also determine optimum operating setpoints for equipment using nonlinear optimization. Nonlinear optimization may identify operating setpoints that further minimize the low level cost function J_{LL}. Low level optimization circuit 132 may provide the on/off decisions and setpoints to building automation system 108 for use in controlling the central plant equipment 60.

In some embodiments, the low level optimization performed by low level optimization circuit 132 is the same or similar to the low level optimization process described in U.S. patent application Ser. No. 14/634,615, filed Feb. 27, 2015, incorporated by reference herein in its entirety.

Referring now to FIG. 4, a block diagram illustrating high level optimization circuit 130 in greater detail is shown, according to an exemplary embodiment. High level optimization circuit 130 may receive load and rate predictions from load/rate prediction circuit 122 and subplant curves from low level optimization circuit 132. High level optimization circuit 130 may determine optimal subplant loads for each of subplants 12-22 as a function of the load and rate predictions and the subplant curves. In some embodiments, the optimal subplant loads minimize the economic cost of operating subplants 12-22 to satisfy the predicted loads for the building or campus. High level optimization circuit 130 may output the optimal subplant loads to low level optimization circuit 132.

High level optimization circuit 130 is shown to include an optimization framework circuit 142. Optimization framework circuit 142 may be configured to select and/or establish an optimization framework for use in calculating the optimal subplant loads. In some embodiments, optimization framework circuit 142 uses linear programming as the optimization framework. A linear programming problem has the following form:

$${arg min}_{x} {c}^{T} x ; subject to Ax \leq b , Hx = g$$

where c is a cost vector, x is a decision matrix, A and b are a matrix and vector (respectively) which describe inequality constraints on the optimization problem, and H and g are a matrix and vector (respectively) which describe equality constraints on the optimization problem.

The following paragraphs describe an exemplary linear optimization framework that may be used by high level optimization circuit 130 to calculate the optimal subplant loads. Advantageously, the linear programming framework described herein allows high level optimization circuit 130 to determine the subplant load distribution for a long optimization period in a very short timeframe complete with load change penalties, demand charges, and subplant performance curves. However, the linear optimization framework is merely one example of an optimization framework that can be used by high level optimization circuit 130 and should not be regarded as limiting. It should be understood that in other embodiments, high level optimization circuit 130 may use any of a variety of other optimization frameworks and/or optimization techniques (e.g., quadratic programming, linear-fractional programming, nonlinear programming, combinatorial algorithms, etc.) to calculate the optimal subplant loads.

Still referring to FIG. 4, high level optimization circuit 130 is shown to include a linear program circuit 144. Linear program circuit 144 may be configured to formulate and solve a linear optimization problem to calculate the optimal subplant loads. For example, linear program circuit 144 may determine and set values for the cost vector c, the A matrix and the b vector which describe the inequality constraints, and the H matrix and the g vector which describe the equality constraints. Linear program circuit 144 may determine an optimal decision matrix x* that minimizes the cost function c^{T}x. The optimal decision matrix x* may correspond to the optimal decisions

$${θ}_{HL}^{*}$$

(for each time step k within an optimization period) that minimize the high level cost function J_{HL}, as described with reference to FIG. 3.

For a central plant 10 that includes chillers, heat recovery chillers, hot water generators, and thermal energy storage, the plant assets across which the loads are to be distributed may include a chiller subplant 16, a heat recovery chiller subplant 14, a heater subplant 12, a hot thermal energy storage subplant 20, and a cold thermal energy storage subplant 22. The loads across each of subplants 12-22 may be the decision variables in the decision matrix x that the high level optimization determines for each time step k within the optimization period. For example, linear program circuit 144 may formulate the decision matrix x as:

$$x = {[ {\dot{Q}}_{Chiller , 1 … n} , {\dot{Q}}_{hrChiller , 1 …n} , {\dot{Q}}_{Heater , 1 …n} , {\dot{Q}}_{HotStorage , 1 …n} , {\dot{Q}}_{ColdStorage , 1 …n} ]}^{T}$$

where \dot{Q}_{Chiller,1 . . . n}, \dot{Q}_{hrChiller,1 . . . n}, \dot{Q}_{Heater,1 . . . n}, \dot{Q}_{HotStorage,1 . . . n}, and \dot{Q}_{ColdStorage,1 . . . n} are n-dimensional vectors representing the thermal energy load assigned to chiller subplant 16, heat recovery chiller subplant 14, heater subplant 12, hot TES subplant 20, and cold TES subplant 22, respectively, for each of the n time steps within the optimization period.

Linear program circuit 144 may formulate the linear program for the simple case where only energy cost and equipment constraints are considered. The simplified linear program may then be modified by inequality constraints circuit 146, equality constraints circuit 148, unmet loads circuit 150, ground loop circuit 152, heat exchanger circuit 154, demand charge circuit 156, load change penalty circuit 158, tank forced full circuit 160, and/or subplant curves circuit 170 to provide additional enhancements, described in greater detail below.

In some embodiments, linear program circuit 144 formulates the simplified linear program using the assumption that each subplant has a specific cost per unit load. For example, linear program circuit 144 may assume that each subplant has a constant coefficient of performance (COP) or efficiency for any given time step k. The COP can change over time and may have a different value for different time steps; however, in the simplest case, the COP for each of subplant is not a function of the loading. With this assumption, linear program circuit 144 may formulate the cost function c as:

$$c = {t}_{s} \cdot {[ {[ {\sum }_{j = 1}^{{n}_{u}} {c}_{j} {u}_{j , C h i l l e r} ]}_{1 … h} , {[ {\sum }_{j = 1}^{{n}_{u}} {c}_{j} {u}_{j , h r C h i l l e r} ]}_{1 … h} , {[ {\sum }_{j = 1}^{{n}_{u}} {c}_{j} {u}_{j , Heater} ]}_{1 … h} , {0}_{h ′} , {0}_{h} ]}^{T}$$

where tₛ is the duration of a time step, nᵤ is the total number of resources (e.g., electricity, natural gas, water, etc.) consumed by the subplants, cⱼ is the cost per unit of the jth resource, and u_{j,Chiller}, u_{j,hrChiller}, and u_{j,Heater} are the usage rates of the jth resource by chiller subplant 16, heat recovery chiller subplant 14, and heater subplant 12, respectively, for each of the h time steps within the optimization period. The first three elements of the form

$${[ {\sum }_{j = 1}^{{n}_{u}} {c}_{j} {u}_{j} ]}_{1 … h}$$

represent vectors of h sums (i.e., summing over all resource use), one for each time step within the optimization period. The last two elements of the form 0ₕ are zero to indicate that charging or discharging the thermal energy storage tanks has no cost (pumping power is neglected).

In some embodiments, linear program circuit 144 uses the load and rate predictions to formulate the linear program. For example, linear program circuit 144 may use the load predictions to determine values for u_{j,Chiller}, u_{j,hrChiller}, and u_{j,Heater} and may use the rate predictions to determine values for cⱼ for each of the nᵤ resources. In some embodiments, linear program circuit 144 uses the subplant curves to define cⱼ as a function of the resource usage. Linear program circuit 144 may use inputs from inequality constraints circuit 146, equality constraints circuit 148, unmet loads circuit 150, ground loop circuit 152, heat exchanger circuit 154, demand charge circuit 156, load change penalty circuit 158, tank forced full circuit 160, and/or subplant curves circuit 170 to determine and set values for the various matrices and vectors in the linear program. Circuits 146-170 may modify the cost vector c, the A matrix, the b vector, the H matrix, and/or the g vector to provide additional enhancements and/or functionality to the linear program. The inputs provided by circuits 146-170 are described in greater detail below.

Linear program circuit 144 may use any of a variety of linear optimization techniques to solve the linear optimization problem. For example, linear program circuit 144 may use basis exchange algorithms (e.g., simplex, crisscross, etc.), interior point algorithms (e.g., ellipsoid, projective, path-following, etc.), covering and packing algorithms, integer programming algorithms (e.g., cutting-plant, branch and bound, branch and cut, branch and price, etc.), or any other type of linear optimization algorithm or technique to solve the linear program subject to the optimization constraints. For embodiments in which nonlinear optimization is used, linear program circuit 144 may use any of a variety of nonlinear optimization techniques to solve the nonlinear optimization problem.

Still referring to FIG. 4, high level optimization circuit 130 is shown to include an inequality constraints circuit 146. Inequality constraints circuit 146 may formulate or define one or more inequality constraints on the optimization problem solved by linear program circuit 144. In some instances, inequality constraints circuit 146 defines inequality constraints on the decision variables \dot{Q}_{Chiller,k}, \dot{Q}_{hrChiller,k}, and \dot{Q}_{Heater,k} corresponding to the loads on chiller subplant 16, heat recovery chiller subplant 14, and heater subplant 12, respectively, for each time step k within optimization period. For example, each of subplants 12-16 may have two capacity constraints given by the following equations:

$${\dot{Q}}_{i , k} \leq {\dot{Q}}_{i , max} ∀ k ∈ horizon$$

$${\dot{Q}}_{i , k} \geq 0 ∀ k ∈ horizon$$

where \dot{Q}_{i,k} is the load on the ith subplant during time step k and \dot{Q}_{i,max} is the maximum capacity of the ith subplant. The first capacity constraint requires the load \dot{Q}_{i,k} on each of subplants 12-16 to be less than or equal to the maximum capacity \dot{Q}_{i,max} of the subplant for each time step k within the optimization period. The second capacity constraint requires the load \dot{Q}_{i,k} on each of subplants 12-16 to be greater than or equal to zero for each time step k within the optimization period.

The inequality constraints for chiller subplant 16 can be placed in the form Ax≤b by defining the A matrix and the b vector as follows:

$$A = [ \begin{matrix}[ {I}_{h} ] & [ {0}_{h} ] & [ {0}_{h} ] & [ {0}_{h} ] & [ {0}_{h} ] \\ [ - {I}_{h} ] & [ {0}_{h} ] & [ {0}_{h} ] & [ {0}_{h} ] & [ {0}_{h} ]\end{matrix} ] , b = [ \begin{matrix}{\dot{Q}}_{Chiller , max} [ {I}_{h} ] \\ [ {0}_{h} ]\end{matrix} ]$$

where [Iₕ] represents either an h by h identity matrix or an h by 1 ones vector, [0ₕ] represents either an h by h zero matrix or an h by 1 zero vector, and \dot{Q}_{Chiller,max} is the maximum capacity of chiller subplant 16. Similar inequality constraints for heat recovery chiller subplant 14 and heater subplant 12 can be placed in the form Ax≤b by defining the A matrices and the b vectors as follows:

$$A = [ \begin{matrix}[ {0}_{h} ] & [ {I}_{h} ] & [ {0}_{h} ] & [ {0}_{h} ] & [ {0}_{h} ] \\ [ {0}_{h} ] & [ - {I}_{h} ] & [ {0}_{h} ] & [ {0}_{h} ] & [ {0}_{h} ]\end{matrix} ] , b = [ \begin{matrix}{\dot{Q}}_{hrChiller , max} [ {I}_{h} ] \\ [ {0}_{h} ]\end{matrix} ]$$

$$A = [ \begin{matrix}[ {0}_{h} ] & [ {0}_{h} ] & [ {I}_{h} ] & [ {0}_{h} ] & [ {0}_{h} ] \\ [ {0}_{h} ] & [ {0}_{h} ] & [ - {I}_{h} ] & [ {0}_{h} ] & [ {0}_{h} ]\end{matrix} ] , b = [ \begin{matrix}{\dot{Q}}_{Heater , max} [ {I}_{h} ] \\ [ {0}_{h} ]\end{matrix} ]$$

where \dot{Q}_{hrChiller,max} is the maximum capacity of heat recovery chiller subplant 14 and \dot{Q}_{Heater,max} is the maximum capacity of heater subplant 12.

Inequality constraints circuit 146 may formulate or define inequality constraints on the decision variables \dot{Q}_{HotStorage,k} and \dot{Q}_{ColdStorage,k} corresponding to the loads on hot TES subplant 20 and cold TES subplant 22 for each time step k within the optimization period. For example, each of subplants 20-22 may have two capacity constraints given by the following equations:

$${\dot{Q}}_{i , k} \leq {\dot{Q}}_{discharge , i , max} ∀ k ∈ horizon$$

$$- {\dot{Q}}_{i , k} \leq {\dot{Q}}_{charge , i , max} ∀ k ∈ horizon$$

where \dot{Q}_{i,k} is the rate at which ith TES subplant is being discharged at time step k, \dot{Q}_{discharge,i,max} is the maximum discharge rate of the ith subplant, and \dot{Q}_{charge,i,max} is the maximum charge rate of the ith subplant. Positive load values for \dot{Q}_{i,k} indicate that the TES subplant is discharging and negative load values for \dot{Q}_{i,k} indicate that the subplant is charging. The first capacity constraint requires the discharge rate \dot{Q}_{i,k} for each of subplants 20-22 to be less than or equal to the maximum discharge rate \dot{Q}_{discharge,i,max} of the subplant for each time step k within the optimization period. The second capacity constraint requires the negative discharge rate −\dot{Q}_{i,k} (i.e., the charge rate) for each of subplants 20-22 to be less than or equal to the maximum charge rate \dot{Q}_{charge,i,max} of the subplant for each time step k within the optimization period.

The inequality constraints for hot TES subplant 20 can be placed in the form Ax≤b by defining the A matrix and the b vector as follows:

$$A = [ \begin{matrix}[ {0}_{h} ] & [ {0}_{h} ] & [ {0}_{h} ] & [ {I}_{h} ] & [ {0}_{h} ] \\ [ {0}_{h} ] & [ {0}_{h} ] & [ {0}_{h} ] & [ - {I}_{h} ] & [ {0}_{h} ]\end{matrix} ] , b = [ \begin{matrix}{\dot{Q}}_{HotDischarge , max} [ {I}_{h} ] \\ {\dot{Q}}_{HotCharge , max} [ {I}_{h} ]\end{matrix} ]$$

where \dot{Q}_{HotDischarge,max} is the maximum discharge rate for hot TES subplant 20 and \dot{Q}_{HotCharge,max} is the maximum charge rate for hot TES subplant 20. Similar inequality constraints for cold TES subplant 22 can be placed in the form Ax≤b by defining the A matrix and the b vector as follows:

$$A = [ \begin{matrix}[ {0}_{h} ] & [ {0}_{h} ] & [ {0}_{h} ] & [ {0}_{h} ] & [ {I}_{h} ] \\ [ {0}_{h} ] & [ {0}_{h} ] & [ {0}_{h} ] & [ {0}_{h} ] & [ - {I}_{h} ]\end{matrix} ] , b = [ \begin{matrix}{\dot{Q}}_{ColdDischarge , max} [ {I}_{h} ] \\ {\dot{Q}}_{ColdCharge , max} [ {I}_{h} ]\end{matrix} ]$$

where \dot{Q}_{ColdDischarge,max} is the maximum discharge rate for cold TES subplant 22 and \dot{Q}_{ColdCharge,max} is the maximum charge rate for cold TES subplant 22.

Inequality constraints circuit 146 may implement an electrical demand constraint for the total electrical usage of all the subplants and the building/campus P_{elec,campus}. Inequality constraints circuit 146 may require that the total electrical demand be less than or equal to a maximum electrical demand P_{elec,max} by defining the A matrix and the b vector as follows:

$$A = [ {u}_{elec , Chiller} [ {I}_{h} ] , {u}_{elec , hrChiller} [ {I}_{h} ] , {u}_{elec , Heater} [ {I}_{h} ] , {0}_{n} , {0}_{n} ] , b = {P}_{elec , max} [ {I}_{h} ] - {P}_{elec , campus , k}$$

where u_{elec,Chiller}, u_{elec,hrChiller}, and u_{elec,Heater} are the electrical usage values for chiller subplant 16, heat recovery chiller subplant 14, and heater subplant 12, respectively, P_{elec,campus,k} is the electrical usage of the building/campus at time k, and P_{elec,max} is the maximum total electrical usage for central plant 10 and the building/campus.

Inequality constraints circuit 146 may implement tank capacity constraints for hot TES subplant 20 and cold TES subplant 22. The tank capacity constraints may require that each TES tank never charge above its maximum capacity or discharge below zero. These physical requirements lead to a series of constraints to ensure that the initial tank level Q₀ of each TES tank at the beginning of the optimization period plus all of the charging during time steps 1 to k into the optimization period is less than or equal to the maximum capacity Qₘₐₓ of the TES tank. A similar constraint may be implemented to ensure that the initial tank level Q₀ of each TES tank at the beginning of the optimization period minus all of the discharging during time steps 1 to k into the optimization period is greater than or equal to zero.

The tank capacity constraints for hot TES subplant 20 can be placed in the form Ax≤b by defining the A matrix and the b vector as follows:

$$A = [ \begin{matrix}[ {0}_{h} ] & [ {0}_{h} ] & [ {0}_{h} ] & {t}_{s} [ {Δ}_{h} ] & [ {0}_{h} ] \\ [ {0}_{h} ] & [ {0}_{h} ] & [ {0}_{h} ] & {t}_{s} [ - {Δ}_{h} ] & [ {0}_{h} ]\end{matrix} ] , b = [ \begin{matrix}{\dot{Q}}_{0 , Hot} [ {I}_{h} ] \\ {\dot{Q}}_{max , Hot} - [ {I}_{h} ]\end{matrix} ]$$

where Q_{0,Hot} is the initial charge level of hot TES subplant 20 at the beginning of the optimization period, Q_{max,Hot} is the maximum charge level of hot TES subplant 20, Δₕ is a lower triangular matrix of ones, and tₛ is the duration of a time step. Discharging the tank is represented in the top row of the A matrix as positive flow from the tank and charging the tank is represented in the bottom row of the A matrix as negative flow from the tank. Similar inequality constraints for cold TES subplant 22 can be placed in the form Ax≤b by defining the A matrix and the b vector as follows:

$$A = [ \begin{matrix}[ {0}_{h} ] & [ {0}_{h} ] & [ {0}_{h} ] & [ {0}_{h} ] & {t}_{s} [ {Δ}_{h} ] \\ [ {0}_{h} ] & [ {0}_{h} ] & [ {0}_{h} ] & [ {0}_{h} ] & {t}_{s} [ - {Δ}_{h} ]\end{matrix} ] , b = [ \begin{matrix}{Q}_{0 , Cold} [ {I}_{h} ] \\ {Q}_{max , Cold} - {Q}_{0 , Cold} [ {I}_{h} ]\end{matrix} ]$$

where Q_{0,cold} is the initial charge level of cold TES subplant 22 at the beginning of the optimization period and Q_{max,Cold} is the maximum charge level of cold TES subplant 22.

Still referring to FIG. 4, high level optimization circuit 130 is shown to include an equality constraints circuit 148. Equality constraints circuit 148 may formulate or define one or more equality constraints on the optimization problem solved by linear program circuit 144. The equality constraints may ensure that the predicted thermal energy loads of the building or campus are satisfied for each time step k in the optimization period. Equality constraints circuit 148 may formulate an equality constraint for each type of thermal energy load (e.g., hot water, cold water, etc.) to ensure that the load is satisfied. The equality constraints may be given by the following equation:

$${\sum }_{i = 1}^{{n}_{s}} {\dot{Q}}_{p , i , k} = {\hat{ℓ}}_{p , k} ∀ k ∈ horizon$$

where \dot{Q}_{p,i,k} is the thermal energy load of type p (e.g., hot water, cold water, etc.) on the ith subplant during time step k, nₛ is the total number of subplants capable of serving thermal energy load p, and [symbol] is the predicted thermal energy load of type p that must be satisfied at time step k. The predicted thermal energy loads may be received as load predictions from load/rate prediction circuit 122.

In some embodiments, the predicted thermal energy loads include a predicted hot water thermal energy load [symbol] and a predicted cold water thermal energy load [symbol] for each time step k. The predicted hot water thermal energy load [symbol] may be satisfied by the combination of heat recovery chiller subplant 14, heater subplant 12, and hot TES subplant 20. The predicted cold water thermal energy load [symbol] may be satisfied by the combination of heat recovery chiller subplant 14, chiller subplant 16, and cold TES subplant 22.

The equality constraints can be placed in the form Hx=g by defining the H matrix and the g vector as follows:

$$H = [ \begin{matrix}[ {I}_{h} ] & [ {I}_{h} ] & [ {0}_{h} ] & [ {0}_{h} ] & [ {I}_{h} ] \\ [ {0}_{h} ] & ( 1 + {u}_{elec , hrChiller} [ {I}_{h} ] & [ {I}_{h} ] & [ {I}_{h} ] & [ {0}_{h} ]\end{matrix} ] , g = [ \begin{matrix}{\hat{ℓ}}_{Cold , 1 ... k} \\ {\hat{ℓ}}_{Hot , 1 ... k}\end{matrix} ]$$

where [symbol] and [symbol] are k-dimensional vectors of predicted cold water loads and predicted hot water loads, respectively, at each of time steps k, and u_{elec,hrChiller} is the electrical consumption of heat recovery chiller subplant 14. For central plants that serve one or more additional types of loads, an additional row may be added to the H matrix and the g vector to define the equality constraints for each additional load served by the central plant.

For this example problem, assuming an optimization period of 72 one-hour samples, the linear program has 360 decision variables and 1224 constraints. However, linear program circuit 144 can solve this linear program to determine the optimal subplant load values in less than 200 milliseconds using the linear programming framework. Advantageously, this allows high level optimization circuit 130 to determine the subplant load distribution for a long optimization period in a very short timeframe.

Still referring to FIG. 4, high level optimization circuit 130 is shown to include an unmet loads circuit 150. In some instances, the central plant equipment 60 may not have enough capacity or reserve storage to satisfy the predicted thermal energy loads, regardless of how the thermal energy loads are distributed across subplants 12-22. In other words, the high level optimization problem may have no solution that satisfies all of the inequality and equality constraints, even if the applicable subplants are operated at maximum capacity. Unmet loads circuit 150 may be configured to modify the high level optimization problem to account for this possibility and to allow the high level optimization to find the solution that results in the minimal amount of unmet loads.

In some embodiments, unmet loads circuit 150 modifies the decision variable matrix x by introducing a slack variable for each type of thermal energy load. The slack variables represent an unsatisfied (e.g., unmet, deferred, etc.) amount of each type of thermal energy load. For example, unmet loads circuit 150 may modify the decision variable matrix x as follows:

$$x = {[ {\dot{Q}}_{Chiller , 1 ... n} , {\dot{Q}}_{hrChiller , 1 ... n} , {\dot{Q}}_{Heater , 1 ... n} , \\ {\dot{Q}}_{HotStorage , 1 ... n} , {\dot{Q}}_{ColdStorage , 1 ... n} , {Q}_{ColdUnmet , 1 ... n} , {Q}_{HotUnmet , 1 ... n} ]}^{T}$$

where Q_{ColdUnmet,1 . . . n} and Q_{HotUnmet,1 . . . n} are n-dimensional vectors representing a total deferred cold thermal energy load and a total deferred hot thermal energy load, respectively, at each time step k within the optimization period. In some embodiments, the decision variables Q_{ColdUnmet,1 . . . n} and Q_{HotUnmet,1 . . . n} represent total deferred loads that have accumulated up to each time step k rather than the incremental deferred load at each time step. The total deferred load may be used because any deferred load is likely to increase the required load during subsequent time steps.

Unmet loads circuit 150 may modify the equality constraints to account for any deferred thermal energy loads. The modified equality constraints may require that the predicted thermal energy loads are equal to the total loads satisfied by subplants 12-22 plus any unsatisfied thermal energy loads. The modified equality constraints can be placed in the form Hx=g by defining the H matrix and the g vector as follows:

$$H = [ \begin{matrix}[ {I}_{h} ] & [ {I}_{h} ] & [ {0}_{h} ] & [ {0}_{h} ] & [ {I}_{h} ] & [ {I}_{h} ] - & [ {0}_{h} ] \\ & & & & & [ {D}_{- 1} ] & \\ [ {0}_{h} ] & ( 1 + & [ {I}_{h} ] & [ {I}_{h} ] & [ {0}_{h} ] & [ {0}_{h} ] & [ {I}_{h} ] - \\ & {u}_{elec , hrChiller} [ {I}_{h} ] & & & & & [ {D}_{- 1} ]\end{matrix} ] , \\ g = [ \begin{matrix}{\hat{ℓ}}_{Cold , 1 ... k} \\ {\hat{ℓ}}_{Hot , 1 ... k}\end{matrix} ]$$

where [D₋₁] is a lower diagonal matrix of ones.

Unmet loads circuit 150 may modify the cost vector c to associate cost values with any unmet loads. In some embodiments, unmet loads circuit 150 assigns unmet loads a relatively higher cost compared to the costs associated with other types of loads in the decision variable matrix x. Assigning a large cost to unmet loads ensures that the optimal solution to the high level optimization problem uses unmet loads only as a last resort (i.e., when the optimization has no solution without using unmet loads). Accordingly, linear program circuit 144 may avoid using unmet loads if any feasible combination of equipment is capable of satisfying the predicted thermal energy loads. In some embodiments, unmet loads circuit 150 assigns a cost value to unmet loads that allows linear program circuit 144 to use unmet loads in the optimal solution even if the central plant is capable of satisfying the predicted thermal energy loads. For example, unmet loads circuit 150 may assign a cost value that allows linear program circuit 144 to use unmet loads if the solution without unmet loads would be prohibitively expensive and/or highly inefficient.

Still referring to FIG. 4, high level optimization circuit 130 is shown to include a subplant curves circuit 170. In the simplest case described with reference to linear program circuit 144, it was assumed that the resource consumption of each subplant is a linear function of the thermal energy load produced by the subplant. However, this assumption may not be true for some subplant equipment, much less for an entire subplant. Subplant curves circuit 170 may be configured to modify the high level optimization problem to account for subplants that have a nonlinear relationship between resource consumption and load production.

Subplant curves circuit 170 is shown to include a subplant curve updater 172, a subplant curves database 174, a subplant curve linearizer 176, and a subplant curves incorporator 178. Subplant curve updater 172 may be configured to request subplant curves for each of subplants 12-22 from low level optimization circuit 132. Each subplant curve may indicate an amount of resource consumption by a particular subplant (e.g., electricity use measured in kW, water use measured in L/s, etc.) as a function of the subplant load. Exemplary subplant curves are shown and described in greater detail with reference to FIGS. 5A-8.

In some embodiments, low level optimization circuit 132 generates the subplant curves by running the low level optimization process for various combinations of subplant loads and weather conditions to generate multiple data points. Low level optimization circuit 132 may fit a curve to the data points to generate the subplant curves and provide the subplant curves to subplant curve updater 172. In other embodiments, low level optimization circuit 132 provides the data points to subplant curve updater 172 and subplant curve updater 172 generates the subplant curves using the data points. Subplant curve updater 172 may store the subplant curves in subplant curves database 174 for use in the high level optimization process.

In some embodiments, the subplant curves are generated by combining efficiency curves for individual devices of a subplant. A device efficiency curve may indicate the amount of resource consumption by the device as a function of load. The device efficiency curves may be provided by a device manufacturer or generated using experimental data. In some embodiments, the device efficiency curves are based on an initial efficiency curve provided by a device manufacturer and updated using experimental data. The device efficiency curves may be stored in equipment models 120. For some devices, the device efficiency curves may indicate that resource consumption is a U-shaped function of load. Accordingly, when multiple device efficiency curves are combined into a subplant curve for the entire subplant, the resultant subplant curve may be a wavy curve as shown in FIG. 6. The waves are caused by a single device loading up before it is more efficient to turn on another device to satisfy the subplant load.

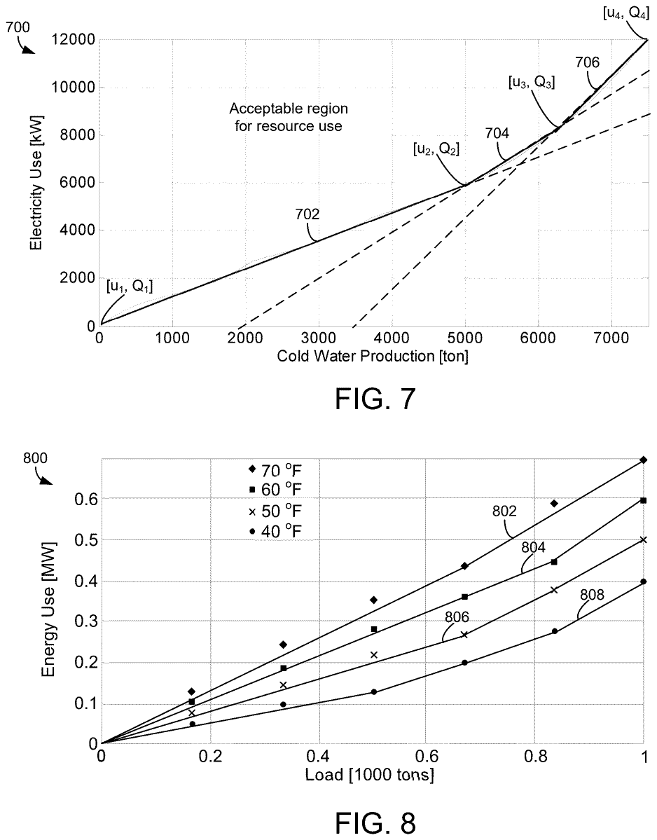

Subplant curve linearizer 176 may be configured to convert the subplant curves into convex curves. A convex curve is a curve for which a line connecting any two points on the curve is always above or along the curve (i.e., not below the curve). Convex curves may be advantageous for use in the high level optimization because they allow for an optimization process that is less computationally expensive relative to an optimization process that uses non-convex functions. Subplant curve linearizer 176 may be configured to break the subplant curves into piecewise linear segments that combine to form a piecewise-defined convex curve. An unmodified subplant curve 600 and a linearized subplant curve 700 generated by subplant curve linearizer 176 are shown in FIGS. 6 and 7, respectively. Subplant curve linearizer 176 may store the linearized subplant curves in subplant curves database 174.

Still referring to FIG. 4, subplant curves circuit 170 is shown to include a subplant curve incorporator 178. Subplant curve incorporator 178 may be configured to modify the high level optimization problem to incorporate the subplant curves into the optimization. In some embodiments, subplant curve incorporator 178 modifies the decision matrix x to include one or more decision vectors representing the resource consumption of each subplant. For example, for chiller subplant 16, subplant curve incorporator 178 may modify the decision matrix x as follows:

$$x = {[ \begin{matrix}... & {\dot{Q}}_{Chiller , 1 ... n} & ... & {u}_{Chiller , elec , 1 ... n} & {u}_{Chiller , water , 1 ... n} & ...\end{matrix} ]}^{T}$$

where u_{Chiller,elec,1 . . . n} and u_{Chiller,water,1 . . . n} are n-dimensional vectors representing the amount of electrical consumption and water consumption, respectively, by chiller subplant 16 at each time step k.

Subplant curve incorporator 178 may add one or more resource consumption vectors to matrix x for each of subplants 12-22. The decision vectors added by subplant curve incorporator 178 for a given subplant may represent an amount of resource consumption for each resource consumed by the subplant (e.g., water, electricity, natural gas, etc.) at each time step k within the optimization period. For example, if heater subplant 12 consumes natural gas, electricity, and water, subplant curve incorporator 178 may add a decision vector u_{Heater,gas,1 . . . n} representing an amount of natural gas consumed by heater subplant 12 at each time step, a decision vector u_{Heater,elec,1 . . . n} representing an amount of electricity consumed by heater subplant 12 at each time step, and a decision vector u_{Heater,water,1 . . . n} representing an amount of water consumed by heater subplant at each time step. Subplant curve incorporator 178 may add resource consumption vectors for other subplants in a similar manner.

Subplant curve incorporator 178 may modify the cost vector c to account for the resource consumption vectors in the decision matrix x. In some embodiments, subplant curve incorporator 178 removes (or sets to zero) any cost directly associated with the subplant loads (e.g., \dot{Q}_{Chiller,1 . . . n}, \dot{Q}_{Heater,1 . . . n}, etc.) and adds economic costs associated with the resource consumption required to produce the subplant loads. For example, for chiller subplant 16, subplant curve incorporator 178 may modify the cost vector c as follows:

$$c = {[ \begin{matrix}... & {0}_{n} & ... & {c}_{elec , 1 ... n} & {c}_{water , 1 ... n} & ...\end{matrix} ]}^{T}$$

where 0ₙ is a n-dimensional zero vector indicating that the direct economic cost of \dot{Q}_{Chiller,1 . . . n} is zero at each time step, c_{elec,1 . . . n} is a n-dimensional vector indicating the per unit cost of electricity at each time step, and c_{water,1 . . . n} is a n-dimensional vector indicating the per unit cost of water at each time step. The modified cost vector associates an economic cost with the resources consumed to produce the subplant loads rather than the subplant loads themselves. In some embodiments, the values for c_{elec,1 . . . n} and c_{water,1 . . . n} are utility rates obtained from load/rate prediction circuit 122.

Subplant curve incorporator 178 may modify the inequality constraints to ensure that the proper amount of each resource is consumed to serve the predicted thermal energy loads. In some embodiments, subplant curve incorporator 178 formulates inequality constraints that force the resource usage for each resource in the epigraph of the corresponding linearized subplant curve. For example, chiller subplant 16 may have a linearized subplant curve that indicates the electricity use of chiller subplant 16 (i.e., u_{Chiller,elec}) as a function of the cold water production of chiller subplant 16 (i.e., \dot{Q}_{Chiller}). Such a linearized subplant curve 700 is shown in FIG. 7. The linearized subplant curve may include a first line segment connecting point [u₁, Q₁] to point [u₂, Q₂], a second line segment connecting point [u₂, Q₂] to point [u₃, Q₃], and a third line segment connecting point [u₃, Q₃] to point [u₄, Q₄].

Subplant curve incorporator 178 may formulate an inequality constraint for each piecewise segment of the subplant curve that constrains the value of u_{Chiller,elec} to be greater than or equal to the amount of electricity use defined by the line segment for the corresponding value of \dot{Q}_{Chiller}. The subplant curve constraints for the electricity use of chiller subplant 16 can be placed in the form Ax≤b by defining the A matrix and the b vector as follows:

$$A = [ \begin{matrix}… & [ - ( {u}_{2} - {u}_{1} ) ] {I}_{n} & … & [ ( {Q}_{2} - {Q}_{1} ) ] {I}_{n} & {0}_{n} & … \\ … & [ - ( {u}_{3} - {u}_{2} ) ] {I}_{n} & … & [ ( {Q}_{3} - {Q}_{2} ) ] {I}_{n} & {0}_{n} & … \\ … & [ - ( {u}_{4} - {u}_{3} ) ] {I}_{n} & … & [ ( {Q}_{4} - {Q}_{3} ) ] {I}_{n} & {0}_{n} & …\end{matrix} ] , b = [ \begin{matrix}{Q}_{1} {u}_{2} - {Q}_{2} {u}_{1} \\ {Q}_{2} {u}_{3} - {Q}_{3} {u}_{2} \\ {Q}_{3} {u}_{4} - {Q}_{4} {u}_{3}\end{matrix} ]$$

Similar inequality constraints can be formulated for other subplant curves. For example, subplant curve incorporator 178 may generate a set of inequality constraints for the water consumption u_{Chiller,water,1 . . . n} of chiller subplant 16 using the points defining the linearized subplant curve for the water consumption u_{Chiller,water,1 . . . n} of chiller subplant 16 as a function of cold water production Q̅_{Chiller}. In some embodiments, the water consumption of chiller subplant 16 is equal to the cold water production and the linearized subplant curve for water consumption includes a single line segment connecting point [u₅, Q₅] to point [u₆, Q₆] (as shown in FIG. 5B). The subplant curve constraints for the cold water consumption of chiller subplant 16 can be placed in the form Ax≤b by defining the A matrix and the b vector as follows:

$$A = [ \begin{matrix}… & [ - ( {u}_{6} - {u}_{5} ) ] {I}_{n} & … & {0}_{n} & [ ( {Q}_{6} - {Q}_{5} ) ] {I}_{n} & …\end{matrix} ] , b = [ {Q}_{5} {u}_{6} - {Q}_{6} {u}_{5} ]$$

Subplant curve incorporator 178 may repeat this process for each subplant curve for chiller subplant 16 and for the other subplants of central plant 10 to define a set of inequality constraints for each subplant curve.

The inequality constraints generated by subplant curve incorporator 178 ensure that high level optimization circuit 130 keeps the resource consumption above all of the line segments of the corresponding subplant curve. In most situations, there is no reason for high level optimization circuit 130 to choose a resource consumption value that lies above the corresponding subplant curve due to the economic cost associated with resource consumption. High level optimization circuit 130 can therefore be expected to select resource consumption values that lie on the corresponding subplant curve rather than above it.

The exception to this general rule is heat recovery chiller subplant 14. The equality constraints for heat recovery chiller subplant 14 provide that heat recovery chiller subplant 14 produces hot water at a rate equal to the subplant's cold water production plus the subplant's electricity use. The inequality constraints generated by subplant curve incorporator 178 for heat recovery chiller subplant 14 allow high level optimization circuit 130 to overuse electricity to make more hot water without increasing the amount of cold water production. This behavior is extremely inefficient and only becomes a realistic possibility when the demand for hot water is high and cannot be met using more efficient techniques. However, this is not how heat recovery chiller subplant 14 actually operates.

To prevent high level optimization circuit 130 from overusing electricity, subplant curve incorporator 178 may check whether the calculated amount of electricity use (determined by the optimization algorithm) for heat recovery chiller subplant 14 is above the corresponding subplant curve. In some embodiments, the check is performed after each iteration of the optimization algorithm. If the calculated amount of electricity use for heat recovery chiller subplant 14 is above the subplant curve, subplant curve incorporator 178 may determine that high level optimization circuit 130 is overusing electricity. In response to a determination that high level optimization circuit 130 is overusing electricity, subplant curve incorporator 178 may constrain the production of heat recovery chiller subplant 14 at its current value and constrain the electricity use of subplant 14 to the corresponding value on the subplant curve. High level optimization circuit 130 may then rerun the optimization with the new equality constraints.

Still referring to FIG. 4, high level optimization circuit 130 is shown to include a ground loop circuit 152 and a heat exchanger circuit 154. In some embodiments, central plant 10 includes a heat exchanger configured to transfer heat between hot water loop 24 and condenser water loop 28. In some embodiments, central plant 10 includes a ground loop that serves as heat rejection for chiller subplant 16 and/or heat extraction for heat recovery chiller subplant 14. Ground loop circuit 152 and heat exchanger circuit 154 may be configured to modify the optimization problem to account for heat transfer resulting from operation of the heat exchanger and/or the ground loop.

Ground loop circuit 152 may incorporate heat rejection to the ground loop into the optimization problem by changing the amount of electricity and water usage by chiller subplant 16. For example, for loadings up to the heat rejection capacity of the ground loop, chiller subplant 16 may use an additional amount of electricity to run the ground loop pumps. The additional electricity usage may be constant or may vary per unit of flow through the ground loop. The amount of water production of chiller subplant 16 may be constant regardless of whether the ground loop is used.

Ground loop circuit 152 and heat exchanger circuit 154 may incorporate heat extraction from the ground loop and heat transfer between hot water loop 24 and condenser water loop 28 into the optimization problem in a similar manner. For example, ground loop circuit 152 and heat exchanger circuit 154 may use heat extraction from the ground loop and heat transfer between loops 24 and 28 to modify the load seen by the central plant equipment. Ground loop circuit 152 may use the ground loop to create what appears as a false building load to the equipment, thereby allowing heat recovery chiller subplant 14 to operate as heat pumps when the building load does not add enough heat to the system. This outcome may be optimal when the ratio between electricity prices and gas prices is low such that it is less expensive to operate the ground loop and the heat exchanger using electricity than it would be to use natural gas to generate heat in heater subplant 12.

Heat exchanger circuit 154 may use the heat exchanger to create what appears to be a false hot water building load, thereby allowing heat recovery chiller subplant 14 to operate as conventional chillers. The excess heat from heat recovery chiller subplant 14 may be transferred through the heat exchanger to condenser loop 28 and ultimately into the atmosphere or into the ground. In some embodiments, heat exchanger circuit 154 operates the heat exchanger to prevent condenser loop from becoming overloaded. For example, heat exchanger circuit 154 may limit the total heat rejected to the capacity of condenser loop 28 minus the heat produced by the conventional chillers.

Ground loop circuit 152 and heat exchanger circuit 154 may modify the decision matrix x by adding a new decision vector for each type of thermal energy load. The new decision vectors may represent the overproduction of each thermal energy load for each time step k within the optimization period. For example, the modified decision matrix may appear as follows:

$$x = {[ {\dot{Q}}_{Chiller , 1 ... n} , {\dot{Q}}_{hrChiller , 1 ... n} , \\ {\dot{Q}}_{Heater , 1 ... n} , {\dot{Q}}_{HotStorage , 1 ... n} , {\dot{Q}}_{ColdStorage , 1 ... n} , ... ... , \\ {Q}_{ColdUnmet , 1 ... n} , {Q}_{HotUnmet , 1 ... n} {\dot{Q}}_{ColdOver , 1 ... n} {\dot{Q}}_{HotOver , 1 ... n} ]}^{T}$$

where \dot{Q}_{ColdOver,1 . . . n} and \dot{Q}_{HotOver, . . . n} are n-dimensional vectors representing the overproduction rates of the cold thermal energy load and the hot thermal energy load, respectively, for each time step k within the optimization period.

Ground loop circuit 152 and heat exchanger circuit 154 may modify the equality constraints to account for any overproduced thermal energy loads. The overproduced thermal energy loads may be added to the equality constraints as slack variables that operate in the opposite direction of the unmet loads. The modified equality constraints may require that the predicted thermal energy loads plus any overproduction are equal to the total loads satisfied by subplants 12-22 plus any unsatisfied thermal energy loads. The modified equality constraints can be placed in the form Hx=g by defining the H matrix and the g vector as follows:

$$H = [ \begin{matrix}[ {I}_{h} ] & [ {I}_{h} ] & [ {0}_{h} ] & [ {0}_{h} ] & [ {I}_{h} ] & [ {I}_{h} ] - & [ {0}_{h} ] & - [ {I}_{h} ] & [ {0}_{h} ] \\ & & & & & [ {D}_{- 1} ] & & & \\ [ {0}_{h} ] & ( 1 + & [ {I}_{h} ] & [ {I}_{h} ] & [ {0}_{h} ] & [ {0}_{h} ] & [ {I}_{h} ] - & [ {0}_{h} ] & - [ {I}_{h} ] \\ & {u}_{elec , hrChiller} [ {I}_{h} ] & & & & & [ {D}_{- 1} ] & & \end{matrix} ]$$

$$g = [ \begin{matrix}{\hat{ℓ}}_{Cold , 1 ... k} \\ {\hat{ℓ}}_{Hot , 1 ... k}\end{matrix} ]$$

where [D₋₁] is a lower diagonal matrix of ones. Ground loop circuit 152 and heat exchanger circuit 154 may modify the cost vector c with the additional cost of the pumping power per unit of overproduction required to run the ground loop and/or the heat exchanger.

Still referring to FIG. 4, high level optimization circuit 130 is shown to include a demand charge circuit 156. As discussed above, optimization framework circuit 142 may formulate the optimization problem as:

$${arg min}_{x} {c}^{T} x ; subject to Ax \leq b , Hx = g$$

However, such a formulation does not account for the demand charge.

The demand charge is an additional charge imposed by some utility providers based on the maximum rate of energy consumption during an applicable demand charge period. For example, the demand charge may be provided in terms of dollars per unit of power (e.g., $/kW) and may be multiplied by the peak power usage (e.g., kW) during a demand charge period to calculate the demand charge. In some instances, the demand charge can account for more than 15% of the electrical bill. Failure to include the demand charge in the optimization scheme can cause all of the equipment to turn on at the same time (e.g., the most efficient or lowest cost time). This would be optimal from a consumption cost standpoint. However, shifting some of the load in time may save thousands of dollars on demand while only costing a few dollars in consumption cost.

Demand charge circuit 156 may be configured to modify the optimization problem to account for the demand charge. Incorporating the demand charge into the optimization framework may greatly improve the performance of the high level optimization. For example, including the demand charge in the optimization framework may reduce the total operating costs of central plant 10 by an additional 5% on top of the 8-10% cost reduction provided by other circuits of central plant controller 102. In various implementations, the savings provided by demand charge circuit 156 and/or central plant controller 102 as a whole may be greater than or less than the exemplary amounts defined herein due to differences in plant configuration and/or energy costs.

Demand charge circuit 156 may account for the demand charge by modifying the cost function used by high level optimization circuit 130. The modified cost function may be defined as:

$${arg min}_{x} [ {c}^{T} x + {c}_{demand} max ( {P}_{elec , k} ) ] ; subject to Ax \leq b , Hx = g$$

where c_{demand} is the demand charge (e.g., $/kW) for the applicable demand charge period and P_{elec,k} is the total electrical power consumption of central plant 10 and the building/campus at time step k. The term max (P_{elec,k}) selects the peak electrical power consumption at any time during the demand charge period. The demand charge c_{demand} and the demand charge period may be defined by the utility rate information received from utilities 126 and may be provided to high level optimization circuit 130 by load/rate prediction circuit 122.

Incorporating the demand charge into the optimization framework complicates the optimization problem in two primary ways. First, the cost function is no longer linear due to the inclusion of the max( ) function. Second, the consumption term c^{T}x calculates cost over a consumption period defined by a time horizon, whereas the demand charge term c_{demand} max(P_{elec,k}) calculates cost over the demand charge period. For example, the consumption period may be defined as the time period beginning at the current time step k and ending at a future time step k+h, where h represents the time horizon. The demand charge period may be defined by utilities 126 and provided to high level optimization circuit 130 along with the utility rate information. In some instances, the consumption period and the demand charge period may not be the same. This complicates the optimization problem by obfuscating potential trade-offs between control decisions that reduce the consumption term at the expense of the demand charge term or vice versa.

Demand charge circuit 156 may modify the optimization problem to incorporate the demand charge term into the linear optimization framework. For example, demand charge circuit 156 may modify the decision matrix x by adding a new decision variable xₚₑₐₖ as follows:

$${x}_{new} = {[ \begin{matrix}… & {u}_{Chiller , elec , 1 ... n} & … & {u}_{hpChiller , elec , 1 ... n} & … & {u}_{Heater , elec , 1 ... n} & … & {x}_{peak}\end{matrix} ]}^{T}$$

where xₚₑₐₖ is the peak power consumption within the demand charge period. Demand charge circuit 156 may modify the cost vector c as follows:

$${c}_{new} = {[ \begin{matrix}… & {c}_{elec , 1 ... n} & … & {c}_{elec , 1 ... n} & … & {c}_{elec , 1 ... n} & … & {c}_{demand}\end{matrix} ]}^{T}$$

such that the demand charge c_{demand} is multiplied by the peak power consumption xₚₑₐₖ.

Demand charge circuit 156 may formulate and/or apply inequality constraints to ensure that the peak power consumption xₚₑₐₖ is greater than or equal to the maximum electric demand over the demand charge period. I.e.:

$${x}_{peak} \geq max ( {u}_{Chiller , elec , k} + {u}_{hpChiller , elec , k} + {u}_{Heater , elec , k} + {P}_{elec , campus , k} ) ∀ k ∈ horizon$$

This inequality constraint may be represented in the linear optimization framework by defining the A matrix and the b vector as follows:

$$A = [ \begin{matrix}⋯ & [ {I}_{h} ] & ⋯ & [ {I}_{h} ] & ⋯ & [ {I}_{h} ] & ⋯ & - 1\end{matrix} ] ,$$

$$b = - {P}_{elec , campus , k}$$

During the high level optimization process, high level optimization circuit 130 may choose a xₚₑₐₖ that is equal to the maximum electrical demand over the demand charge period to minimize the cost associated with xₚₑₐₖ.

Demand charge circuit 156 may apply an inequality constraint to ensure that the peak power consumption decision variable xₚₑₐₖ is greater than or equal to its previous value x_{peak,previous} during the demand charge period. This inequality constraint may be represented in the linear optimization framework by defining the A matrix and the b vector as follows:

$$A = [ \begin{matrix}⋯ & - 1\end{matrix} ] ,$$

$$b = - {x}_{peak , previous}$$

Advantageously, the modifications to the decision variable matrix x, the cost vector c, and the inequality constraints provided by demand charge circuit 156 allow the cost function to be written in a linear form as follows:

$${arg min}_{x} [ {c}_{new}^{T} {x}_{new} ] = {arg min}_{x} [ {c}^{T} x + {c}_{demand} {x}_{peak} ] ; subject to$$

$$Ax \leq b , Hx = g$$

This linear form of the cost function can be used in the linear optimization framework.

The cost function as written in the previous equation has components that are over different time periods. For example, the consumption term c^{T}x is over the consumption period whereas the demand charge term c_{demand}xₚₑₐₖ is over the demand charge period. To properly make the trade-off between increasing the demand charge versus increasing the cost of energy consumption, demand charge circuit 156 may apply a weighting factor to the demand charge term and/or the consumption term. For example, demand charge circuit 156 may divide the consumption term c^{T}x by the duration h of the consumption period (i.e., the time period between the current time and the time horizon) and multiply by the amount of time d_{demand} remaining in the current demand charge period so that the entire cost function is over the demand charge period. The new optimization function may be given by:

$${arg min}_{x} [ \frac{{d}_{demand}}{h} {c}^{T} x + {c}_{demand} {x}_{peak} ] ; subject to$$

$$Ax \leq b , Hx = g which is equivalent to :$$

$${arg min}_{x} [ {c}^{T} x + \frac{h}{{d}_{demand}} {c}_{demand} {x}_{peak} ] ; subject to$$

$$Ax \leq b , Hx = g$$

The latter form of the new optimization function has the advantage of adjusting only one term of the function rather than several.

Still referring to FIG. 4, high level optimization circuit 130 is shown to include a load change penalty circuit 158. In some instances, high level optimization circuit 130 determines a solution to the optimization problem that includes significantly changing the load on one or more of subplants 12-22 within a relatively short timeframe. For example, the lowest cost solution from a resource consumption standpoint may involve taking a subplant from off to full load and back to off again within only a few time steps. This behavior may result from high level optimization circuit 130 identifying small fluctuations in the economic cost of resources and operating central plant 10 accordingly to achieve the minimal economic cost. However, operating central plant 10 in such a way may be undesirable due to various negative effects of rapidly changing the subplant loads (e.g., increased equipment degradation), especially if the cost saved is relatively minimal (e.g., a few cents or dollars).

Load change penalty circuit 158 may modify the optimization problem to introduce a penalty for rapidly changing the subplant loads. For example, load change penalty circuit 158 may modify the decision matrix x by adding a new decision vector for each subplant. The new decision vectors represent the change in subplant load for each subplant from one time step to the next. For example, load change penalty circuit 158 may modify the decision matrix x as follows:

$$x = {[ \begin{matrix}⋯ & {\dot{Q}}_{Chiller , 1 ... n} & ⋯ & {\dot{Q}}_{hrChiller , 1 ... n} & ⋯ & {\dot{Q}}_{Heater , 1 ... n} & ⋯ & {δ}_{Chiller , 1 ... n} & {δ}_{hrChiller , 1 ... n} & {δ}_{Heater , 1 ... n}\end{matrix} ]}^{T}$$

where δ_{Chiller,1 . . . n}, δ_{hrChiller,1 . . . n}, and δ_{Heater,1 . . . n} are n-dimensional vectors representing the change in subplant load for \dot{Q}_{Chiller,1 . . . n}, \dot{Q}_{hrChiller,1 . . . n}, and \dot{Q}_{Heater,1 . . . n}, respectively, at each time step k relative to the previous time step k−1.

Load change penalty circuit 158 may modify the cost vector c to add a cost associated with changing the subplant loads. For example, load change penalty circuit 158 may modify the cost vector c as follows:

$$c = {[ \begin{matrix}⋯ & {0}_{n} & ⋯ & {0}_{n} & ⋯ & {0}_{n} & ⋯ & {c}_{δ Chiller , 1 ... n} & {c}_{δ hrChiller , 1 ... n} & {c}_{δ Heater , 1 ... n}\end{matrix} ]}^{T}$$

Load change penalty circuit 158 may add constraints such that each of the load change variables δ cannot be less than the change in the corresponding subplant load \dot{Q}. For example, the added constraints for chiller subplant 16 may have the following form:

$$A = [ \begin{matrix}⋯ & {I}_{h} - {D}_{- 1} & ⋯ & - [ {I}_{h} ] & [ {0}_{h} ] & [ {0}_{h} ] \\ ⋯ & {D}_{- 1} - {I}_{h} & ⋯ & - [ {I}_{h} ] & [ {0}_{h} ] & [ {0}_{h} ] \\ ⋮ & ⋮ & ⋮ & ⋮ & ⋮ & ⋮\end{matrix} ] ,$$

$$b = [ \begin{matrix}[ \begin{matrix}{\dot{Q}}_{Chiller , old} \\ {0}_{h - 1}\end{matrix} ] \\ [ \begin{matrix}- {\dot{Q}}_{Chiller , old} \\ {0}_{h - 1}\end{matrix} ] \\ ⋮\end{matrix} ]$$

where \dot{Q}_{Chiller,old} is the value for \dot{Q}_{Chiller} at the previous time step. Similar constraints may be added for each of subplants 12-22.

The constraints added by load change penalty circuit 158 require that the load change variables δ are greater than or equal to the magnitude of the difference between the current value of the corresponding subplant load \dot{Q} and the previous value of the subplant load \dot{Q}_{old}. In operation, high level optimization circuit 130 may select values for the load change variables δ that are equal to the magnitude of the difference due to the costs associated with the load change variables. In other words, high level optimization circuit 130 may not choose to make the load change variables δ greater than the actual change in the corresponding subplant load because making the load change variables δ greater than necessary would be suboptimal.

Still referring to FIG. 4, high level optimization circuit 130 is shown to include a tank forced full circuit 160. Tank forced full circuit 160 may modify the optimization problem such that the thermal energy storage (TES) tanks are forced to full at the end of the optimization period. This feature provides increased robustness in the event of a subplant failure and/or controller failure by ensuring that the TES tanks have sufficient stored thermal energy to satisfy building loads while the failure is being repaired. For example, plant operators can use the stored thermal energy to meet the building loads while central plant controller 102 is brought back online.

Tank forced full circuit 160 may force the TES tanks to full by increasing the cost of discharging the TES tanks. In some embodiments, tank forced full circuit 160 modifies the cost of discharging the TES tanks such that the discharge cost is higher than other costs in the cost function, but less than the cost of unmet loads. This forces high level optimization circuit 130 to take the benefit (i.e., negative cost) of charging the TES tanks to their maximum values.

Referring now to FIGS. 5A-B, two subplant curves 500 and 510 are shown, according to an exemplary embodiment. Subplant curves 500 and 510 may be used as subplant curves 140, as described with reference to FIG. 3. Subplant curves 500 and 510 define the resource usage of a subplant (e.g., one of subplants 12-22) as a function of the subplant load. Each subplant curve may be specific to a particular subplant and a particular type of resource used by the subplant. For example, subplant curve 500 may define the electricity use 502 of chiller subplant 16 as a function of the load 504 on chiller subplant 16, whereas subplant curve 510 may define the water use 506 of chiller subplant 16 as a function of the load 504 on chiller subplant 16. Each of subplants 12-22 may have one or more subplant curves (e.g., one for each type of resource consumed by the subplant).

In some embodiments, low level optimization circuit 132 generates subplant curves 500 and 510 based on equipment models 120 (e.g., by combining equipment models 120 for individual devices into an aggregate curve for the subplant). Low level optimization circuit 132 may generate subplant curves 500 and 510 by running the low level optimization process for several different loads and weather conditions to generate multiple data points. Low level optimization circuit 132 may fit a curve to the data points to generate the subplant curves. In other embodiments, low level optimization circuit 132 provides the data points to high level optimization circuit 132 and high level optimization circuit 132 generates the subplant curves using the data points.

Referring now to FIG. 6, another subplant curve 600 is shown, according to an exemplary embodiment. Subplant curve 600 defines the electricity use of chiller subplant 16 (i.e., u_{Chiller,elec}) as a function of the cold water production of chiller subplant 16 (i.e., \dot{Q}_{Chiller}). In some embodiments, subplant curve 600 is generated by combining efficiency curves for individual devices of chiller subplant 16 (e.g., individual chillers, pumps, etc.). For example, each of the chillers in subplant 16 may have a device-specific efficiency curve that defines the amount of electricity use by the chiller as a function of the load on the chiller. Many devices operate less efficiently at higher loads and have device efficiency curves that are U-shaped functions of load. Accordingly, combining multiple device efficiency curves to form subplant curve 600 may result in subplant curve 600 having one or more waves 602, as shown in FIG. 6. Waves 602 may be caused by a single device loading up before it is more efficient to turn on another device to satisfy the subplant load.

Referring now to FIG. 7, a linearized subplant curve 700 is shown, according to an exemplary embodiment. Subplant curve 700 defines the electricity use of chiller subplant 16 (i.e., u_{Chiller,elec}) as a function of the cold water production of chiller subplant 16 (i.e., \dot{Q}_{Chiller}). Subplant curve 700 may be generated by converting subplant curve 600 into a linearized convex curve. A convex curve is a curve for which a line connecting any two points on the curve is always above or along the curve (i.e., not below the curve). Convex curves may be advantageous for use in the high level optimization because they allow for an optimization process that is less computationally expensive relative to an optimization process that uses non-convex functions.

In some embodiments, subplant curve 700 is generated by subplant curve linearizer 176, as described with reference to FIG. 4. Subplant curve 700 may be created by generating a plurality of linear segments (i.e., segments 702, 704, and 706) that approximate subplant curve 600 and combining the linear segments into a piecewise-defined linearized convex curve 700. Linearized subplant curve 700 is shown to include a first linear segment 702 connecting point [u₁, Q₁] to point [u₂, Q₂], a second linear segment 704 connecting point [u₂, Q₂] to point [u₃, Q₃], and a third linear segment 706 connecting point [u₃, Q₃] to point [u₄, Q₄]. The endpoints of line segments 702-706 may be used to form constraints that force the electricity use of chiller subplant 16 in the epigraph of the linearized subplant curve 700.

Referring now to FIG. 8, another subplant curve 800 is shown, according to an exemplary embodiment. Subplant curve 800 defines the energy use of one of subplants 12-22 as a function of the load on the subplant for several different weather conditions. In some embodiments, subplant curve 800 is generated by subplant curves circuit 170 using experimental data obtained from the low level optimization circuit 132. For example, subplant curve updater 172 may request resource usage data from low level optimization circuit 132 for various combinations of load conditions and environmental conditions. In the embodiment shown in FIG. 8, subplant curve updater 172 requests energy use data for each combination of temperature (e.g., 40° F., 50° F., 60° F., and 70° F.) and load (e.g., 170 tons, 330 tons, 500 tons, 830 tons, and 1000 tons). Low level optimization circuit 132 may perform the low level optimization process for the requested load and temperature combinations and return an energy use value for each combination.

Subplant curve updater 172 may use the data points provided by low level optimization circuit 132 to find the best piecewise linear convex function that fits the data. For example, subplant curve updater 172 may fit a first subplant curve 802 to the data points at 70° F., a second subplant curve 804 to the data points at 60° F., a third subplant curve 806 to the data points at 50° F., and a fourth subplant curve 808 to the data points at 40° F. Subplant curve updater 172 may store the generated subplant curves 802-808 in subplant curves database 174 for use in the high level optimization algorithm.

In some implementations, central plant controller 102 uses high level optimization circuit 130 as part of an operational tool to exercise real-time control over central plant 10. In the operational tool, high level optimization circuit 130 may receive load and rate predictions from load/rate prediction circuit 122 and subplant curves (or data that can be used to generate subplant curves) from low level optimization circuit 132. When implemented in the operational tool, high level optimization circuit 130 may determine optimal subplant loads for heater subplant 12, heat recovery chiller subplant 14, chiller subplant 16, hot TES subplant 20, and/or cold TES subplant 22, as described with reference to FIGS. 2-4. In some embodiments, high level optimization circuit 130 determines ground loop and heat exchanger transfer rates in addition to the subplant loads. When implemented in the operational tool, high level optimization circuit 130 may provide the determined subplant loads and/or transfer rates to low level optimization circuit 132 for use in determining optimal on/off decisions and/or operating setpoints for the equipment of each subplant.

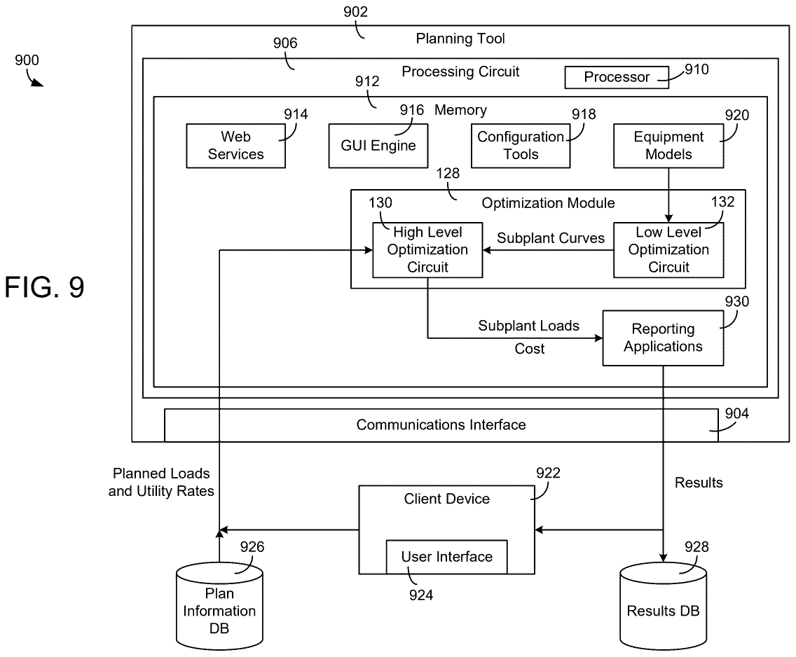

Referring now to FIG. 9, a block diagram of a planning system 900 is shown, according to an exemplary embodiment. Planning system 900 may be configured to use optimization circuit 128 and/or the optimal allocator 1620 described herein as part of a planning tool 902 to simulate the operation of a central plant over a predetermined time period (e.g., a day, a month, a week, a year, etc.) for planning, budgeting, and/or design considerations. When implemented in planning tool 902, optimization circuit 128 may operate in a similar manner as described with reference to FIGS. 2-4. For example, optimization circuit 128 may use building loads and utility rates to determine an optimal subplant load distribution to minimize cost over a simulation period. However, planning tool 902 may not be responsible for real-time control of a building automation system or central plant.

In planning tool 902, high level optimization circuit 130 may receive planned loads, hardware utilization rates, total computations, and/or utility rates for the entire simulation period. The planned loads and utility rates may be defined by input received from a user via a client device 922 (e.g., user-defined, user selected, etc.) and/or retrieved from a plan information database 926. High level optimization circuit 130 uses the planned loads and utility rates in conjunction with subplant curves from low level optimization circuit 132 to determine optimal subplant loads (i.e., an optimal dispatch schedule) for a portion of the simulation period.

The portion of the simulation period over which high level optimization circuit 130 optimizes the subplant loads may be defined by a prediction window ending at a time horizon. With each iteration of the optimization, the prediction window is shifted forward and the portion of the dispatch schedule no longer in the prediction window is accepted (e.g., stored or output as results of the simulation). Load and rate predictions may be predefined for the entire simulation and may not be subject to adjustments in each iteration. However, shifting the prediction window forward in time may introduce additional plan information (e.g., planned loads and/or utility rates) for the newly-added time slice at the end of the prediction window. The new plan information may not have a significant effect on the optimal dispatch schedule since only a small portion of the prediction window changes with each iteration.

In some embodiments, high level optimization circuit 130 requests all of the subplant curves used in the simulation from low level optimization circuit 132 at the beginning of the simulation. Since the planned loads and environmental conditions are known for the entire simulation period, high level optimization circuit 130 may retrieve all of the relevant subplant curves at the beginning of the simulation. In some embodiments, low level optimization circuit 132 generates functions that map subplant production to equipment level production and resource use when the subplant curves are provided to high level optimization circuit 130. These subplant to equipment functions may be used to calculate the individual equipment production and resource use (e.g., in a post-processing circuit) based on the results of the simulation.

Still referring to FIG. 9, planning tool 902 is shown to include a communications interface 904 and a processing circuit 906. Communications interface 904 may include wired or wireless interfaces (e.g., jacks, antennas, transmitters, receivers, transceivers, wire terminals, etc.) for conducting data communications with various systems, devices, or networks. For example, communications interface 904 may include an Ethernet card and port for sending and receiving data via an Ethernet-based communications network and/or a Wi-Fi transceiver for communicating via a wireless communications network. Communications interface 904 may be configured to communicate via local area networks or wide area networks (e.g., the Internet, a building WAN, etc.) and may use a variety of communications protocols (e.g., BACnet, IP, LON, etc.).

Communications interface 904 may be a network interface configured to facilitate electronic data communications between planning tool 902 and various external systems or devices (e.g., client device 922, results database 928, plan information database 926, etc.). For example, planning tool 902 may receive planned loads and utility rates from client device 922 and/or plan information database 926 via communications interface 904. Planning tool 902 may use communications interface 904 to output results of the simulation to client device 922 and/or to store the results in results database 928.

Still referring to FIG. 9, processing circuit 906 is shown to include a processor 910 and memory 912. Processor 910 may be a general purpose or specific purpose processor, an application specific integrated circuit (ASIC), one or more field programmable gate arrays (FPGAs), a group of processing components, or other suitable processing components. Processor 910 may be configured to execute computer code or instructions stored in memory 912 or received from other computer readable media (e.g., CDROM, network storage, a remote server, etc.).

Memory 912 may include one or more devices (e.g., memory units, memory devices, storage devices, etc.) for storing data and/or computer code for completing and/or facilitating the various processes described in the present disclosure. Memory 912 may include random access memory (RAM), read-only memory (ROM), hard drive storage, temporary storage, non-volatile memory, flash memory, optical memory, or any other suitable memory for storing software objects and/or computer instructions. Memory 912 may include database components, object code components, script components, or any other type of information structure for supporting the various activities and information structures described in the present disclosure. Memory 912 may be communicably connected to processor 910 via processing circuit 906 and may include computer code for executing (e.g., by processor 906) one or more processes described herein.

Still referring to FIG. 9, memory 912 is shown to include a GUI engine 926, web services 914, and configuration tools 918. In an exemplary embodiment, GUI engine 916 includes a graphical user interface component configured to provide graphical user interfaces to a user for selecting or defining plan information for the simulation (e.g., planned loads, utility rates, environmental conditions, etc.). Web services 914 may allow a user to interact with planning tool 902 via a web portal and/or from a remote system or device (e.g., an enterprise control application).

Configuration tools 918 can allow a user to define (e.g., via graphical user interfaces, via prompt-driven “wizards,” etc.) various parameters of the simulation such as the number and type of subplants, the devices within each subplant, the subplant curves, device-specific efficiency curves, the duration of the simulation, the duration of the prediction window, the duration of each time step, and/or various other types of plan information related to the simulation. Configuration tools 918 can present user interfaces for building the simulation. The user interfaces may allow users to define simulation parameters graphically. In some embodiments, the user interfaces allow a user to select a pre-stored or pre-constructed simulated plant and/or plan information (e.g., from plan information database 926) and adapt it or enable it for use in the simulation.

Still referring to FIG. 9, memory 912 is shown to include optimization circuit 128. Optimization circuit 128 may use the planned loads and utility rates to determine optimal subplant loads over a prediction window. The operation of optimization circuit 128 may be the same or similar as previously described with reference to FIGS. 2-4. With each iteration of the optimization process, optimization circuit 128 may shift the prediction window forward and apply the optimal subplant loads for the portion of the simulation period no longer in the prediction window. Optimization circuit 128 may use the new plan information at the end of the prediction window to perform the next iteration of the optimization process. Optimization circuit 128 may output the applied subplant loads to reporting applications 930 for presentation to a client device 922 (e.g., via user interface 924) or storage in results database 928.

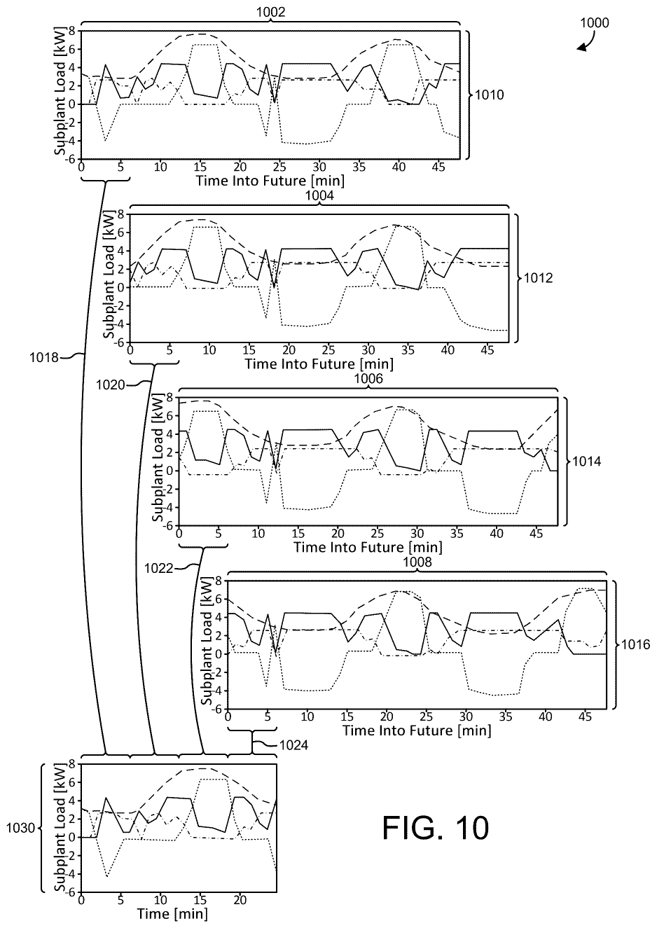

Still referring to FIG. 9, memory 912 is shown to include reporting applications 930. Reporting applications 930 may receive the optimized subplant loads from optimization circuit 128 and, in some embodiments, costs associated with the optimized subplant loads. Reporting applications 930 may include a web-based reporting application with several graphical user interface (GUI) elements (e.g., widgets, dashboard controls, windows, etc.) for displaying key performance indicators (KPI) or other information to users of a GUI. In addition, the GUI elements may summarize relative energy use and intensity across various plants, subplants, or the like. Other GUI elements or reports may be generated and shown based on available data that allow users to assess the results of the simulation. The user interface or report (or underlying data engine) may be configured to aggregate and categorize subplant loads and the costs associated therewith and provide the results to a user via a GUI. The GUI elements may include charts or histograms that allow the user to visually analyze the results of the simulation. An exemplary output that may be generated by reporting applications 930 is shown in FIG. 10.

Referring now to FIG. 10, several graphs 1000 illustrating the operation of planning tool 902 are shown, according to an exemplary embodiment. With each iteration of the optimization process, planning tool 902 selects an optimization period (i.e., a portion of the simulation period) over which the optimization is performed. For example, planning tool 902 may select optimization period 1002 for use in the first iteration. Once the optimal load distribution 1010 (e.g., a heat allocation) has been determined, planning tool 902 may select a portion 1018 of load distribution 1010 to send to plant dispatch 1030. Portion 1018 may be the first b time steps of load distribution 1010. Planning tool 902 may shift the optimization period 1002 forward in time, resulting in optimization period 1004. The amount by which the prediction window is shifted may correspond to the duration of time steps b.

Planning tool 902 may repeat the optimization process for optimization period 1004 to determine the optimal plant load distribution 1012. Planning tool 902 may select a portion 1020 of plant load distribution 1012 to send to plant dispatch 1030. Portion 1020 may be the first b time steps of load distribution 1012. Planning tool 902 may then shift the prediction window forward in time, resulting in optimization period 1006. This process may be repeated for each subsequent optimization period (e.g., optimization periods 1006, 1008, etc.) to generate updated load distributions (e.g., load distributions 1014, 1016, etc.) and to select portions of each load distribution (e.g., portions 1022, 1024) to send to plant dispatch 1030. Plant dispatch 1030 includes the first b time steps 1018-1024 from each of optimization periods 1002-1008. Once the optimal subplant load distribution 1030 is compiled for the entire simulation period, the results may be sent to reporting applications 930, results database 928, and/or client device 922, as described with reference to FIG. 9.

Referring now to FIG. 11, a flowchart of a process 1100 for optimizing cost in a central plant is shown, according to an exemplary embodiment. In various implementations, process 1100 may be performed by central plant controller 102 or planning tool 902. The central plant may include a plurality of subplants (e.g., subplants 12-22) configured to serve the energy loads of a building or campus. The central plant may be an actual plant (e.g., central plant 10) or a simulated central plant including a plurality of simulated subplants.

Process 1100 is shown to include receiving load prediction data and utility rate data (step 1102). The load prediction data may include predicted or planned thermal energy loads for a building or campus for each time step k (e.g., k=1 . . . n) of an optimization period. The load prediction data may include predicted or planned values one or more different types of loads for the building or campus. For example, the load prediction data may include a predicted hot water load [symbol] and a predicted cold water load [symbol] for each time step k within the prediction window.

In some embodiments, the load prediction data are based on weather forecasts from a weather service and/or feedback from the building or campus. Feedback from the building or campus may include various types of sensory inputs (e.g., temperature, flow, humidity, enthalpy, etc.) or other data relating to the controlled building (e.g., inputs from a HVAC system, a lighting control system, a security system, a water system, etc.). The load predictions may also be based on predictions of heat generated by data center equipment, for example as described herein with reference to data center heat prediction circuit 300. In some embodiments, the load prediction data are generated by load/rate prediction circuit 122, as described with reference to FIG. 2. For example, the load prediction data may be based on a measured electric load and/or previous measured load data from the building or campus. The load prediction data may be a function of a given weather forecast (\hat{φ}_{w}), a day type (day), the time of day (t), and/or previous measured load data (Yₖ₋₁). Such a relationship is expressed in the following equation:

$${\hat{ℓ}}_{k} = f ( {\hat{ϕ}}_{w} , day , t \vert {Y}_{k - 1} )$$

The utility rate data may indicate a cost or price per unit of one or more resources (e.g., electricity, natural gas, water, etc.) consumed by the central plant to serve the thermal energy loads of the building or campus at each time step k in the prediction window. In some embodiments, the utility rates are time-variable rates. For example, the price of electricity may be higher at certain times of day or days of the week (e.g., during high demand periods) and lower at other times of day or days of the week (e.g., during low demand periods). The utility rates may define various time periods and a cost per unit of a resource during each time period. Utility rates may be actual rates (e.g., received from utilities 126) or predicted utility rates (e.g., estimated by load/rate prediction circuit 122).

In some embodiments, the utility rates include demand charges for one or more of the resources consumed by the central plant. A demand charge may define a separate cost based on the maximum usage of a particular resource (e.g., maximum energy consumption) during a demand charge period. The utility rates may define various demand charge periods and one or more demand charges associated with each demand charge period. In some instances, demand charge periods may overlap partially or completely with each other and/or with the prediction window. The utility rate data may include time-variable (e.g., hourly) prices, a maximum service level (e.g., a maximum rate of consumption allowed by the physical infrastructure or by contract) and, in the case of electricity, a demand charge or a charge for the peak rate of consumption within a certain period.

Still referring to FIG. 11, process 1100 is shown to include generating an objective function that expresses a total monetary cost of operating the central plant as a function of the utility rate data and an amount of resources consumed by the central plant (step 1104). In some embodiments, the objective function is a high level cost function J_{HL} for the central plant. The high level cost function J_{HL} may represent the sum of the monetary costs of each utility consumed by the central plant for the duration of the optimization period. For example, the high level cost function J_{HL} may be described using the following equation:

$${J}_{HL} ( {θ}_{HL} ) = {\sum }_{k = 1}^{{n}_{h}} {\sum }_{i = 1}^{{n}_{s}} [ {\sum }_{j = 1}^{{n}_{u}} {t}_{s} \cdot {c}_{jk} {u}_{jik} ( {θ}_{HL} ) ]$$

where nₕ is the number of time steps k in the optimization period, nₛ is the number of subplants, tₛ is the duration of a time step, cⱼₖ is the economic cost of utility j at a time step k of the optimization period, and uⱼᵢₖ is the rate of use of utility j by subplant i at time step k.

In some embodiments, the objective function is generated using a linear programming framework. For example, step 1104 may include generating an objective function of the form:

$${arg min}_{x} {c}^{T} x ; subject to Ax \leq b , Hx = g$$

where c is a cost vector, x is a decision matrix, A and b are a matrix and vector (respectively) which describe inequality constraints on the variables in the decision matrix x, and H and g are a matrix and vector (respectively) which describe equality constraints on the variables in the decision matrix x. In other embodiments, the objective function may be generated using any of a variety of other optimization frameworks (e.g., quadratic programming, linear-fractional programming, nonlinear programming, combinatorial algorithms, etc.).

In some embodiments, step 1104 includes formulating the decision matrix x. The loads across each of subplants 12-22 may be the decision variables in the decision matrix x. For example, for a central plant that includes chillers, heat recovery chillers, hot water generators, and thermal energy storage, step 1104 may include formulating the decision matrix x as:

$$x = {[ \begin{matrix}{\dot{Q}}_{Chiller , 1 ... n} , & {\dot{Q}}_{hrChiller , 1 ... n} , & {\dot{Q}}_{Heater , 1 ... n} , & {\dot{Q}}_{HotStorage , 1 ... n} , & {\dot{Q}}_{ColdStorage , 1 ... n}\end{matrix} ]}^{T}$$

where \dot{Q}_{Chiller,1 . . . n}, \dot{Q}_{hrChiller,1 . . . n}, \dot{Q}_{Heater,1 . . . n}, \dot{Q}_{HotStorage,1 . . . n}, and \dot{Q}_{Coldstorage,1 . . . n} are n-dimensional vectors representing the thermal energy load assigned to chiller subplant 16, heat recovery chiller subplant 14, heater subplant 12, hot TES subplant 20, and cold TES subplant 22, respectively, for each of the n time steps within the optimization period.

In some embodiments, step 1104 includes generating the decision matrix x to include one or more decision vectors representing the resource consumption of each subplant. For example, for a central plant that includes a chiller subplant, step 1104 may include generating the decision matrix x as follows:

$$x = {[ \begin{matrix}⋯ & {\dot{Q}}_{Chiller , 1 ... n} & ⋯ & {u}_{Chiller , elec , 1 ... n} & {u}_{Chiller , water , 1 ... n} & ⋯\end{matrix} ]}^{T}$$

where u_{Chiller,elec,1 . . . n} and u_{Chiller,water,1 . . . n} are n-dimensional vectors representing the amount of electrical consumption and water consumption, respectively, by the chiller subplant at each time step k.

Step 1104 may include adding one or more resource consumption vectors to matrix x for each of subplants 12-22. The decision vectors added in step 1104 for a given subplant may represent an amount of resource consumption for each resource consumed by the subplant (e.g., water, electricity, natural gas, etc.) at each time step k within the optimization period. For example, if a heater subplant consumes natural gas, electricity, and water, step 1104 may include adding a decision vector u_{Heater,gas,1 . . . n} representing an amount of natural gas consumed by the heater subplant at each time step, a decision vector u_{Heater,elec,1 . . . n} representing an amount of electricity consumed by the heater subplant at each time step, and a decision vector u_{Heater,water,1 . . . n} representing an amount of water consumed by the heater subplant at each time step. Step 1104 may include adding resource consumption vectors for other subplants in a similar manner.

In some embodiments, step 1104 includes generating the cost vector c. Generating the cost vector c may include adding economic costs associated with the resource consumption required to produce the subplant loads. For example, the decision matrix x provided above, step 1104 may include generating the cost vector c as follows:

$$c = {[ \begin{matrix}⋯ & {0}_{n} & ⋯ & {c}_{elec , 1 ... n} & {c}_{water , 1 ... n} & ⋯\end{matrix} ]}^{T}$$

where 0ₙ is a n-dimensional zero vector indicating that the direct economic cost of \dot{Q}_{Chiller,1 . . . n} is zero at each time step, c_{elec,1 . . . n} is a n-dimensional vector indicating the per unit cost of electricity at each time step, and c_{water,1 . . . n} is a n-dimensional vector indicating the per unit cost of water at each time step. The cost vector associates an economic cost with the resources consumed to produce the subplant loads rather than the subplant loads themselves. In some embodiments, the values for c_{elec,1 . . . n} and c_{water,1 . . . n} are utility rates obtained from the utility rate data received in step 1102.

In some embodiments, step 1104 includes generating the A matrix and the b vector which describe the inequality constraints, and the H matrix and the g vector which describe the equality constraints. The inequality constraints and equality constraints may be generated by inequality constraints circuit 146 and equality constraints circuit 148, as described with reference to FIG. 4. For example, step 1104 may include generating inequality constraints that constrain the decision variables in matrix x to be less than or equal to maximum capacities for the corresponding central plant equipment and less than or equal to maximum charge/discharge rates for thermal energy storage. Step 1104 may include generating inequality constraints that prevent charging the thermal energy storage above maximum capacity and/or discharging the thermal energy storage below zero. Step 1104 may include generating equality constraints that ensure the building energy loads are satisfied at each of the time steps in the prediction window.

In some embodiments, step 1104 includes modifying the objective function to account for unmet loads (e.g., as described with reference to unmet loads circuit 150), to account for heat extraction or rejection to a ground loop (e.g., as described with reference to ground loop circuit 152), to account for heat exchange between the hot water loop and the condenser water loop (e.g., as described with reference to heat exchanger circuit 154), to account for subplant curves that are not simple linear functions of load (e.g., as described with reference to subplant curves circuit 170), and/or to force the thermal energy storage tanks to full at the end of the prediction window (e.g., as described with reference to tank forced full circuit 160). Modifying the objective function may include modifying the decision matrix x, the cost vector c, the A matrix and the b vector which describe the inequality constraints, and/or the H matrix and the g vector which describe the equality constraints.

Still referring to FIG. 11, process 1100 is shown to include modifying the objective function to account for a demand charge (step 1106). Step 1106 is an optional step that may be performed by demand charge circuit 156 to account for a demand charge that may be imposed by utility providers in some pricing scenarios. The demand charge is an additional charge imposed by some utility providers based on the maximum rate of energy consumption during an applicable demand charge period. For example, the demand charge may be provided in terms of dollars per unit of power (e.g., $/kW) and may be multiplied by the peak power usage (e.g., kW) during a demand charge period to calculate the demand charge.

Accounting for the demand charge may include modifying the various components of the objective function such as the decision matrix x, the cost vector c, and/or the A matrix and the b vector which describe the inequality constraints. The modified objective function may be defined as:

$${arg min}_{x} [ {c}^{T} x + {c}_{demand} max ( {P}_{elec , k} ) ] ; subject to Ax \leq b , Hx = g$$

where c_{demand} is the demand charge for the applicable demand charge period and P_{elec,k} is the total electrical power consumption of the central plant and the building/campus at time step k. The term max (P_{elec,k}) selects the peak electrical power consumption at any time during the demand charge period. The demand charge c_{demand} and the demand charge period may be defined by the utility rate information received in step 1102.

Step 1106 may include modifying the decision matrix x by adding a new decision variable xₚₑₐₖ as follows:

$${x}_{new} = {[ \begin{matrix}⋯ & {u}_{Chiller , elec , 1 … n} & ⋯ & {u}_{hpChiller , elec , 1 … n} & ⋯ & {u}_{Heater , elec , 1 … n} & ⋯ & {x}_{peak}\end{matrix} ]}^{T}$$

where xₚₑₐₖ is the peak power consumption within the optimization period. Step 1106 may include modifying the cost vector c as follows:

$${c}_{new} = {[ \begin{matrix}⋯ & {c}_{elec , 1 … n} & ⋯ & {c}_{elec , 1 … n} & ⋯ & {c}_{elec , 1 … n} & ⋯ & {c}_{demnad}\end{matrix} ]}^{T}$$

such that the demand charge c_{demand} is multiplied by the peak power consumption xₚₑₐₖ.

Step 1106 may include generating and/or imposing inequality constraints to ensure that the peak power consumption xₚₑₐₖ is greater than or equal to the maximum electric demand for each time step in the optimization period. I.e.:

$${x}_{peak} \geq max ( {u}_{Chiller , elec , k} + {u}_{hpChiller , elec , k} + {u}_{Heater , elec , k} + {P}_{elec , campus , k} ) ∀ k ∈ horizon$$

This inequality constraint may be represented in the linear optimization framework by defining the A matrix and the b vector as follows:

$$A = [ \begin{matrix}⋯ & [ {I}_{h} ] & ⋯ & [ {I}_{h} ] & ⋯ & [ {I}_{h} ] & ⋯ & - 1\end{matrix} ] , b = - {P}_{elec , campus , k}$$

Step 1106 may include generating and/or imposing an inequality constraint to ensure that the peak power consumption decision variable xₚₑₐₖ is greater than or equal to its previous value x_{peak,previous} during the demand charge period. This inequality constraint may be represented in the linear optimization framework by defining the A matrix and the b vector as follows:

$$A = [ \begin{matrix}⋯ & - 1\end{matrix} ] , b = - {x}_{peak , previous}$$

Advantageously, the modifications to the decision variable matrix x, the cost vector c, and the inequality constraints in step 1106 may allow the objective function to be written in a linear form as follows:

$${arg min}_{x} [ {c}_{new}^{T} {x}_{new} ] = {arg min}_{x} [ {c}^{T} x + {c}_{demand} {x}_{peak} ] ; subject to Ax \leq b , Hx = g$$

This linear form of the objective function can be used in the linear optimization framework.

In some embodiments, step 1106 includes applying a weighting factor to at least one of the consumption term and the demand charge term of the objective function. For example, the objective function as written in the previous equation has components that are over different time periods. The consumption term c^{T}x is over the consumption period whereas the demand charge term c_{demand}xₚₑₐₖ is over the demand charge period. To properly make the trade-off between increasing the demand charge versus increasing the cost of energy consumption, step 1106 may include applying a weighting factor to the demand charge term and/or the consumption term. For example, step 1106 may include dividing the consumption term c^{T}x by the duration h of the consumption period (i.e., the time period between the current time and the time horizon) and multiplying by the amount of time d_{demand} remaining in the current demand charge period so that the entire objective function is over the demand charge period. The new optimization function may be given by:

$${arg min}_{x} [ {c}^{T} x + \frac{{d}_{demand}}{h} {c}^{T} x + {c}_{demand} {x}_{peak} ] ; subject to Ax \leq b , Hx = g$$

which is equivalent to:

$${arg min}_{x} [ {c}^{T} x + \frac{h}{{d}_{demand}} {c}_{demand} {x}_{peak} ] ; subject to Ax \leq b , Hx = g$$

The latter form of the new optimization function has the advantage of adjusting only one term of the function rather than several.

Still referring to FIG. 11, process 1100 is shown to include modifying the objective function to account for a load change penalty (step 1108). Step 1108 is an optional step that may be performed by load change penalty circuit 158 to account for the cost of changing the loads assigned to each of the subplants. In some instances, the lowest cost solution from a resource consumption standpoint may involve taking a subplant from off to full load and back to off again within only a few time steps. However, operating the central plant in such a way may be undesirable due to various negative effects of rapidly changing the subplant loads (e.g., increased equipment degradation), especially if the cost saved is relatively minimal (e.g., a few cents or dollars).

Step 1108 may include modifying the objective function to introduce a penalty for rapidly changing the subplant loads. In some embodiments, step 1108 includes modifying the decision matrix x by adding a new decision vector for each subplant. The new decision vectors represent the change in subplant load for each subplant from one time step to the next. For example, step 1108 may include modifying the decision matrix x as follows:

$$x = {[ \begin{matrix}… & {\dot{Q}}_{Chiller , 1 … n} & … & {\dot{Q}}_{hrChiller , 1 … n} & ⋯ & {\dot{Q}}_{Heater , 1 … n} & ⋯ & {δ}_{Chiller , 1 … n} & {δ}_{hrChiller , 1 … n} & {δ}_{Heater , 1 … n}\end{matrix} ]}^{T}$$

where δ_{Chiller,1 . . . n}, δ_{hrChiller,1 . . . n}, and δ_{Heater,1 . . . n} are n-dimensional vectors representing the change in subplant load for \dot{Q}_{Chiller,1 . . . n}, \dot{Q}_{hrChiller,1 . . . n}, and \dot{Q}_{Heater,1 . . . n}, respectively, at each time step k relative to the previous time step k−1.

Step 1108 may include modifying the cost vector c to add a cost associated with changing the subplant loads. For example, step 1108 may include modifying the cost vector c as follows:

$$c = {[ \begin{matrix}⋯ & {0}_{n} & ⋯ & {0}_{n} & ⋯ & {0}_{n} & ⋯ & {c}_{δ Chiller , 1 … n} & {c}_{δ hr Chiller , 1 … n} & {c}_{δ Heater , 1 … n}\end{matrix} ]}^{T}$$

Step 1108 may include adding constraints such that each of the load change variables δ cannot be less than the change in the corresponding subplant load \dot{Q}. For example, the added constraints for a chiller subplant may have the following form:

$$A = [ \begin{matrix}⋯ & {I}_{h} - {D}_{- 1} & ⋯ & - [ {I}_{h} ] & [ {0}_{h} ] & [ {0}_{h} ] \\ ⋯ & {D}_{- 1} - {I}_{h} & ⋯ & - [ {I}_{h} ] & [ {0}_{h} ] & [ {0}_{h} ] \\ ⋮ & ⋮ & ⋮ & ⋮ & ⋮ & ⋮\end{matrix} ] , b = [ \begin{matrix}[ \begin{matrix}{\dot{Q}}_{Chiller , old} \\ {0}_{h - 1}\end{matrix} ] \\ [ \begin{matrix}- {\dot{Q}}_{Chiller , old} \\ {0}_{h - 1} \\ ⋮\end{matrix} ]\end{matrix} ]$$

where \dot{Q}_{Chiller,old} is the value for \dot{Q}_{Chiller} at the previous time step. Similar constraints may be added for each of subplants 12-22. The constraints added by in step 1108 may require that the load change variables & are greater than or equal to the magnitude of the difference between the current value of the corresponding subplant load Q and the previous value of the subplant load \dot{Q}_{old}.

Still referring to FIG. 11, process 1100 is shown to include optimizing the objective function over an optimization period subject to a set of constraints to determine an optimal distribution of energy loads over multiple groups of central plant equipment (step 1110). The set of constraints may include the inequality constraints and the equality constraints formulated in steps 1104, 1106, and/or 1108. Optimizing the objective function may include determining an optimal decision matrix x* that minimizes the cost function c^{T}x. The optimal decision matrix x* may correspond to the optimal decisions

$${θ}_{HL}^{*}$$

(for each time step k within an optimization period) that minimize the high level cost function J_{HL}, as described with reference to FIG. 3.

Step 1110 may include using any of a variety of linear optimization techniques to determine the optimal decision matrix. For example, step 1110 may include using basis exchange algorithms (e.g., simplex, crisscross, etc.), interior point algorithms (e.g., ellipsoid, projective, path-following, etc.), covering and packing algorithms, integer programming algorithms (e.g., cutting-plant, branch and bound, branch and cut, branch and price, etc.), or any other type of linear optimization algorithm or technique to solve for the optimal decision matrix subject to the optimization constraints. For embodiments in which nonlinear optimization is used, step 1110 may include using any of a variety of nonlinear optimization techniques to solve for the optimal decision matrix. The result of step 1110 may be an optimal distribution of energy loads over the multiple groups of subplant equipment (i.e., the multiple subplants) for each of the time steps k.

Still referring to FIG. 11, process 1100 is shown to include using the optimal distribution of energy loads to determine optimal operating statuses for individual devices of the central plant equipment (step 1112). In some embodiments, step 1112 is performed by low level optimization circuit 132, as described with reference to FIGS. 2-4. For example, step 1112 may include using the subplant loads determined in step 1110 to determine optimal low level decisions

$${θ}_{L L}^{*}$$

(e.g. binary on/off decisions, flow setpoints, temperature setpoints, etc.) for the central plant equipment. In some embodiments, step 1112 is performed for each of the plurality of subplants.

Step 1112 may include determining which devices of each subplant to use and/or the operating setpoints for such devices that will achieve the subplant load setpoint while minimizing energy consumption. The low level optimization performed in step 1112 may be described using the following equation:

$${θ}_{LL}^{*} = arg {min}_{{θ}_{LL}} {J}_{LL} ( {θ}_{LL} )$$

where

$${θ}_{LL}^{*}$$

contains the optimal low level decisions and J_{LL} is the low level cost function.

To find the optimal low level decisions

$${θ}_{LL}^{*} ,$$

step 1112 may include minimizing the low level cost function J_{LL}. The low level cost function J_{LL} may represent the total energy consumption for all of the equipment in the applicable subplant. The low level cost function J_{LL} may be described using the following equation:

$${J}_{LL} ( {θ}_{LL} ) = {\sum }_{j = 1}^{N} {t}_{s} \cdot {b}_{j} \cdot {u}_{j} ( {θ}_{LL} )$$

where N is the number of devices of in the subplant, tₛ is the duration of a time step, bⱼ is a binary on/off decision (e.g., 0=off, 1=on), and uⱼ is the energy used by device j as a function of the setpoint θ_{LL}. Each device may have continuous variables which can be changed to determine the lowest possible energy consumption for the overall input conditions.

In some embodiments, step 1112 includes minimizing the low level cost function J_{LL} subject to inequality constraints based on the capacities of the subplant equipment and equality constraints based on energy and mass balances. In some embodiments, the optimal low level decisions

$${θ}_{L L}^{*}$$

are constrained by switching constraints defining a short horizon for maintaining a device in an on or off state after a binary on/off switch. The switching constraints may prevent devices from being rapidly cycled on and off.

Step 1112 may include determining optimum operating statuses (e.g., on or off) for a plurality of devices of the central plant equipment. According to an exemplary embodiment, the on/off combinations may be determined using binary optimization and quadratic compensation. Binary optimization may minimize a cost function representing the power consumption of devices in the applicable subplant. In some embodiments, non-exhaustive (i.e., not all potential combinations of devices are considered) binary optimization is used. Quadratic compensation may be used in considering devices whose power consumption is quadratic (and not linear).

Step 1112 may include determining optimum operating setpoints for equipment using nonlinear optimization. Nonlinear optimization may identify operating setpoints that further minimize the low level cost function J_{LL}. In some embodiments, step 1112 includes providing the on/off decisions and setpoints to building automation system 108 for use in controlling the central plant equipment 60.

### Liquid Cooling for Data Center

Referring now to FIG. 12, a schematic illustration of a system 1200 that provides liquid cooling for a data center is shown, according to an exemplary embodiment. As described in detail above, the central plant 10 is configured to generate chilled fluid (e.g., water) that can be provide to a building, including to a data center. In the system 1200, the chilled fluid is used for liquid cooling of the data center. In the example shown the central plant 10 provides chilled fluid to a data center via a pipe (or other fluid pathway) 1212. The fluid is also returned to the central plant 10 via the pipe 1212.

In some embodiments, the data center equipment includes multiple server racks, shown as server rack A 1202, server rack B 1204, server rack C 1206, server rack D 1208, and server rack E 1210. Each server rack is in direct thermal contact with the pipe 1212. For example, each server rack may include a heat exchanger configured to provide a high efficiency of thermal energy transfer from the server rack to the pipe 1212. In the illustration of FIG. 12, server rack A 1202 provides thermal energy generated by devices at server rack A 1202, denoted as Q_{ServerA}, to the chilled fluid from the central plant 10. Additionally, server rack B 1204 provides thermal energy generated by devices at server rack B 1204, denoted as Q_{ServerB}, to the chilled fluid from the central plant 10, server rack C 1206 provides thermal energy generated by devices at server rack C 1206, denoted as Q_{ServerC}, to the chilled fluid from the central plant 10, server rack D 1208 provides thermal energy generated by devices at server rack D 1208, denoted as Q_{ServerD}, to the chilled fluid from the central plant 10, and server rack E 1210 provides thermal energy generated by devices at server rack E 1210, denoted as Q_{ServerE}, to the chilled fluid from the central plant 10. Although the racks 1202-1210 are shown as arranged in series along the pipe 1212, in other embodiments, the pipe 1212 is configured to interact with the racks 1202-1210 in parallel.

The fluid warms due to the thermal energy from the racks 1202-1210. The return fluid is returned to the central plant 10, where it can be chilled again or otherwise allocated in the central plant 10.

Advantageously, the liquid cooling system 1200 is configured to benefit from all of the various features described above with reference to FIGS. 1-11. In particular, the chilled water load attributable to the liquid cooling system 1200 for the data center equipment 1201 can be incorporated into the central plant optimization systems and methods of FIGS. 1-11, and the central plant controller can be configured to allocate loads to cover the demands of the liquid cooling system 1200.

### Controlling Heat and Task Distribution Across Data Center

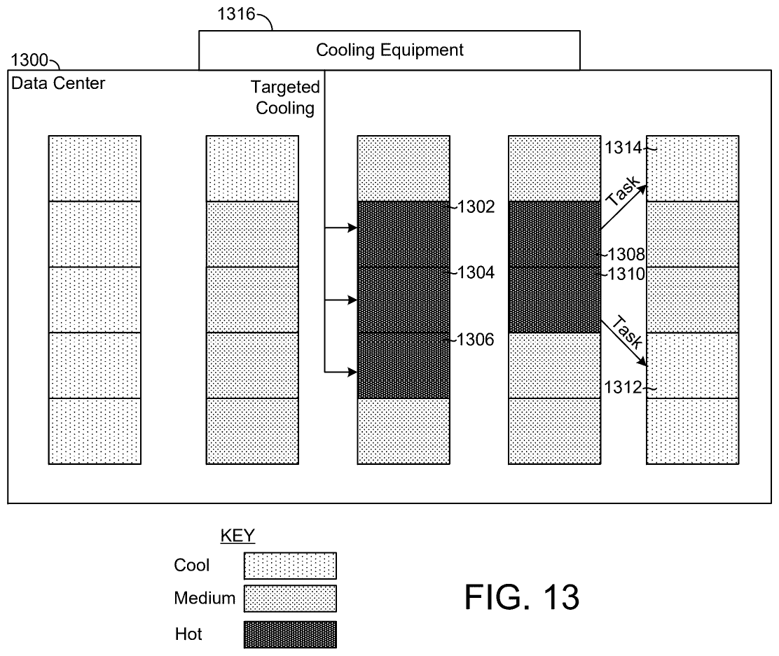

Referring now to FIG. 13, an illustration of heat and task distribution across a data center is shown, according to an exemplary embodiment. In particular, FIG. 13 shows a heat map of a data center 1300. The heat map shows multiple servers with the illustration indicating a relative temperature of each server. For example, server 1302, server 1304, server 1306, server 1308, and server 1310 are shown as being hot, e.g., relative to a preset value above which a server is classified as hot. As another example, server 1312 and server 1314 are shown as being cool, e.g., relative to a preset value below which a server is classified as being cool. Other servers are shown as medium temperature, e.g., at temperatures between the values that define the hot and cold categories.

The data shown in the heat map of FIG. 13 may be collected by sensors positioned in the servers and/or by multiple sensors or cameras distributed around the data center 1300. The sensors can detect hot spots in the data center. Temperature differential across the servers may be caused by differences in task allocation across the servers, hardware differences between the servers, proximity of servers to airflow, heat flow through walls or from building mass, the arrangement and operation of cooling equipment 1316, etc. The temperature differential is considered across the area of the data center (e.g., the floor) or across vertical levels (i.e., in two dimensions), or across volumes in three-dimensions. Server locations and operations can be adjusted to reduce temperature gradations vertically and/or across the area of the data center in some embodiments.

In some embodiments, different servers have different optimal operating temperatures. In such cases, the classification illustrated by the heat map may be configured to adjust for such differences by independently defining the classification criteria for each server. Accordingly, each server may be classified as hot, medium, or cool based on the optimal operating temperature or temperature range of the corresponding server. A server-by-server thermal control may be implemented based on a particular temperature setpoint for each particular server.

As illustrated in FIG. 13, the cooling equipment 1316 (e.g., computer room air conditioners, rack cooling units, server fans, airside system, liquid cooling system) that serves the data center 1300 may be configured to provide targeted cooling to the servers classified as being hot. In the example shown, the cooling equipment 1316 provides targeted cooling to hot servers 1302-1306. By targeting the cooling, energy is saved from being used to needlessly affect the temperature of other servers which are already maintained at an acceptable temperature level. Additionally, cooling can be directed as need to control to different setpoints for different servers.

Also as illustrated in FIG. 13, in some cases the data center 1300 is controlled to shift tasks from hot servers to cool- or medium-temperature servers. In the example shown, tasks originally scheduled to be executed by server 1308 are reassigned to server 1314, while tasks originally scheduled to be executed by server 1310 are reassigned to server 1312. The heat generation associated with execution of these tasks is thereby also shifted from the hot servers 1308-1310 to cool servers 1312-1314, potentially achieving a similar heat-reduction as that which would result from targeted cooling. Heat may thereby be spread more evenly around the data center 1300, which may reduce the risk of overheating of any individual server and reduce the need for targeted cooling. This may increase the reliability and efficiency of all servers in the data room as well as reduce the load on the cooling equipment 1316. Additionally, task shifting may facilitate controlling temperature to different setpoints for different servers.

In various embodiments, coordination of targeted cooling from the cooling equipment 1316 and task shifting between servers is performed. One goal for balancing the use of targeted cooling and task shifting may be an attempted to establish an equilibrium across the data room. In some cases, a temperature gradient across the data room is minimized by task shifting and control of the cooling equipment 1316.

In some embodiments, the data center includes multiple temperature sensors disposed at multiple spots in the data center. The sensors can detect hot spots within the data center (e.g., due to operations of one or more servers). In some embodiments, the hot spots are detected using one or more thermal cameras in the data room. The operations performed by the one or more servers in the hot spots are shifted by the load control agent or other controller to other servers outside of the hot spots in some embodiments. In some embodiments, servers in the cooler and/or coolest areas of the rooms are chosen for the operations shed form the servers in the hot spots. In some embodiments, the servers are deployed in movable racks on automated carts and the carts are moved outside of the hot spots to cooler area in the data room in response to a detection of a hot spot. In some embodiments, the load control agent adjusts the loads on the server or the placement of the servers to achieve a thermal equilibrium throughout the data center. In some embodiments, the cooling equipment may directly provide cool air or liquid to the hot spot location in response to hot spot detection.

Various adaptations of the systems and methods described herein to facilitate server-by-server monitoring and control are within the scope of the present disclosure.

### Data Center Cooling Systems

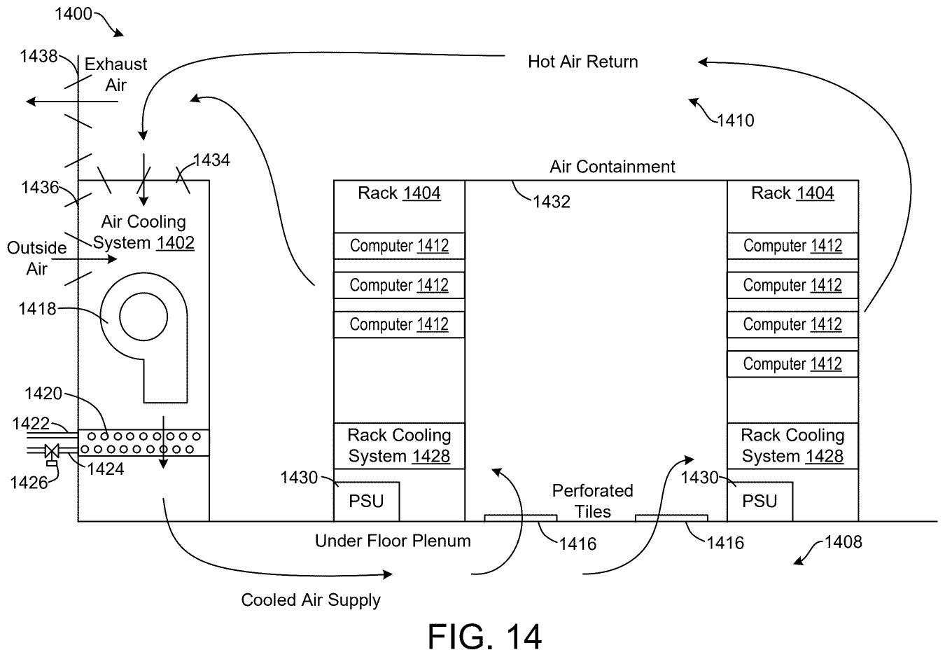

FIG. 14 shows an air cooling system 1402 cooling the racks 1404 of a data center environment 1400. In some embodiments, cooled air from the air cooling system 1402 is provided through an under-floor plenum 1408 and perforated tiles 1416 to the cold aisle of the racks 1404. Heat is exchanged from the central processing units (CPUs), graphics processing units (GPUs), and/or other electronics of the computers 1412 and the cool air provided by the air cooling system 1402. For example, heat is rejected from the computers into the cool air via a heat exchanger that may be mounted on the computer. A hot air return 1410 provides a volume where air that has been heated from by the CPUs/GPUs can be drawn back to the air cooling system 1402 for cooling. The hot air return 1410 may be isolated from the cold air through the use of an air containment mechanism (e.g., a false ceiling 1432) or the hot air return 1410 may rely on the air being drawn through the racks by rack fans 1414 and rising due to the natural buoyancy of hotter air.

The air cooling system 1402 may include a supply fan 1418 to draw hot air from the hot air return 1410 to through the air cooling system 1402 and across a cooling coil 1420. The supply fan 1418 may be controlled to maintain a constant temperature (e.g., a return air temperature, an average computer temperature, etc.) or may be controlled to maintain a proper air flow (e.g., prevent backflow of hot air into the racks) through the data center environment 1400 by volume matching with fans of the rack cooling system 1428 or CPU/GPU fans that pull air from the cold aisle.

The air cooling system 1402 may include a damper system (e.g., dampers 1434-1438) to control the mixture of return air and outside air. In some embodiments, the dampers 1434-1438 are controlled in simultaneously so that the when the return air damper 1434 opens, the outside air damper 1436 and the exhaust damper 1438 close. The outside air damper 1436 and the exhaust damper 1438 may be used to control the amount of outside air that is drawn into the data center environment 1400. For example, the outside air damper 1436 and the exhaust damper 1438 may open if the outdoor air temperature is cooler than the hot return air advantageously providing cooling without energy expenditure by the compressor of the air cooling system 1402 (e.g., if the air cooling system 1402 is a computer room air conditioner (CRAC)) or by the water cooling system providing chilled water to coil 1420 (e.g., if the air cooling system 1402 is a computer room air handler (CRAH)). or if additional ventilation is required. The outside air damper 1436 and the exhaust damper 1438 close if the outdoor air temperature rises above the hot return air.

The cooling coil 1420 may be any device that can reduce the temperature of the air stream flowing through the air cooling system 1402. In FIG. 14, cooling coil 1420 is depicted as a chilled water coil that receives chilled water from a supply pipe 1424. Warmed water may exit from a return pipe 1422. Valve 1426 may be used to control the amount of water (e.g., mass flow, volumetric flow, etc.) that flows through the cooling coil 1420. For example, valve 1426 may be modulated to maintain a temperature of cooled air exiting the air cooling system 1402. Other types of cooling coils 1420 may be disposed in the air cooling system 1402. The air cooling system 1402 may be a direct expansion device and the cooling coil 1420 may be the evaporator side heat exchanger of the refrigerant cycle. The air cooling system 1402 may be configured as a CRAH and the cooling coil 1420 may carry chilled water from a chiller (e.g., of a central plant system). The air cooling system 1402 may use direct evaporative cooling (DEC) and the cooling coil 1420 may be wetted membrane providing cooling by evaporation of water as the air passes through the air cooling system 1402.

The amount of cooling provided can be controlled by changing the temperature of the cooling coil 1420 and/or the flow through the cooling coil 1420. The preferred method and the actuator (e.g., valve, valve motor, compressor drive, etc.) depends on the configuration of the air cooling system 1402.

The air cooling system 1402 may be configured as a CRAC and include a refrigerant cycle for which the cooling coil 1420 is the evaporator side heat exchanger. Cooling can be controlled, for example, by adjusting the speed of the compressor (e.g., by way of a variable speed drive) or by changing the orifice opening size of the expansion valve. In some embodiments, direct control over the expansion valve and/or the compressor speed is not provided by the air cooling system 1402 and the cooling is controlled indirectly by providing a supply temperature setpoint for the temperature leaving the air cooling system 1402 and/or a flow setpoint for the supply fan 1418. Providing a temperature setpoint may cause the air cooling system 1402 to change the internal pressures of the refrigerant and in turn raise or lower the temperature of the evaporator and cooling coil 1420.

The air cooling system 1402 may be configured as a CRAH and cooling can be controlled, for example, by adjusting the flow of chilled water through the cooling coil 1420 (e.g., by way of a ball valve). In some embodiments, direct control of the water valve is not provided by the air cooling system 1402 and the cooling is controlled indirectly by providing a supply temperature setpoint for the temperature leaving the air cooling system 1402. A proportional-integral-derivative (PID) control loop may provide modulate the valve of the cooling coil 1420 to maintain the desired supply temperature setpoint.

The air cooling system 1402 may be configured as a DEC and cooling can be controlled, for example, by turning on/off the water flow that wets the evaporative membrane. In some embodiments, evaporative cooling is binary (e.g., on or off) and a supply air temperature can act as a threshold beyond which evaporative cooling is turned on. In some embodiments, a DEC unit includes multiple evaporative membranes with individualized water flow control allowing for some level of continuous control.

In some embodiments, the air cooling system 1402 includes an outdoor air damper upstream of the supply fan 18. The outdoor air damper may be used to mix outdoor air with the return air from the hot air return 1410 and exhaust some of the return air. The computers 1412 may be configured to operate at a relatively hot temperature (e.g. 50° C., 60° C., etc.) causing the return air to be elevated beyond temperatures typical of an office building. With high return air temperatures, the outdoor air is often cooler than the return air temperatures and significant energy savings can be realized by pulling fresh outdoor air into the air cooling system 1402. In some embodiments, the air cooling system 1402 is disposed at the exterior wall of the data center environment 1400 and no duct work is required to bring in outdoor air and exhaust return air. In some embodiments, the duct work provides a path for the outdoor air to reach the air cooling system 1402 and for exhaust air to leave the data center environment 1400.

The racks 1404 may include a number of computers 1412, a rack cooling system 1428, and a power supply unit (PSU) 1430. The PSU may supply electrical power to the computers 1412 of the rack 1404.

The racks 1404 may use various cooling configurations for rack cooling system 1428. The rack cooling system 1428 may provide air-based systems. The rack cooling system 1428, for example, may draw air across the CPUs/GPUs (e.g., and their heat exchanger). Alternatively or additionally, the computers 1412 may include individual CPU/GPU fans to control the CPU/GPU temperature that draw air through the racks 1404. In some embodiments, the racks 1404 may rely on a containment method such that the supply fan 1418 forces cool air through the racks 1404. The rack cooling system 1428 may use liquid cooling. Direct liquid cooling systems may be configured to pass chilled water from a water cooling system (e.g., a central plant, chiller plant, etc.) directly across one or more heat exchangers attached to the computer 1412 (e.g., attached to the CPU, GPU, etc.). Indirect liquid cooling systems may be configured with a primary heat exchanger in the rack 1404 to exchange heat between a secondary heat transfer fluid in the rack and the chilled water from the water cooling system. The secondary heat transfer fluid may then be circulated across one or more heat exchangers attached to the computer 1412 (e.g., attached to the CPU, GPU, etc.). Liquid-to-air cooling systems may be configured with a primary heat exchanger in the rack 1404 to exchange heat between air traveling through the rack 1404 and the chilled water from the water cooling system. The liquid-to-air cooling system may cool the air entering the rack 1404, for example, if the air cooling system 1402 does not have a cooling coil 1420 or if the air is to be further cooled. In some embodiments, the rack cooling system 1428 uses a combination of methods to provide cooling to the computers 1412. Hybrid cooling techniques including both air cooled systems and liquid cooling systems may be used. For example, the air cooling system 1402 may be a CRAC that maintains the supply air temperature at a moderate temperature (e.g., 60° F.) to operate a low pressure lifts and at high efficiency and the rack cooling system 1428 may use liquid-to-air cooling to further cool the racks at times of high demand (e.g., using the chilled water supplied at approximately 42° F. to perform zone conditioning). As an additional example, direct or indirect liquid cooling may also increase the cooling capacity of a rack 1404.

In some embodiments, racks 1404 use immersion cooling to reject heat from the computers 1412. The computers 1412 may be submerged directly in a non-conductive liquid coolant. The coolant can absorb heat from the components, such as processors and memory, through direct contact, allowing for improved thermal conductivity. A synthetic, dielectric fluid that prevents electrical shorts may be used, making it safe for direct contact with electronic parts. Heat in the coolant can then be rejected into chilled water of a water cooling system (e.g., central plant, chiller plant, etc.) using a heat exchanger. Immersion cooling can reduce the need for large fans and support denser server configurations. Systems and methods described herein may allow for optimal control of data centers that employ a hybrid approach of immersion cooling, liquid cooling, and/or air-based cooling systems.

In some embodiments, computers 1412 of the racks 1404 use thermoelectric cooling (e.g., a Peltier cooler, thermoelectric heat pump, solid state refrigerator, etc.). Thermoelectric cooling may be used to supplement air and/or liquid based cooling provided to the racks. In various embodiments, heat removed from the computers by thermoelectric cooling may still be removed from the building by way of the chilled water and/or cooled air, or may be removed from the building by way of a different heat transfer path separate from the chilled water and/or cooled air. In some embodiments, thermoelectric cooling may also be used to increase the effectiveness of the other cooling media. Heat transfer may be more effective in computers using thermoelectric cooling resulting in elevated return temperatures that are more efficiently rejected, for example, by venting through economizers or use of water side economizers.

In general, the computers 1412 of the racks 1404 can reject heat into a variety of different media (e.g., the chilled water, the cooled air, thermoelectric cooling, etc.) which remove the heat from the building via multiple heat transfer paths. The heat transfer paths may be discrete (i.e., non-overlapping, parallel, separate, etc.) or partially overlapping (e.g., sequential, arranged in series, etc.) in various embodiments. For example, the heat rejected into the cooled air may exit the building via an exhaust airflow from the building or can be transferred from the air into the cooled water and can exit the building via a water flow. Similarly, the heat rejected into the thermoelectric cooling can exit the building directly from the thermoelectric cooling equipment or can be transferred into the cooled water or the chilled air and may exit the building via a water flow or an airflow. In general, the systems and methods described herein can be applied to any type or combination of cooling systems (e.g., water cooling, air cooling, thermoelectric cooling, etc.) and can be used to optimize the amount of heat transfer into and/or out of each cooling system. It is contemplated that the cooling systems can be arranged in parallel with each other, in series with each other, or in any combination of series and/or parallel arrangements in various embodiments.

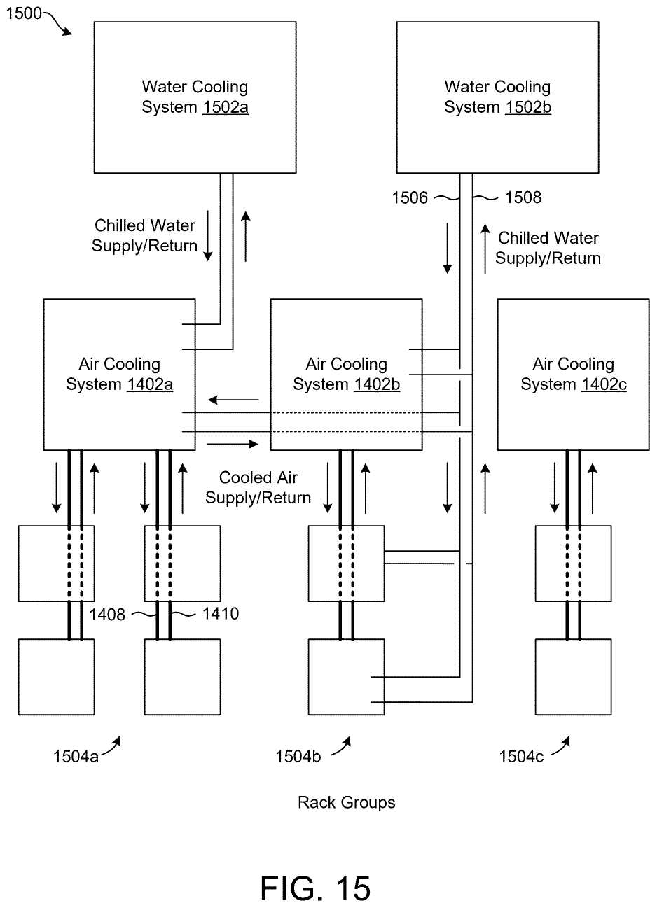

FIG. 15 shows a schematic block diagram of a cooling system 1500 for a data center employing both liquid-based cooling and air-based cooling at the rack, according to some embodiments. The cooling system 1500 may include one or more water cooling systems 1502a-b, and one or more air cooling systems 1402a-c to cool computers housed in racks. Racks may be divided into rack groups based on various criteria such as the customer (e.g., in collocated data center) and/or the systems that can provide cooling to the racks. For example, racks of rack group 1504a may be combined because they are all served by air cooling system 1402a and do not have any liquid cooling capability. Racks of the rack group 1504b may be combined because they are all served by air cooling system 1402b and have a liquid cooling provided by water cooling system 1502b.

Chilled water can be provided for heat rejection to an air cooling system (e.g., air cooling system 1402a-b) and directly to racks (e.g., of rack group 1504b) using the chilled water supply pipes (e.g., pipe 1506). Heat may be rejected from the air of air the air cooling systems into the chilled water via a heat exchanger or heat is rejected from the racks of the rack groups into the chilled water via a heat exchanger (e.g., using direct liquid cooling, indirect liquid cooling, immersion cooling, or liquid-to-air cooling). Warmed water may be returned to the water cooling system 1502a-b using a return water pipe (e.g., pipe 1508) where it can be cooled again in a closed loop system.

Cooled air can be provided for heat rejection to any of the racks (e.g., of rack group 1504a-c). Air may be cooled by an air cooling system 1402a-c and provided to the racks using supply duct or plenum 1408. Heat is rejected from the computers of the racks into the air contacts a heat exchanger connected to the computer as it traverses the rack. Warmed air may be returned to the air cooling system 1402a-c using a return duct or plenum 1410.

Various configurations of the cooling system 1500 are possible. FIG. 15 shows water cooling system 1502a providing chilled water to a single air cooling system 1402a, whereas water cooling system 1502b is shown providing chilled water to air cooling system 1402a, 1402b, and rack groups 1504b. A chilled water system may provide chilled water to any number of air cooling systems and/or any number of rack groups. In addition, two chilled water systems may serve the same rack group (e.g., cooling systems 1502a,b both serving air cooling system 1402a as in FIG. 15). Valving may be provided (e.g., as part of the air cooling system or the piping system) to allow the air cooling system to be served by the water cooling system that would provide the most efficient operations according to the current conditions (e.g., weather conditions, amounts of heat generation, etc.) and current constraints on the system (e.g., equipment under service, unavailable due to minimum on or off timers, etc.).

In some embodiments, one or more air cooling systems may not have any chilled water input (e.g., air cooling system 1402c). An air cooling system may be configured as a CRAC unit and include an internal refrigeration cycle to cool air before being provided to the rack groups.

Some rack groups may only be cooled by air cooling systems. For example, the racks may only reject heat into air provided by the air cooling systems. Some rack groups may only be served by water cooling systems (e.g., using direct, indirect, liquid-to-air, and/or immersion cooling). Some rack groups may be cooled by both by air provided by the air cooling systems and chilled water provided by the water cooling systems. For example, individual racks of the rack group may reject heat generated into both cooled air and chilled water. An individual rack group may be served by any number of water cooling systems and/or any number of air cooling systems.

Heat generated by the rack groups can be rejected into cooled air provided by the air cooling system and/or chilled water provided by the water cooling system. An algorithm (e.g., process, method, function, etc.) may be used to allocate the heat generated by the computers (e.g., of a rack group) to be rejected by a particular air cooling system (e.g., into the air provided) or water cooling system (e.g., into the chilled water provided). As used herein, to “allocate” heat generated to a particular cooling system or heat rejection media (e.g., chilled water or cooled air) refers to the act or process or determining a particular amount of heat (e.g., target amount, ideal amount, optimal amount, etc.) to be rejected by each cooling system or heat rejection media, in some embodiments. For example, allocating an amount of heat generated by one or more computers of a rack group may refer to determining (i) a first amount of heat to be rejected from the rack group into cool air provided by an air cooling system and (ii) a second amount of heat to be rejected from the rack group into chilled water provided by a water cooling system. In some embodiments, allocating the amount of heat generated by one or more computers of a rack group may include determining a heat transfer target or setpoint for each of the water cooling system and the air cooling system, which can then be used by the equipment of the water cooling system and/or air cooling system to control the various devices thereof (e.g., chillers, fans, pumps, valves, actuators, etc.) to achieve the heat transfer target or setpoint for each system.

### Data Center Cooling Control System

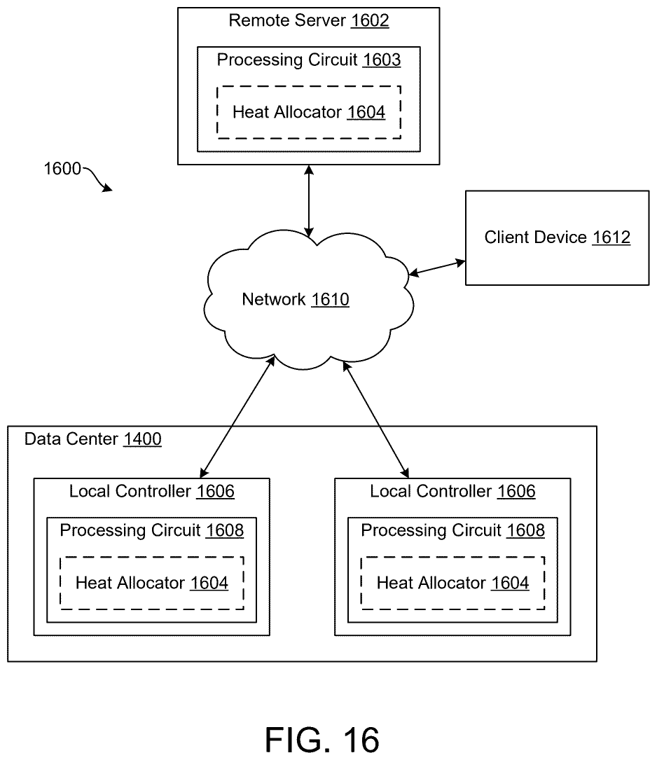

FIG. 16 shows a data center cooling control system 1600 according to some embodiments. The data center cooling control system 1600 may be implemented as a central plant control system 100 with additional features and functionality to control additional equipment of the data center. For example, data center cooling control system 1600 may control a central plant 10 (e.g., a water cooling system 1502) feeding the data center as well as the air cooling system 1402 (e.g., CRAC, CRAH, DEC units, etc.). The data center cooling control system 1600 may allocate the heat generated by the computers of the data center to various modes of heat rejection (e.g., into air provided by the air cooling system 1402 and into water provided by the water cooling system) and operate the equipment to reject the heat according to the allocation.

The data center cooling control system 1600 may include a remote server 1602 with a processing circuit 1603 and heat allocator 1604. In some embodiments, the heat allocator 1604 is configured on the remote server 1602 and the allocations of the heat generated by the computers are sent to local controllers 1606 located at the data center 1400. Heat allocations may be communicated over network 1610 using a suitable communication protocol. The network 1610 can include routers, switches, antennas, computers, and any other hardware required to communicate information between the data center cooling control system 1600 (e.g., from the remote server 1602 to the local controllers 1606). A portion of the network 1610 can be wireless and/or a portion of the network 1610 can be wired. The network 1610 can include one or more networks with routers to facilitate data transfer between the different networks. In some embodiments, the processing circuit 1603 includes a number of processing circuits (e.g., configured in a cloud architecture) and the various processing circuits 1603 communicate using network 1610.

The data center cooling control system 1600 may include local controllers 1606 with a processing circuit 1608 and heat allocator 1604. In some embodiments, the heat allocator 1604 is configured on the local controller 1606 and the allocations of the heat generated by the computers are calculated by the local controllers 1606 at the data center 1400. The local controllers 1606 may be configured to operate the cooling equipment of the data center 1400. For example, the local controllers 1606 may generate control setpoints based on the heat allocations (e.g., obtained from the remote server 1602 or internally calculated). The setpoints may include water temperature setpoints, chilled water flow setpoints, supply air temperature setpoints, air flow setpoints, and any other setpoint known to one skilled in the art to cause a local controller 1606 to reject an allocated amount of heat. The local controllers may also include the feedback control logic that is implemented in order to cause the equipment to operate at the given setpoint. The complexity of the data center control equipment may require more than one local controller 1606 (e.g., to measure the multitude of temperatures and/or run all the feedback control algorithms).

The functionality of the heat allocator 1604 may be distributed over any of the processing circuits 1603 and 1608. In some embodiments, the heat allocator 1604 is fully implemented by the processing circuit 1603 and results are communicated to the local controllers over the network 1610. In some embodiments, the heat allocator 1604 is fully implemented by a single local controller 1606 and results may be communicated to other local controllers to operate the equipment according to the heat allocations. In some embodiments, the heat allocator 1604 is distributed across the processing circuits 1608 of multiple local controllers 1606. In some embodiments, the heat allocator 1604 is distributed across processing circuits 1603 of the remote server 1602 and processing circuits of the local controllers 1606 and intermediate results may be communicated over the network 1610 to continue computation on another device and/or architecture.

The data center cooling control system 1600 may include one or more client devices 1612. The client device 1612 can be used to display data (e.g., results, measurements, etc.) of data center cooling control system 1600. The client device 1612 may be used to configure the various algorithms of the data center cooling control system 1600 (e.g., including functionality of the heat allocator 1604). The client device 1612 may also be used to deploy portions of the algorithms of the data center cooling control system 1600. For example, the client device may generate a user interface based on instructions from the processing circuits 1603 and 1608 (e.g., from the heat allocator 1604). The heat allocator 1604 may provide instructions to the client device 1612 (e.g. JavaScript, Cascading Style Sheets) that instruct the client device 1612 how to generate the user interface within a client application (e.g., an internet browser, a proprietary application, etc.). In some embodiments, the client device 1612 can provide application programming interfaces (APIs) that cause various functionality of the heat allocator 1604 to be triggered. For example, the application may provide a user interface that executes a callback to an API responsive to clicking a button to generate a new model of the water cooling system 1502.

The local controller 1606 and/or the remote server may include additional functionality not provided by the heat allocator. For example, any of the functionality of the central plant controller 102 and/or the planning tool 902 may be provided in addition to or in support of the heat allocator 1604.

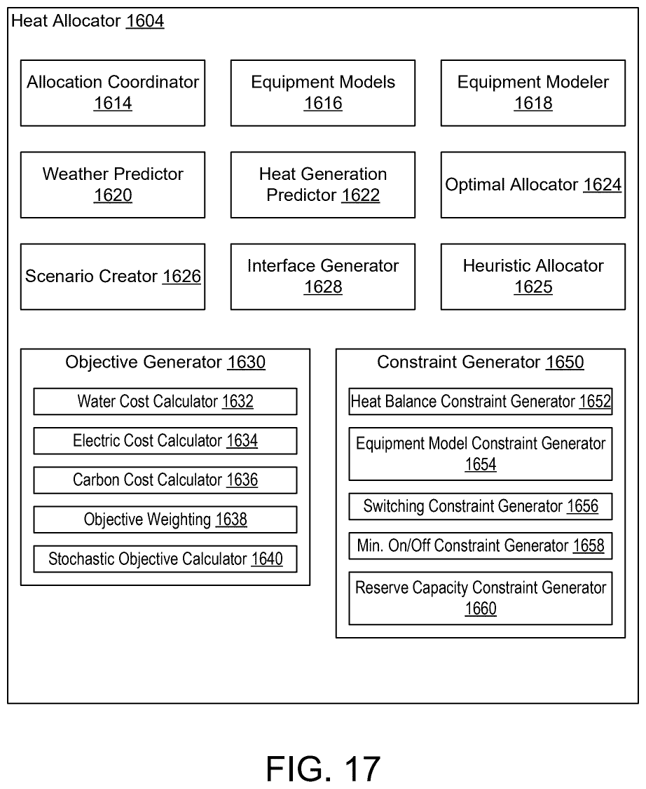

FIG. 17 shows the heat allocator 1604 according to some embodiments. The heat allocator may be implemented as a circuit (e.g., as described herein) within the processing circuits 1603 and/or 1608. An allocation coordinator 1614 may be configured to control the timing and flow of data through the other circuitry of the heat allocator 1604 or the data center cooling control system 1600. For example, the allocation coordinator 1614 may cause the modules or circuits to execute in a specific order to perform the function of heat allocator 1604. In some embodiments, the allocation coordinator 1614 may route the information and/or outputs of other circuits that are dependent on the information or use the information as an input.

### Computer Heat Generation Prediction

In some embodiments, the heat allocator 1604 is configured to measure and/or predict the heat generated by the computers and to determine how to allocate the heat generation between various methods of heat rejection (e.g., air cooling system 1402 and/or water cooling system 1502). The heat can be allocated via various algorithms. For example, constraints may be generated that ensure that the allocation will reject all the heat generated and an allocation that satisfies the constraints can be found. In some embodiments, the solution is found by performing optimization. For example, the solution may minimize an objective function that includes the cost of rejecting the heat with components from an electrical cost, a carbon cost, a water cost and/or any costs that may be incurred by rejecting heat generated from the computers of the data center 1400.

The heat allocator 1604 may include a weather predictor 1620. In some embodiments, the weather predictor 1620 is configured to predict the weather conditions that affect the heat generation of the data center 1400 and/or the efficiency of the equipment that rejects the heat. For example, the weather predictor 1620 may predict the temperature and the wet-bulb temperature. One skilled in the art will recognize the same information included in the wet-bulb temperature and the temperature is also included in measurements of other conditions (e.g., temperature and wet-bulb temperature can be calculated from temperature and dew point or temperature and relative humidity, etc.). Depending on the effect of the weather on the efficiency and/or the load generation the weather predictor 1620 may be implemented with varying levels of sophistication. For example, the weather predictor 1620 may use the current measurements to predict into the future (e.g., by zero-hold) or the weather predictor 1620 may blend the current measurements with a typical daily temperature/humidity trend for the area. In some embodiments, the weather predictor 1620 is configured to obtain the weather prediction from an outside source (e.g., NOAA or any other weather prediction service). The weather predictor 1620 may blend a current and local temperature measurement with the weather prediction obtained from the outside source. The current temperature can account for localized effects or mispredictions at the current time and the weather predictor 1620 may gradually adjust the local temperature measurement towards the obtained weather prediction as the prediction moves further into the future.

The heat allocator 1604 may include a heat generation predictor 1622. The heat generation predictor 1622 may be configured to calculate the amount of heat generated by the computers of the data center 1400 at the current time and/or for a period of time into the future (e.g., a prediction horizon). The heat generation predictor 1622 may predict the computer utilization (e.g., the expected computational load as a fraction of the total available computational resources) and use the predicted computer utilization to predict the heat generation. For example, the computer utilization may follow a daily or a weekly trend. The computer utilization may also depend on events that are occurring across the user base of the computational resources. For example, if a new software release may cause a predictable uptick in the computational load on the data center 1400 (e.g., if it is housing the data center). The computational load may also increase due to streaming of a sporting event (e.g., soccer match, etc.) or be based on the weather of a large geographic area. Computer utilization can be predicted using a suitable timeseries prediction technique. For example, the prediction can be the average utilization for a given day of the week and be trained using historical computer utilization data. Additional techniques for predicting timeseries (e.g., computer utilization, or other heat loads) can be found in U.S. Pat. No. 11,803,174 granted on Oct. 31, 2023 ('174 patent), the entirety of which is herein incorporated by reference.

In some embodiments, the effect of the utilization of an individual computer, a rack of computers, or a group of racks is determined by the heat generation predictor 1622 (e.g., during a training process). With the individual effect of each component known, the heat load can be estimated based on the server utilization. In some embodiments, historical data for total heat generation is collected. For example, the heat rejected by the HVAC system (e.g., both from using mechanical forms of heat rejection including the refrigeration cycle in a CRAC or chilled water from a chiller and drawing in outside air that is cooler than the return air) may be used as an estimator of the total heat generation (if the temperature in the data center is constant then total heat generation may be equal to total heat rejection). During training, the heat generation predictor 1622 may find parameters of a model for heat generation by minimizing the squared error between the measured heat load (e.g., the total amount of heat rejection performed) and a model estimate as represented in,

$${{α}^{*}}_{k} = {arg min}_{{α}_{k}} {\sum }_{t ∈ τ} {( {L}_{t} - {\hat{L}}_{t} ( {B}_{ct} , {α}_{k} ) )}^{2} ,$$

where the a*ₖ are the best fit parameters, Lₜ is the heat generation at various times t that are an element of the historical training period T, and B_{ct} is the server utilization of a computer, rack, or rack group with index c at the time t. In some embodiments, the estimated load \hat{L}ₜ is a linear function of the computer utilization,

$${\hat{L}}_{t} ( {B}_{ct} , {α}_{k} ) = {\sum }_{k ∈ K} {α}_{k} {\sum }_{c ∈ {C}_{k}} {B}_{ct} ,$$

where K represents the set of all computer (or rack or rack group) types (e.g., each unique model number, processor configuration, etc.) that have a different heat generation coefficient and Ck is the set of all computers (or rack or rack group) of type k. Linear regression can be used to identify the parameters of the model for the estimated load that is a linear function of the computer utilization.

In some embodiments, different processor configurations include, for example, computer hardware including CPUs, GPUs, Dual inline memory (DIMM), high bandwidth memory (HBM), ASICs, tensor processing units (TPUs), quantum processors, or any combination thereof. For example, computers or other hardware with GPUs can generate significantly more heat than computers with only CPUs. Systems and methods described herein may be configured to determine first best fit parameters a*₁, where type 1 is used to represent computers or other hardware using only CPUs and second best fit parameters a*₂, where type 2 is used to represent computers or other hardware using both CPUs and GPUs.

In some embodiments, the server utilization B_{ct} is weighted, for example, to account for the differences between utilization of a CPU and utilization of a GPU. The server utilization may be a weighted average of the CPU and GPU utilization. The GPU utilization may be weighted more heavily than CPU utilization to account for the additional heat generation of GPUs. For example, the GPU utilization may be weighted at 65% and the CPU utilization at 35%.

In some embodiments, the server utilization B_{ct} is segmented (e.g., apportioned, distributed) into a CPU utilization and a GPU utilization. Because GPUs tend to have increased heat generation, including both a GPU and CPU utilization may increase load prediction accuracy. For example, the equation for the best fit parameters may be adjusted to include both utilizations as in:

$${{α}^{*}}_{k} = {arg min}_{{a}_{k}} {\sum }_{t ∈ T} {( {L}_{t} - {\hat{L}}_{t} ( {B}_{CPU , ct} , {B}_{GPU , ct} , {α}_{k} ) )}^{2} ,$$

where B_{CPU,ct} is the CPU utilization of a computer, rack, or rack group with index c at the time t and B_{GPU,ct} is the GPU utilization of a computer, rack, or rack group with index c at the time t. Where the utilizations are segmented between CPU and GPU utilization, the model parameters a*ₖ may be a vector (e.g., having an element related to CPU utilization and an element related to GPU utilization). In some embodiments, the estimated load \hat{L}ₜ is a linear function of the computer utilization,

$${\hat{L}}_{t} ( {B}_{ct} , {α}_{k} ) = {\sum }_{k ∈ K} {[ {α}_{k} ]}^{T} {\sum }_{c ∈ {C}_{k}} [ \begin{matrix}{B}_{CPU , ct} \\ {B}_{GPU , ct}\end{matrix} ] .$$

It is contemplated that while the equations, constraints and objective functions described herein use example processor types of CPUs and GPUs, one skilled in the art would recognize the equations and the respective descriptions can be modified to account for other hardware configurations (e.g., by expanding vectors with more types, etc.). For example, computers or server blades having any combination of CPUs, GPUs, DIMM, HBM, ASICs, TPUs, quantum processors may be used to form a type for the purposes of predicting heat generation and allocating heat rejection throughout a data center. Similarly, the type of computing load may be used for the purposes of predicting heat generation and allocating heat rejection. For example, the type of computing load (e.g., training artificial intelligence models, performing inference using an artificial intelligence model, general computing, data retrieval, network routing, etc.) may be used to predict the hardware to which the computing load will be assigned and/or may be affect the amount of heat generated by a particular type of hardware. In some embodiments, the type (for the purposes of predicting heat generation and allocating heat rejection) may be based on the combination of hardware type and computing load type.

In some embodiments, the estimated load is a nonlinear function of the computer utilization and nonlinear regression techniques are used to identify the parameters (e.g., depending on the form of the nonlinearity). In some embodiments, the manufacturer's specification of the computer can be used to develop bounds for acceptable parameters. For example, if the specification says the maximum power usage by the computer is 200 W the coefficients in the linear model, αₖ, could be bound between 140 W and 260 W for that computer type (e.g., ±30% from the manufacturer's specification). In some embodiments, the parameters of the linear model, αₖ, are written in a form of a difference from the value in the computer's specification and regularization terms may be used during regression in order to find solutions near the value from the computer specification (e.g., ridge regression or least absolute shrinkage and selection operator (LASSO) can be used).

In some embodiments, the total power usage of an individual computer, a rack of computers, or a group of racks is measured. Most of the power used by a computer is turned into heat during the computation process allowing; thus, total power usage may be a good estimate of the heat generation for the same individual computer, rack of computers, or group of racks. The computers may have onboard fans that convert some electrical energy into air movement and LEDs that convert some electrical energy into light energy leading to a difference between the total power usage and the heat generation. If such differences are important, a model that relates the power usage to the heat generation may be determined. The techniques described herein related to computer utilization can be used to determine the model that relates the power usage to the heat generation. Additionally or alternatively, a single coefficient between power usage and heat generation can be determined based on the total heat generation (e.g., measured as heat rejection at the HVAC system) and total electrical consumption (e.g. of all the computers or of the data center).

After parameters α*ₖ have been found, the parameters may be used by heat generation predictor 1622 to predict the heat generated by the computers (racks or rack groups). In some embodiments, the heat generation predicted is segmented based on the type of computer and/or processor configuration of the computers. For example, for each computer (rack or rack group) a heat generation prediction may be generated for the CPU-based loads and/or the GPU-based loads. Segmented heat generation predictions may be used by the objective generator 1630 and/or the constraint generator 1650 to account for different considerations when serving computers (racks or rack groups) of different types. For example, some computers may require liquid cooling due to higher heat generation density or have different temperature requirements. GPU-based loads may require liquid cooling and/or require decreased water temperatures in order to reject the higher amount of heat created by such devices.

Measurements of the total power usage or the utilization of an individual computer, a rack of computers, or a group of racks may be used to generate a prediction model for the total power usage at the same level of granularity. The heat generation predictor 1622 may predict the computer power utilization using the techniques described herein and/or in the '174 patent and use the predicted computer utilization to predict the heat generation.

### Hybrid Data Center Optimization

Cooling in hybrid data centers can pose particular challenges to the determine suitable allocations of the heat generated by the rack/computers across the multiple heat rejection capabilities (e.g., the water cooling systems 1502 and the air cooling systems 1402). Stated differently, in a hybrid cooled computer rack, it is necessary to decide if the rack/computers should be cooled by water, air, or both. This requires coordinating the operation of both the water cooling systems 1502 and the air cooling systems 1402 while considering the amounts of energy consumed by both cooling systems 1502 and 1402 to remove heat from the same terminal system (e.g., the computer rack). In some embodiments, additional constraints are added to account for considerations of thermodynamics' second law. For example, constraints may be included account for temperature differences between the two media when both liquid and air cooling is provided. Inclusion of such constraints advantageously ensure that conformant allocations can be used to operate the air cooling systems 1402 and the water cooling systems 1502 and the computer processors remain at an operable temperature or within operable temperature ranges.

Data centers are often considered essential infrastructure as the economic costs related down time can be large. Allocations related to a specific (e.g., nominal or current) amount of heat generation may rapidly change causing increased demand on the cooling equipment. If the cooling systems are not available (e.g., ready) to reject the increased heat generation, computers may need to be taken offline and/or computational tasks deferred to avoid generating heat in excess of the cooling equipment's heat dissipation capabilities. Advantageously, by adding constraints related to alternate heat generation scenarios, it may be possible to ensure that both the current load is met and that there is enough reserve capacity in the event that computer utilization, and therefore heat generation, rapidly increases.

In some embodiments, the heat allocator 1604 includes an optimal allocator 1624 to generate optimal allocations of the heat generated by the computers between the water cooling systems 1502 and the air cooling systems 1402 of the data center. Optimal allocations as used herein refer to allocations that are generated by finding a solution to an optimization problem (e.g., using gradient descent, linear programming, mixed-integer linear programming, nonlinear programming, neural networks, etc.). One skilled in the art will recognize that an optimal allocation found using optimization algorithms may not be the best (e.g., the optimal allocation may not be the most minimizing solution or the most maximizing solution). Some techniques (e.g., those relying on iterations) include various tolerances and stopping criteria to prevent utilizing computational resources to decrease cost and/or improve optimality by an insignificant amount. As used herein the scope of an optimal allocation includes any result (e.g., the allocations) found using an optimization algorithm or by solving an optimization problem including allocations for which a more optimal allocation can be found or that have been subsequently post-processed.

The heat allocator 1604 may also include a heuristic allocator 1625. The heuristic allocator 1625 may be configured to determine allocations other than optimal allocations found using an optimization algorithm. The heuristic allocator 1625 may be used as an alternative to the optimal allocator 1624, for example, in a resource-limited environment. The heuristic allocator 1625 may also be used in addition to the optimal allocator 1624. For example, if the optimal allocator 1624 is disposed on a device in a cloud architecture, the heuristic allocator 1625 may be included on an edge device (e.g., a controller) for use if a connection is lost to the optimal allocator 1624. The heuristic allocator 1625 may use rules or other non-optimizing techniques to determine an allocation. For example, the heuristic allocator 1625 may be configured with a function that maps the heat generation (e.g., that will become the load on the HVAC system) to a particular allocation. The mapping function may be configured to allocate as much heat generation as possible to the water cooling system 1502 while maintaining the load on any operating chillers within a range (e.g., between 40% and 70% for variable speed chillers or between 80% and 100% for constant speed chillers) and allocate any remaining heat generation to the air cooling system 1402.

In some embodiments, the heuristic allocator 1625 may be configured based on insight obtained from the optimal allocator 1624. Training data may be generated by the optimal allocator 1624 for various heat generation (and weather, etc.) scenarios. For example, the training data may include both the conditions (e.g., heat generation, weather, etc.) that drive the optimal equipment configuration to use in rejecting the heat and the optimal configuration determined by the optimal allocator 1624. In some embodiments, a person may view the data and program appropriate rules into the heuristic allocator 1625. Additionally or alternatively, the rules of the heuristic allocator 1625 may be adjusted based on the training data. For example, the heuristic allocator may be a function that maps the conditions to an equipment configuration with parameters that are adjusted based on the training data. A look-up table, mathematical function, neural network, etc. may be used as the function of the heuristic allocator 1625

The optimal allocator 1624 may be configured to find a solution to an optimization problem. For example, the optimal allocator 1624 may be configured to find a solution to:

$${θ}^{*} = arg {min}_{θ} J ( θ ) ,$$

$$subject to f ( θ ) \leq 0 , h ( θ ) = 0 ,$$

where J(θ) is the objective function, ƒ(θ) represents nonlinear (and/or linear) inequality constraints, and h(θ) represents nonlinear (and/or linear) equality constraints. As described in more detail herein the objective generator 1630 may be configured to generate the objective function J(θ) based on the pricing structure of the utilities providing energy and/or resources to the data center to perform the cooling. The constraint generator 1650 may be configured to generate the constraints ƒ(θ)≤0, h(θ)=0. The objective function may depend on the allocations of heat generation θ to the various air cooling systems 1402 and water cooling systems 1502. The optimal allocator 1624 may find an optimal allocation θ* by solving the optimization problem described herein. The optimal allocation may then be communicated (e.g., sent) to the respective local controllers 1606 responsible for implementing that allocation. Optimal allocations may be found for the current time period and/or a time period into the future.

### Objective Function

In some embodiments, the optimal allocator 1624 uses an objective function that is based on the cost of the resources used to operate the water cooling systems 1502 and/or the air cooling systems 1402. The cost may be a summation of the cost of water, the cost of electricity, and any other cost that may be incurred from operating the cooling system equipment (e.g., maintenance costs, cost of carbon offsets, replacement costs, etc.) over a predictive horizon. For example, the objective generator 1630 may generate the cost function:

$$J ( θ ) = {\sum }_{t ∈ h} {\sum }_{u ∈ U} {c}_{u , t} {U}_{u , t} ( θ ) ,$$

where c_{u,t} is the cost per unit (e.g., the rate) of the utility u at the time step t of the horizon h, and U_{u,t} is the rate of utility usage (e.g., consumption) of the utility u at the time step t of the horizon h. It is noted that the objective function may include a sampling period coefficient that converts the time from units of seconds to the units of samples (e.g., for addition in the cost function); however, if the rate of utility usage is already in units of per sample, the coefficient may not be needed. In some embodiments, the cost components of the objective function include more terms (e.g., base rates, demand charges, block and index purchasing, etc.).

The objective generator 1630 may include a water cost calculator 1632. The water cost calculator 1632 is configured to generate the cost of water such that it can be used as part of the objective function for the optimization problem of the optimal allocator 1624. The water cost calculator 1632 may calculate the cost of water by multiplying the rate of water usage (e.g., gallons per second) by the cost of water usage (e.g., dollars per gallon). The water cost may include additional terms to account for complex rate structures that may exist for commercial data centers. The water usage may be subject to a progressive rate structure wherein the water per unit of usage costs more as more is used. For example, water usage may be subject to a three-tiered rate based on the monthly usage (a first rate for the first amount of water, a second rate for water usage between a first amount and a second amount, and a third rate for all water usage above the second amount). The water cost calculator 1632 may model cost similar to a subplant model as described herein if the term of the tier (e.g., a month) aligns with the prediction horizon used by the cost function by defining an additional decision variable for the total water cost and generating constraints that ensure the total water cost is greater than that defined by the tier. In some embodiments, the prediction horizon will be significantly smaller than the term of the tier and the water cost calculator 1632 requests that the optimal allocator 1624 execute a monthly plan to determine from which tier the rate should be used. The water cost calculator 1632 may adjust the cost of water used in the short horizon optimization problem to achieve the target determined from the plan (e.g., in situations where it is optimal to target an amount of water at the transition point between tiered rates). For example, the methods described in U.S. Pat. No. 11,379,935 granted on Jul. 5, 2022 ('935 patent), the entire contents of which is herein incorporated by reference, could be used to achieve a target water usage a specific tier. In some embodiments, fines may be assessed to a data center that consumes an excessive amount of water over a particular term (e.g., month, year). Such fines and/or penalties can be implemented similar to a tiered rate structure.

In some embodiments, the operators of a data center may wish to curtail water usage (e.g., conserve water). The reasons for curtailing water usage may not be a direct economic decision, for example, the company operating the data center and/or the companies using the data center may wish to be viewed as a “good corporate citizen” and choose to conserve water even though economically it could cost more. The water cost calculator 1632 may add additional, user defined costs (e.g., entered through a user interface) to the cost of water to artificially inflate the cost of water used by the optimal allocator 1624 to cause the optimal allocator 1624 to tend to use less water.

The objective generator 1630 may include an electric cost calculator 1634. The electric cost calculator 1634 is configured to generate the cost of electricity such that it can be used as part of the objective function for the optimization problem of the optimal allocator 1624. The electric cost calculator 1634 may calculate the cost of electricity by multiplying the rate of electricity usage (e.g., kW) by the cost of electricity usage (e.g., dollars per kWh). It is noted that the sample time coefficient as described previously is needed if the rate of electrical usage is in kW rather than kWh per sample (e.g., because kW is a rate of energy usage per time). The electricity cost may include additional terms to account for complex rate structures that may exist for commercial data centers. As described herein, electricity may be provided using a complex rate structure that includes a base rate, a consumption cost, a demand charge, a tiered consumption cost (regressive or progressive), block and index purchase plans, etc.

The electric cost calculator 1634 may be configured to generate a demand charge. Demand charges may be associated with the peak electrical consumption within a given time period (e.g., within a month). In some embodiments, the demand charge can be added to the cost function by modifying the various components of the objective to include a cost associated with the peak electrical rate. The modified objective function may be defined as:

$$J ( θ ) = {\sum }_{t ∈ h} {\sum }_{u ∈ U} {c}_{u , t} {U}_{u , t} ( θ ) + {c}_{demand} {max}_{t ∈ D} ( {U}_{e le , t} ) ,$$

where c_{demand} is the demand charge for the applicable demand charge period D and u_{ele,t} is the total electrical consumption associated with the demand charge. For example, U_{ele,t} may be the sum of the electrical usage by the air cooling 1402, systems the water cooling systems 1502, the computers, lighting, and other systems of the data center. The term max (U_{ele,t}) selects the peak electrical power consumption at any time during the demand charge period. The demand charge c_{demand} and the demand charge period may be defined by the utility rate information. In some embodiments, another variable is used to represent the peak demand, for example, in.

$$J ( θ ) = {\sum }_{t ∈ h} {\sum }_{u ∈ U} {c}_{u , t} {U}_{u , t} ( θ ) + {c}_{demand} {p}_{ele , D} ,$$

where the peak demand variable p_{ele,D} is constrained to be greater than electrical consumption for every time period t that is part of the horizon.

The extent of the prediction horizon may not align with the end of a demand charge. In such situations, a weighting factor may be multiplied by the demand charge. The weighting factor may depend on the amount of time left in the horizon and the amount of time left in the demand period. Appropriate weighting of the demand charge may be used to prorate the demand and cause near optimal decisions to be made even when the entire demand period is not part of the horizon. Weighting of the demand charge is described in more detail above. In addition, further details related to demand charge weighting can be found in U.S. Pat. No. 10,386,820 granted on Aug. 20, 2019, the entire contents of which are herein incorporated by reference.

Some utility providers apply more than one demand charge. For example, an off-peak, on-peak, and anytime demand charge may be used. When more than one demand charge is applied to the electrical bill of the utility more than demand charge may be added to the objective function bye the electric cost calculator 1634. Demand charges may also be subject to demand ratcheting. For example, once set a demand charge or may be based on the highest electrical usage over a previous time period (e.g., 6 months, 12 months, etc.). In some embodiments, multiple demand charges are generated in order to accommodate a ratcheting demand charge. Further details on incorporating one or more demand charges into an objective function can be found in U.S. Pat. No. 10,282,796, granted on May 7, 2019, the entire contents of which are herein incorporated by reference.

The utility company may ask for additional energy sources to be brought online (e.g., when the utility grid is under stress and/or a brownout is imminent). The utility may offer incentives (which can be in the form of lucrative payouts) in order to generate electricity and/or reduce electrical demand when requested. These incentives (sometimes known as demand response programs) may come in multiple varieties. For example, some demand response programs are voluntary, and resources (either curtailments or generators) enter the market and are paid at the real-time electrical rate for their curtailment and/or generation. The utility company may only make such a request (e.g., open the market) when the real-time electrical rate is at a level where it is economically reasonable for the utility to offer the incentives. Some utilities make this decision by comparing the real-time electrical rate to the net-benefit test rate. As another example, the utility may contract with the resources such that the resources are obligated to remove demand from the grid (either through generation or curtailment) when requested. The incentive payments may be added to the objective function by the electric cost calculator 1634. For example, the incentive payments may be added as a negative number as they can reduce the effective cost of electricity. Further details on incorporating one or more incentive programs into an objective function can be found in U.S. Pat. No. 10,949,777, granted on Mar. 16, 2021 and in U.S. Pat. No. 10,418,832, granted on Sep. 17, 2019, the entire contents of both are herein incorporated by reference.

The electricity usage may be subject to a tiered rate structure wherein the cost of electricity (e.g., per kWh) increases as more electricity is used for a time period (e.g., month, year, etc.). Additionally or alternatively, the electricity usage may be subject to a tiered rate structure wherein the cost of electricity (e.g., per kWh) decreases as more electricity is used for a time period (e.g., month, year, etc.). The electric cost calculator 1634 may model cost similar to a subplant model as described herein; this technique may be of particular use if the cost is progressive and the term of the tier (e.g., a month) aligns with the prediction horizon used by the cost function. In some embodiments, (e.g., regressive rates and/or when the prediction horizon will be significantly smaller than the term of the tier) the electric cost calculator 1634 requests that the optimal allocator 1624 execute a monthly plan to determine from which tier the rate should be used. For example, the methods described in the '935 patent, could be used. It is important to note that when working with a tiered electrical rate structure, similar to demand charges, it may be necessary to use the electrical usage of all the systems of the data center (e.g., the sum of the electrical usage by the air cooling 1402, systems the water cooling systems 1502, the computers, lighting, and other systems of the data center), which implicitly requires predicting future values for the electricity usage that are not determined by the optimal allocator 1624 (e.g., usage by the computers, lighting, etc.).

The data center may participate in block and index purchasing programs that may be appropriately included in the objective function by the electric cost calculator 1634. Block and index purchasing programs for electricity may come in at least two varieties, power-type block and index and energy-type block and index. In a power-type block and index program an amount (e.g., the block) of energy is purchased for several time segments (e.g., hours) based on a schedule. For example, 1 MW of electricity may be purchased for each hour between 8 AM and 8 PM each weekday. Outside of the time of the block purchase (e.g., nights and weekends) or if more than the block (e.g., more than the 1 MW in the example) is used during the times of the block purchase electrical usage may be charged at the index rate (e.g., real-time rate, day-ahead rate, etc.) The electric cost calculator 1634 may modify the objective function to include the cost of electricity during the block time period rather than a cost per unit usage multiplied by a rate, as shown in:

$$J ( θ ) = {\sum }_{t ∈ h} {\sum }_{u ∈ U ∉ ele} {c}_{u , t} {U}_{u , t} ( θ ) + {C}_{e le , t} ,$$

where C_{ele,t} is the total electrical cost at the time t. The cost can then be constrained based on the electrical rates and the block purchase. For example, the cost may be constrained by C_{ele,t}>0 and C_{ele,t}>c_{index,t}(U_{ele,t}(θ)−U_{block,t}). The constraints represent that the additional cost is zero up until the entire block purchase U_{block,t} for that time period is used (e.g., the money has already been spent and there is no additional cost that can be controlled by using less electricity than the entire block purchase) and each unit of electricity beyond the block is charged at the index rate c_{index,t}. In some embodiments, the right to use electricity at a guaranteed rate may be purchased and two rates are used to constrain the cost, C_{ele,t}>c_{block,t}U_{ele,t}(θ) and C_{ele,t}>r_{index,t}(U_{ele,t}(θ)−U_{block,t})+c_{block,t}U_{block,t}, where r_{block,t} is the guaranteed rate.

The block and index structure may also be a load following structure, wherein the data center is charged at a block rate for a percentage (e.g., 80%, 60%, etc.) of its electrical usage at each time period regardless of what is used. To account for load following type block and index purchase programs the electric cost calculator 1634 may use the original cost function and a blended rate. For example, the electric cost calculator 1634 may calculate the blended rate using c_{ele,t}=wc_{block,t}+(1−w)c_{index,t}, where w is the percentage of the electrical usage purchased at the block rate.

The block and index structure may also be of the energy-type. In energy-type block and index structures, the electrical energy may be bought in bulk for a longer time period (e.g., over the course of a month). Energy-type block and index structures may be treated as tiered rate structures. For example, the additional (e.g., the controlled cost) is zero until the block is used. Beyond that initial block the electrical cost (e.g., rate) per kW may be charged at the index rate. Further details on incorporating one or more block and index programs into an objective function, as well as information related to how to determine an optimal block purchase (e.g., prior to the beginning of the block period) can be found in U.S. Pat. No. 11,164,126, granted on Nov. 2, 2021, the entire contents of which is herein incorporated by reference.

In some embodiments, the objective generator 1630 includes a carbon cost calculator 1636. The carbon cost calculator 1636 may be configured to incorporate a cost of carbon dioxide production (and/or other greenhouse gases) into the objective function used by the optimal allocator 1624. The carbon cost may be a real cost of carbon (e.g., by governmental applied tariffs) or a self-imposed cost of carbon in order to cause the optimal allocator to choose less carbon intensive allocations (e.g., to meet sustainability objectives, etc.). The cost of carbon can be based on the production of carbon dioxide (and/or other greenhouse gases) associated with operating the cooling systems of the data center. Nonlimiting examples of other greenhouse gases that may be included by the carbon cost calculator 1636 include methane, nitrous oxide, and sulfur dioxide. The carbon cost calculator 1636 may use carbon emissions from scope 1 (e.g., onsite carbon emissions for example from burning fossil fuels), scope 2 (e.g., carbon emissions associated with the generation of electricity and/or other resources used by the data center), and/or scope 3 (e.g., carbon emissions used along the entire supply chain (e.g., transporting coal to produce the electricity). Carbon emissions, cost of carbon, etc. as used herein include within their scope other greenhouse gases as described.

In some embodiments, the carbon cost calculator 1636 includes the cost of carbon as added as another term in the objective function. For example, a carbon emissions rate factor may be associated with one or more utility consumption rates as shown in:

$$J ( θ ) = {\sum }_{t ∈ h} {\sum }_{u ∈ U} {c}_{u , t} {U}_{u , t} ( θ ) + {c}_{CO 2 , t} {r}_{u , CO 2 , t} {U}_{u , t} ( θ ) ,$$

where c_{CO2,t} is the cost of carbon emissions (e.g., in $/tonne) at a given time t and r_{u,CO2,t} is the rate at which carbon emissions are produced per unit of utility consumption (e.g., tonnes/kWh). Advantageously, such an objective function can be used to reduce and/or prevent additional greenhouse gas emissions (e.g., by optimizing the amount of greenhouse gas emissions of the system) and/or monitor, track, and/or verify greenhouse gas emission reductions.

In some embodiments, the data center may have a target (e.g., a goal, a mandate, etc.) for carbon emissions over a given time period (e.g., within a calendar year, a quarter, etc.). In the presence of a target for carbon emissions, the objective function may be treated as a tiered rate structure. If the time period over which the carbon emissions target is calculated aligns with the prediction horizon the cost function may be modified to include a total cost of carbon, as in

$$J ( θ ) = {\sum }_{t ∈ h} {\sum }_{u ∈ U} ( {c}_{u , t} {u}_{u , t} ( θ ) + {c}_{CO 2 , t} {r}_{u , CO 2 , t} {U}_{u , t} ( θ ) ) + {C}_{CO 2 , p e n a l t y}$$

where constraints are added to the optimization problem to calculate the penalty cost C_{CO2,penalty}≥c_{CO2,target} (Σₜₑₕ Σ_{uϵU}c_{CO2,t}r_{u,CO2,t}U_{u,t}(θ)−U_{CO2,target}) where c_{CO2,target} is a penalty cost that is applied to emissions above the target U_{CO2,target}. In some embodiments, the time period over which the carbon emissions target is calculated does not align with the prediction horizon the cost function and the carbon emissions rate is be adjusted during operations in order to hit the target at the end of the time period over which the emissions target is calculated. Generating a carbon emissions plan that hits the target and adjusting the cost of carbon emissions c_{CO2,t} can be performed in a method similar to generating a run hours plan and adjusting the cost of maintenance per run hour as described in the '935 patent, the entire contents of which is herein incorporated by reference.

The objective weighting 1638 may be configured to apply weights to components of the objective function. For example, the optimal allocator 1624 may perform a multi-objective optimization wherein sustainability goals, maintenance goals, etc. are combined by applying weights to terms in the objective function and/or adding a term to the objective function for a goal that does not directly affect the cost of data center operations. For example, there may not be a true cost of carbon emissions (e.g., there are no governmental tariffs, penalties, etc. that are associated with emissions), but the data center may still wish to limit carbon emissions in some way. Additionally or alternatively, water usage may have a direct cost, but for the purposes of sustainability the data center may wish to further limit its water consumption.

The objective weighting 1638 may be configured to apply weights to components of the objective function for each of the multi-objectives as in:

$$J ( θ ) = {\sum }_{t ∈ h} {\sum }_{u ∈ U} ( {w}_{cost , t} {c}_{u , t} {U}_{u , t} ( θ ) + {w}_{CO 2 , t} {r}_{u , CO 2 , t} {U}_{u , t} ( θ ) ) + {w}_{water , t} {U}_{water , t} ( θ ) ,$$

where the weights w_{cost,t}, w_{CO2,t}, and w_{water,t} are the weights given to cost, CO₂ emissions and water usage, respectively. In some embodiments, other terms and/or weights can be included in the multi-objective objective function (e.g., weight may be given to expected down time, run hours on equipment that is difficult to maintain, etc.). In addition, any number of weights may be used. When performing multi-objective optimization, the objective weighting 1638 may request simulated optimal allocation of the data center heat generation to be performed (e.g., for a month, a year, etc.) by the optimal allocator 1624. The resultant information may be displayed on a user interface and an operator can choose the weights that produce an outcome that is most in line with the goals of the data center. Additional information related to multi-objective building control and/or optimization with carbon emissions can be found in U.S. Publication No. 2023/0020417 published on Jan. 19, 2023 and U.S. Publication Number 2023/0253787 published on Aug. 10, 2023, the entire contents of both are herein incorporated by reference.

In some embodiments, the stochastic objective calculator 1640 is configured to calculate stochastic objective functions. Stochastic objective functions include objectives that are calculated from several operational scenarios. For example, the stochastic objective calculator 1640 may calculate a statistic of a number (e.g., 100, 1000, etc.) of different heat generation scenarios (e.g., from different computer utilization scenarios) and/or weather scenarios. The optimal allocator 1624 may minimize a value at risk (VaR) statistic calculated by the stochastic objective calculator 1640 (e.g., the 95^{th} percentile of cost, the 90^{th} percentile of operational costs, etc.). The optimal allocator 1624 may minimize a conditional value at risk (CVar) statistic calculated by the stochastic objective calculator 1640 (e.g., the average cost of the highest 5% of the scenarios, etc.).

In some embodiments, the stochastic objective calculator 1640 may also add penalties for violating certain constraints. For example, a constraint can be included as a soft constraint by adding a penalty cost as in,

$$J ( θ ) = {\sum }_{t ∈ h} {\sum }_{u ∈ U} {c}_{u , t} {U}_{u , t} ( θ ) + {p}_{t} ,$$

and constraining pₜ by pₜ≥0 and pₜ≥ρₜΔx, where ρₜ is the penalty per unit of constraint violation and Δx is the constraint violation. Data centers may be subjected to quick and unexpected spikes in computer utilization (e.g., from streaming of a live event, a new update to downloadable software, etc.). In some embodiments, it is advantageous to include a reserve capacity constraint such that the equipment can provide an amount (e.g., 10%, 20%) of more cooling to each of the computer racks and/or rack groups without violating a constraint (e.g., a switching constraint or a minimum off time constraint). Additionally or alternatively, a reserve capacity constraint may be such that the currently running equipment can provide an amount (e.g., 10%, 20%) of more cooling to each of the computer racks and/or rack groups (e.g., the currently running equipment has enough extra capacity to meet the needs of a computer rack that increases utilization rapidly without turning on additional equipment). The reserve capacity constraint can be implemented as a penalty where the constraint violation, Δx, is the difference between the target reserve capacity and the actual reserve capacity. Additional information related to stochastic optimization can be found in U.S. Pat. No. 10,739,742 ('742 patent) granted on Aug. 3, 2020, the entire contents of which is herein incorporated by reference.

In some embodiments, the objective generator 1630 or the stochastic objective calculator 1640 include penalties for violating load balance constraints. A violation of a load balance constraint may indicate that the heat generated by a computer, rack, or rack group is not allocated to a cooling system. Physically, a computer, etc. that does not receive enough cooling may either slow down (e.g., perform fewer computations than expected) so that the generated heat ultimately balances with the allocations or the processors will heat causing their temperature to rise. If the temperature of the processor becomes too high, the equipment may fail or the computer may be forced to slow down (e.g., by low level firmware on the computer).

The penalty per unit of constraint violation, ρₜ, may be based on the type of equipment for which the load balance constraint is violated. For example, it may be more costly to replace GPUs or to throttle (e.g., slow down, etc.) computations being performed by GPUs than throttling or replacing CPUs. The objective generator 1630 or objective calculator 1640 may generate an objective function wherein the penalty rate depends on the type of hardware that generated the heat for which not enough heat rejection is allocated (e.g., the hardware that is not receiving the required cooling capacity). For example, the penalty per unit of constraint violation may be a first value for violations involving loads from CPUs and a second (e.g., larger) value for violations involving loads from GPUs.

In some embodiments, the stochastic objective calculator 1640 is configured to add to the objective function the number of additional equipment that must turn on under increased load scenarios. For example, the optimization problem may determine allocations for multiple scenarios at different load increases (e.g., increase by a 20%, 30%, etc. or increased to the 90^{th} percentile load prediction). The number of additional equipment that must turn when the data center is subjected to an increase in load may each contribute some weight to the objective function, for example as part of a multi-objective optimization.

### Control Constraints

In some embodiments, the optimal allocator 1624 is configured to find a solution to the optimal allocation problem subject to various constraints determined by the constraint generator 1650. Different types of constraints may be generated by different instruction sets including a heat balance constraint generator 1652, an equipment model constraint generator 1654, a switching constraint generator 1656, a minimum on/off time constraint generator 1658, and a reserve capacity constraint generator 1660.

The heat balance constraint generator 1652 may be configured to generate constraints that cause the optimal allocator 1624 to determine allocations (e.g., solutions to the optimization problem) for which the heat generated by each computer, computer rack, and/or rack group is balanced by an associated heat rejection capability of either air or water provided by the air cooling system 1402 and/or the water cooling system 1502. For example, the heat balance constraint generator 1652 may generate constraints of the form,

$${l}_{r , t} = {\sum }_{s ∈ S} {θ}_{sr , t} ,$$

where l_{r,t} is the heat generated (e.g., kW, etc.) by the r^{th} load (e.g., computer, computer rack, or rack group) and θ_{sr,t} is the amount of heat allocated from the r^{th} load to the s^{th} cooling system (e.g., θ_{sr,t} is the amount of heat from the r^{th} load that is to be rejected by the s^{th} cooling system). The heat balance constraint generator 1652 may generate a similar constraint for each of the computers, computer racks, or rack groups (e.g., for each load r∈R). In some embodiments, the equality constraint may be converted to an inequality constraint (e.g., less than or equal to) to ensure that the total allocation is at least as large as the load. The heat balance constraint generator 1652 may, for any of the constraints described herein, generate similar constraints for each element of the time horizon (e.g., for each t∈h), for each computer, computer rack, or rack group (e.g., for each load r∈R), and/or for each cooling system (e.g., for each system s∈S). In some embodiments, the same index on each side of the equality or inequality constraint indicates that the constraint can be repeated for all such indexes.

The heat balance constraint generator 1652 may also be configured to generate constraints that cause the optimal allocator 1624 to determine allocations (e.g., solutions to the optimization problem) for which the air cooling system 1402 and/or the water cooling system 1502 are operating to reject the total amount of heat allocated to the respective cooling system. For example, the heat balance constraint generator 1652 may generate constraints of the form,

$${P}_{s , t} = {\sum }_{r ∈ R} {θ}_{sr , t} ,$$

where P_{s,t} is the total heat rejection (e.g., kW, etc.) by the s^{th} cooling system (e.g., air cooling system 1402 and/or the water cooling system 1502) and θₛᵣ is the amount of heat allocated from the r^{th} load to the s^{th} cooling system (e.g., θ_{sr,t} is the amount of heat from the r^{th} load that is to be rejected by the s^{th} cooling system). The heat balance constraint generator 1652 may generate a similar constraint for each of the cooling systems. In some embodiments, the equality constraint may be converted to an inequality constraint (e.g., greater than or equal to) to ensure that the heat rejection is at least as large as the load. The heat balance constraint generator 1652 may further constrain Pₛ to satisfy minimum and maximum device capacities via constraints of the form,

$${μ}_{s}^{-} {X}_{s , t} \leq {P}_{s , t} \leq {μ}_{s}^{+} {X}_{s , t} ,$$

where

$${μ}_{s}^{-} and {μ}_{s}^{+}$$

are the minimum heat rejection capacity of the s^{th} cooling system, and X_{s,t} is a binary variable equal to 1 if the s^{th} system is currently running and 0 otherwise. It is noted that the maximum/minimum heat rejection capacity may also be a function of time (e.g., based on current conditions, damper or other actuator positions, etc.).

Certain physical systems may also limit how the heat rejection capability of a cooling system is distributed across all the computers, racks of computers, or rack groups served by the cooling system. For example, an air distribution system may not have dampers and cooled air is distributed based on the air flow resistances within the air distribution system. The heat balance constraint generator 1652 may generate constraints for each cooling system of the form and for each rack,

$${ρ}_{sr}^{-} {P}_{s , t} \leq {θ}_{sr , t} \leq {ρ}_{sr}^{+} {P}_{s , t} ,$$

where

$${ρ}_{sr}^{-}$$

is the minimum fraction (e.g. between 0 and 1 inclusive) of the total heat rejection from cooling system s that can be allocated to rack r and where

$${ρ}_{sr}^{+}$$

is the maximum traction of the total heat rejection from cooling system s that can be allocated to rack r. It is noted that the maximum/minimum fraction of heat rejection may also be a function of time (e.g., based on current conditions, damper or other actuator positions, etc.).

In some embodiments, the additional constraints are added to account for second law (e.g., of thermodynamics) considerations. If water is provided to a computer rack at 42° F. for indirect or direct liquid cooling also providing air at 42° F. may provide less additional cooling to the rack than expected. Additional constraints may be added to account for this loss of heat rejection capability at the rack. For example, the capacity of a water cooling system 1502 may be reduced because if the chilled water is supplied at an elevated temperature so that the air can further cool the rack, the water cooling system may be unable to provide its designed maximum heat rejection (e.g., due to flow limitations etc.). Additionally or alternatively, constraints related to the allocation of a rack's heat generation to the two heat rejection capabilities (chilled water and cooled air) may be restricted to operate within a specific ratio if both are allocated. For example, if only one heat rejection capability is operating then that heat rejection capability can be allocated 100% of the heat generation (and the other 0%, but if both are operating it may be necessary to constrain the allocations such that the water cooling system rejects between 60% and 90% of the heat.

In some embodiments, the loads (e.g., the generated heats, l_{r,t}) are divided (e.g., partitioned, segmented, etc.) into loads generated by CPUs of the r^{th} load and GPUs of the r^{th} load. For example, the allocations may still be constrained to satisfy that the allocations meet the total load as in:

$${l}_{r , CPU , t} + {l}_{r , GPU , t} = {\sum }_{s ∈ S} {θ}_{sr , t} ,$$

with the additional index to indicate if the load is related to (e.g., generated by) CPUs or GPUs. By dividing the load the constraint generator 1650 can generate constraints that relate specifically to GPUs and/or CPUS. The constraint generator 1650 may generate one or more constraints of the form:

$${ξ}_{rc , CPU} {l}_{r , CPU , t} + {ξ}_{rc , GPU} {l}_{r , GPU , t} = {\sum }_{s ∈ S} {ψ}_{src} {θ}_{sr , t} , or$$

$${ζ}_{rc , CPU} {l}_{r , CPU , t} + {ζ}_{rc , GPU} {l}_{r , GPU , t} \leq {\sum }_{s ∈ S} {υ}_{src} {θ}_{sr , t} ,$$

ξ_{rc,CPU}, ξ_{rc,GPU}, and ψ_{src} are constraint parameters for the constraint with index c. The constraint allows flexibility in the specification of how certain CPU and/or GPU loads must be satisfied.

It may be desired to serve all GPUs with liquid cooling and/or the heat allocations (e.g., the heat to be rejected, θ_{sr,t}). A constraint may be generated that ensures at least as much liquid cooling is allocated as the amount of heat generated by the GPUs by setting ζ_{rc,CPU}=0 and ζ_{rc,GPU}=1 for all loads r and v_{src}=1 for all s∈S_{water} (e.g., all water cooling systems) and v_{src}=0 for all s∈S_{water} (e.g., all air cooling systems) which reduces to

$${l}_{r , GPU , t} \leq {\sum }_{s ∈ {S}_{water}} {θ}_{sr , t} .$$

Similarly, if it is desired that the GPU load is to be satisfied by water-based cooling and the CPU load satisfied by air-based cooling, the equality constraints can be used. ξ_{rc,CPU}=0 and ξ_{rc,GPU}=1 for all loads r and ψ_{src}=1 for all s∈S_{water} (e.g., all water cooling systems) and ψsrc_{src}=0 for all s∈Sₐᵢᵣ (e.g., all air cooling systems) for one set of constraints and ξ_{rc,CPU}=1 and ξ_{rc,GPU}=0 for all loads r and ψ_{src}=0 for all s∈S_{water} (e.g., all water cooling systems) and ψsrc_{src}=1 for all s∈Sₐᵢᵣ (e.g., all air cooling systems) for a second set of constraints.

The constraint generator 1650 may additionally or alternatively generate constraints that ensure at least a fraction of a particular load is served by allocations from a particular type of system. For example, if at least 40% of the GPU-based load is to be allocated to water cooling systems, the constraint generator 1650 may generate a constraint with ζ_{rc,CPU}=0 and ζ_{rc,GPU}=0.4 for all loads r and v_{src}=1 for all s∈S_{water} (e.g., all water cooling systems) and v_{src}=0 for all s∈Sₐᵢᵣ (e.g., all air cooling systems).

In some embodiments, the equipment chilling water to reject the heat may operate at different chilled water temperature setpoints in order to serve the equipment efficiently. For example, chillers may operate more efficiently at elevated chilled water temperatures, but may not be able to meet load with appropriate flow rates if the temperature is too high. In some embodiments, the GPUs may require lower temperature water in order to reject the heat generated by the GPUs. CPUs, on the other hand, may operate at the reduced temperature, however, in order to take advantage of efficiencies associated with some chillers (or other water cooling equipment) operating at a higher temperature, CPUs may alternatively be supplied with higher temperature water. The constraint generator 1650 may generate constraints to ensure that enough heat is rejected by chillers operating at the reduced temperature such that all heat generated by GPUs can be rejected at the reduced temperature. In some embodiments, the constraints have the form:

$${l}_{r , GPU , t} = {\sum }_{s ∈ S} {θ}_{srm = 1 , t} ,$$

$${l}_{r , CPU , t} = {\sum }_{s ∈ S} {θ}_{srm = 2 , t} ,$$

$${θ}_{srm = 1 , t} \leq {μ}_{s}^{+} {M}_{sm = 1 , t} ,$$

$${θ}_{srm = 2 , t} \leq {μ}_{s}^{+} {M}_{sm = 2 , t} ,$$

$${M}_{sm = 1 , t} + {M}_{sm = 2 , t} \leq 1.$$

The constraint generator 1650 may generate the first constraint to ensure that the GPUs are allocated to a system operating in mode 1 (e.g., m=1), for example, representing a mode operating at the reduced temperature setpoint. The constraint generator 1650 may generate the second constraint to ensure that the CPUs are allocated to a system operating in mode 2 (e.g., operating at an elevated temperature setpoint). The constraint generator 1650 may generate the third, fourth, and fifth constraint to ensure a device only operates in one of the modes. The constraint generator 1650 may introduce additional decision variables M_{sm=1,t} indicating the mode within which a system is operating. For example, if a system s is operating in mode 1, then M_{sm=1,t}=1, M_{sm=2,t}=0. The constraint generator 1650 may introduce additional constraints and decision variables in a similar fashion if the equipment can operate in more than two modes. For example, the system may operate at three temperatures with the third temperature serving another class of computer hardware and/or a subdivision of the CPUs or GPUs.

In some embodiments, one or more air cooling systems 1402 may use chilled water produced by a water cooling system (e.g., heat rejected by the air cooling system is transferred to the water cooling system through heat exchange). The heat balance constraint generator 1652 may generate balance constraints that cause the optimal allocator 1624 to determine allocations (e.g., solutions to the optimization problem) for which the water cooling systems 1502 are operating to reject the total amount of heat allocated to the respective cooling system from both the direct loads and the indirect loads of downstream air cooling system(s) to which they are connected. For example, the heat balance constraint generator 1652 may generate constraints of the form,

$${P}_{s , t} = {\sum }_{r ∈ R} {θ}_{sr , t} + {\sum }_{{s}^{′} ∈ {S}_{s}^{′}} {P}_{{s}^{′} , t} ,$$

where the constraint for P_{s,t} has been modified to include an allocation for the heat P_{s′,t} of all downstream cooling systems

$${s}^{′} ∈ {S}_{s}^{′}$$

of the s^{th} cooling system (e.g., for a water-cooling system ‘Water1’ that serves two downstream air-cooling systems ‘Air1a’ and ‘Air1b’, the set of downstream equipment is

$${S}_{Water 1}^{′} = \{ Air 1 a , Air 1 b \} ,$$

and thus the constraint for P_{Water1} also accounts for the chilled water needed to generate P_{Air1a} and P_{Air1b}). The heat balance constraint generator 1652 may generate a similar constraint for each of the water cooling systems.

In some embodiments, the optimal allocator 1624 may remove allocations θₛᵣ that are not physically possible. For example, the systems may not be connected. For example, as shown in FIG. 15 heat generated by rack group 1504c cannot be allocated to water cooling system 1502b because no piping exists to supply chilled water to the rack group 1504c nor is the rack group 1504c shown to be compatible with liquid cooling. In some embodiments, the optimal allocator 1624 may instead generate allocations for all connections between cooling system and heat generation (e.g., computer, computer rack, or rack group), even if the connection is not possible or does not exist. The constraint generator 1650 may generate constraints that force the invalid allocations to equal zero (e.g., by setting both the parameters to zero TUI

$${ρ}_{sr}^{-} and {ρ}_{s r}^{+}$$

parameters to zero for disallowed connections). Advantageously, this may allow for code reuse and simplified support without substantially increasing computational effort by the optimal allocator 1624 as many optimization routines will include a preprocessor that eliminates the variable constrained to zero internally.

The constraint generator 1650 may include the equipment model constraint generator 1654 to determine the resource consumption (e.g., utility used, etc.) by an air cooling system 1402 and/or a water cooling system 1502. The equipment model constraint generator 1654 may generate different types of constraints for different cooling systems. Various nonlimiting examples of equipment model constraints are described herein.

The equipment model constraint generator 1654 may be configured to generate linear constraints for some cooling systems. A linear constraint has the form:

$${U}_{s , u , t} = {β}_{s , u , t} {P}_{s , t} ,$$

where U_{s,u,t} is the resource consumption of utility u by the cooling system s per unit of heat rejection, P_{s,t} and β_{s,u,t} is a coefficient that relates the utility usage to the amount of heat rejection (e.g., related to the efficiency or related to a coefficient of performance, etc.). The efficiency ε_{s,u,t} can depend on time, for example, through other variables like the weather conditions (e.g., wetbulb, drybulb, etc.). In some embodiments, optimization of an individual cooling system is performed to determine a best fit coefficient to use. For example, low-level optimization of the individual equipment and setpoints within a cooling system may be performed to determine the typical efficiency of the system.

In some embodiments, the equipment model constraint generator 1654 includes constraints related to values of production that cannot be performed by the cooling system. For example, a chiller of a water cooling system 1502 may have a minimum amount of heat rejection while in operation to maintain stable control. The equipment model constraint generator 1654 may generate a constraint that causes the water cooling system 1502 to either be off (e.g., not operating) or to operate at a heat rejection greater than the smallest minimum amount of heat rejection of the chillers within the water cooling system 1502.

In some embodiments, the equipment model constraint generator 1654 may be configured to generate nonlinear constraints for some cooling systems. Nonlinear constraints may have the form,

$${U}_{s , u , t} = {ℬ}_{s , u , t} ( {P}_{s , t} , φ ) ,$$

where φ represents factors in addition to the total heat rejection that affect the utility consumption (e.g., weather, return air/water temperature, etc.). In some embodiments, thermoelectric cooling is used to enhance the efficiency of water and air based heat rejection capability. Thermoelectric cooling may be included in φ and may be a variable that is not optimized or may be included as an optimization variable. In some embodiments, nonlinear constraints are linearized to use a computationally efficient optimization algorithm. For example, nonlinear equipment models can be converted to piece-wise linear models. Additionally or alternatively, nonlinear equipment models that are convex may use multiple constraints to generate a suitable model. For example, several constraints may be generated each constraining the utility usage above a line. For example, the equipment model constraint generator 1654 may be configured to convert a convex equipment model into multiple inequality constraints as in,

$${U}_{s , u , t} \geq {β}_{s , u , t}^{( 1 )} {P}_{s , t} + {b}_{s , u , t}^{( 1 )} .$$

$$\begin{matrix}{U}_{s , u , t} \geq {β}_{s , u , t}^{( 2 )} {P}_{s , t} + {b}_{s , u , t}^{( 2 )} \\ ⋮\end{matrix}$$

Additional information related to generating constraints based on equipment models can be found in U.S. Pat. No. 10,706,375 granted on Jul. 7, 2020, the entire contents of which is herein incorporated by reference.

The switching constraint generator 1656 is configured to generate constraints that limit the number of cooling systems that are switched on/off at any given time element of the horizon. For example, to increase operational stability it may be desired that no more than one cooling system be turned off at a given time element and no more than one cooling system be turned on at a given time element. The switching constraint generator 1656 may introduce additional variables in order to enforce the constraint. For example, the switching constraint generator 1656 may include a variable associated with the operating state of the equipment (e.g., on or off), X_{s,t} as well as the operating state of the equipment in the previous time period, σ_{s,t}. By definition the switching constraint generator 1656 may generate a constraint,

$${σ}_{s , t} = {X}_{s , t - 1} ,$$

for each cooling system and time element of the prediction horizon. The net change in equipment cooling systems turned on may be constrained using:

$${\sum }_{s ∈ S} {X}_{s , t} - {σ}_{s , t} \leq {π}_{net , t} ,$$

where π_{net,t} is the maximum net increase in systems that are operating. The maximum number of equipment turned on (or off) at any given time element may be constrained by introducing new variables representing a switch from the off state to the operating state (or from operating to off) using:

$${δ}_{s , t}^{+} \geq {X}_{s , t} - {σ}_{s , t} ,$$

$${δ}_{s , t}^{+} \geq 0$$

$${δ}_{s , t}^{-} \geq {σ}_{s , t} - {X}_{s , t}$$

$${δ}_{s , t}^{-} \geq 0$$

where

$${δ}_{s , t}^{+}$$

represents switching the system s on at time t and

$${δ}_{s , t}^{-}$$

represents switching the system s off at time t. The total number of systems turned on (or off) may then be limited using the defined switching variables in:

$$\begin{matrix}{\sum }_{s ∈ S} {δ}_{s , t}^{+} \leq {π}_{+ , t} \\ {\sum }_{s ∈ S} {δ}_{s , t}^{-} \leq {π}_{- , t}\end{matrix} ,$$

where π_{+,t} is the maximum number of systems that can be turned on at time t and π_{-,t} is the maximum number of systems that can be turned off at time t.

In some embodiments, it is important to limit number of allocation θₛᵣ that can switch from zero to non-zero, or from non-zero to zero. Changing an allocation from zero to nonzero (or nonzero to zero) may require opening and closing valves (e.g., for water cooled racks) and opening and closing dampers (e.g., for air cooled racks). Excessive switching can lead to poor control of computer temperatures and/or increased maintenance. Variables similar to those above for counting the number of times a cooling system switches from a non-zero heat rejection to zero heat rejection (or vice-versa) may be added for the allocations θₛᵣ.

In some embodiments, the constraint generator 1650 is configured to cause the optimal allocator 1624 to determine allocations that do not violate minimum on time or minimum off time constraints. Additional variables may be added to the optimization problem to constrain minimum on and minimum off timers. For example, the minimum on/off constraint generator 1658 may include a variable that tracks any switches that occurred i time periods ago,

$${\partial }_{i , s , t}^{-} ,$$

for switching off and

$${\partial }_{i , s , t}^{+}$$

for switching on. By definition, the minimum on/off constraint generator 1658 may generate the constraints,

$$\begin{matrix}{\partial }_{i , s , t}^{-} = {δ}_{s , t - i}^{-} \\ {\partial }_{i , s , t}^{+} = {δ}_{s , t - i}^{+}\end{matrix} .$$

Such variables may be added for i such that the difference in time between t and t−i is greater than the longest minimum on (or off) time constraint. To constrain the minimum on time the switching constraint generator 1656 may generate constraints of the form,

$${δ}_{s , t}^{+} + {\partial }_{i , s , t}^{-} \leq 1 , and$$

$${δ}_{s , t}^{-} + {\partial }_{i , s , t}^{+} \leq 1.$$

The first constraint causes the optimal allocator 1624 to not turn on the cooling system s if any of the additional variables are tracking a previous switch off and the second constraint causes the optimal allocator 1624 to not turn off the equipment of any of the additional variables are tracking a previous switch on.

The reserve capacity constraint generator 1660 may be configured to generate constraints that cause the optimal allocator 1624 to find allocations that limit the number of cooling systems that must turn on (or off) in the event of a rapid increase in computer utilization at the data center. In some embodiments, limiting the number of cooling systems that must turn on (or off) includes generating alternative plan variables for every decision of the optimization problem. The alternative plan variables can be produced for the entire horizon or for a limited number of time elements into the future for which it is desired to limit the switching in the event of increased load. Constraints for the alternative plan may be the same as the original optimization problem (e.g., the nominal plan) except that the load may be increased. For example, the constraint that ensures that the heat generation is allocated may be modified with a different amount of heat generation as in,

$${λ}_{r , t} = {\sum }_{s ∈ S} {θ}_{sr , t} ,$$

where λ_{r,t} is the alternative (e.g., increased) heat generation from the computers under the increased utilization. Variables for alternative operating states of the cooling systems, χ_{s,t}, are also generated. The reserve capacity constraint generator 1660 may add linking constraints that link the alternative allocations for the increased load to the original allocations. For example, the reserve capacity constraint generator 1660 may limit the net number of cooling systems that can be turned on by generating the constraint,

$${\sum }_{s ∈ S} ( {X}_{s , t} - {𝒳}_{s , t} ) \leq {π}_{net , t}^{′} .$$

Additionally or alternatively, the maximum number of equipment turned on at any given time element may be constrained by introducing new variables representing a change between the original allocations and the alternative allocations:

$${δ}_{s , t}^{′} \geq {X}_{s , t} - {𝒳}_{s , t} , {δ}_{s , t}^{′} \geq 0$$

where δ′_{s,t} represents switching the system s on at time t in the alternative plan. The total number of cooling systems additionally selected to be operating in the alternative allocation may be limited using the defined switching variables in:

$${\sum }_{s ∈ S} {δ}_{s , t}^{′} \leq {π}_{+ , t}^{′} .$$

The heat allocator 1604 may include equipment models 1616 to store models of equipment that are used by the equipment model constraint generator 1654 to generate the constraints that determine the utility usage by an air cooling system 1402 and/or a water cooling system 1502. The equipment models 1616 may store any of the models used by the heat allocator 1604. The equipment models 1616 may store the linear or nonlinear models used to determine the resource consumption of the air cooling systems 1402 and/or the water cooling systems 1502. For example, the equipment models 1616 may store the models of the form U_{s,u,t}=β_{s,u,t}P_{s,t}, U_{s,u,t}= [symbol] _{s,u,t}(P_{s,t},φ), a Gordon Ng model of chillers, fan models of CRAC and/or CRAH units, NTU effectiveness models for towers, and/or any other model that may be used to perform optimal allocation of heat generated by computers in a data center. The models of the equipment models 1616 may be used either directly by the optimal allocator 1624 and/or to determine simplified models that can be used by the optimal allocator 1624 to reduce the computational complexity of the optimization problem.

In some embodiments, the alternative (e.g., increased) heat generation, λ_{r,t}, may depend on the type of hardware for which the reserve capacity is generated. For example, the alternative heat generation may be a fraction increase compared to the predicted load, as in λ_{r,t}=1.30l_{r,t}. The fractional increase may depend on the type of hardware for the r^{th} computer, rack, or rack group. For example, for GPUs the alternative heat generation may be expressed as λ_{r,GPU,t}=1.30l_{r,GPU,t}, whereas for CPUs the alternative heat generation may be expressed as λ_{r,CPU,t}=1.10l_{r,CPU,t}. By using a larger reserve capacity for GPUs the heat allocator 1604 may ensure that the GPUs have enough cooling capacity even if a large processing spike occurs.

The equipment models 1616 may also store models related to the computer racks and/or the connectivity between the cooling systems and the computer racks. Manufacturer's data related to the power usage of the computers within the data center may be used to constrain the coefficients that relate computer utilization to heat generation used by the heat generation predictor 1622). For example, if the specification says the maximum power usage by the computer is 200 W the coefficients in the linear model, αₖ, could be bound between 140 W and 260 W for that computer type (e.g., ±30% from the manufacturer's specification). In some embodiments, a user interface allows a user of the heat allocator 1604 to enter interconnections between the cooling systems and the computer racks of the data center. The interconnectivity may be used to generate the load balance constraints used when determining how heat generated by the computers is allocated to the different modes of heat rejection provided by the air cooling systems 1402 and the water cooling systems 1502.

In some embodiments, the equipment modeler 1618 is configured to determine the models used by the equipment model constraint generator 1654 to generate the constraints that determine the utility usage by an air cooling system 1402 and/or a water cooling system 1502. For example, the equipment modeler may obtain training data including historical data of the amount of heat rejection performed by the cooling systems and/or equipment thereof, the utility consumption (e.g., water, electricity, etc.), and any other conditions that may affect the utility consumption of the cooling systems and/or equipment thereof (e.g., weather conditions). The equipment modeler 1618 may perform least squares regression to find parameters that best fit the training data. For example, a model describing each cooling system and/or equipment thereof may be determined using least squares regression

In some embodiments, the equipment modeler 1618 is configured to generate cooling system models from the underlying equipment models of the cooling systems. For example, a water cooling system 1502 may include four chillers and a number of pumps and towers. For any heat rejection amount it is possible to determine the best combination of chillers to use (e.g., by exhaustive search, optimization algorithm, and/or a heuristic), and the best equipment setpoints, and determine the resource consumption of the whole water cooling system 1502. New training data may be generated from the multiple load conditions and used to perform least squares regression (e.g., curve fitting) to determine a model of the water cooling system 1502. Operationally, the mapping from heat rejection amount to a respective combination of chillers and respective setpoints can be saved (e.g., by the equipment models 1616) and used to operate the equipment once an allocation is determined by the optimal allocator 1624 or the heuristic allocator 1625.

The equipment modeler 1618 may perform similar calculations to determine a model for an air cooling system. An air cooling system may include several CRACs and/or CRAHs that can be combined into a model for use by the equipment modeler 1618. Additionally or alternatively, a CRAC may have several stages of cooling that can be combined into a single model. It is noted that the interconnectivity of equipment (e.g., chillers, CRACs, CRAHs, etc.) determines (e.g., constrains, restricts, etc.) how equipment can be combined into one or more air cooling systems and/or water cooling systems that will be used in the allocation problem. For example, combining some CRACs that are configured to provide cooled air to one set of racks with another CRAC that is configured to provide cooled air only to a different set of racks may lead to allocations that cannot be realized by the equipment.

The heat allocator 1604 may include an interface generator 1628 to create a user interface that displays the results of the heat generation allocation produced by either the optimal allocator 1624 or the heuristic allocator 1625. The interface generator 1628 can provide instructions (e.g. JavaScript, Cascading Style Sheets) to the client device 1612 that instruct the client device 1612 how to generate the user interface within a client application (e.g., an internet browser, a proprietary application, etc.). In some embodiments, the interface generator 1628 can provide application programming interfaces (APIs) that cause various functionality of the heat allocator 1604 to be triggered. For example, the application may provide a user interface that executes a callback to an API to cause the heat allocator 1604 to enter an automatic mode and begin sending allocations to the local controllers 1606 to cause the equipment (e.g., the water cooling systems and the air cooling systems) to operate according to the allocations.

The interface generator 1628 may receive information from any of the instruction sets of the heat allocator 1604. For example, the interface generator 1628 may generate a floor plan of the data center as shown in FIG. 13. Color overlays may be used to indicate computer and/or rack temperature. Additionally or alternatively, color overlays may be used to indicate heat generation. In some embodiments, the heat allocator 1604 provides the interface generator with predictions of the heat generation and the user can view future expected performance (e.g., heat generation, temperatures, utilization, etc.) of the data center in the future. In addition to the heat generation, the allocations of the heat generation to the water cooling systems and/or the air cooling systems may be included on the user interface. The allocation may be shown in total (e.g., the total amount of heat rejected by each of the cooling systems) and/or an indication of the connections between each computer rack and its respective cooling system may be included on the user interface and individual allocations may be shown associated with the connection. The estimated cost of cooling the computers of the data center may be calculated from the optimal objective functions and added to the user interface. The estimated cost may be calculated at the data center (e.g., whole facility) level, for each rack, for each cooling system, for each computer, or at any combination of granularities.

In some embodiments, the scenario creator 1626 is configured to generate additional heat generation and/or weather scenarios. Alternative scenarios may be used in stochastic optimization and optimization with reserve capacity as described herein. The scenario creator 1626 may generate scenarios from a distribution around the predicted heat generation and/or weather. For example, the heat generation predictor 1622 may determine a prediction of the utilization and the heat generation over the next two days. The heat generation predictor 1622 may additionally provide a distribution of the expected total heat generation (e.g., in kWh) over the next two days. To determine an allocation that provides reserve capacity (e.g., allows for minimal switching in the event that utilization is unexpectedly high), the scenario creator 1626 may determine an alternative scenario by scaling the predicted heat generation such that the total heat generation over the next two days is in the upper tail of the distribution (e.g., the 90^{th} percentile, 95^{th} percentile, etc.). Alternatively or additionally, the scenario creator 1626 may add an offset to the predicted heat generation such that the total heat generation over the next two days is in the upper tail of the distribution. The scenario creator 1626 may also cause other attributes of the heat generation and/or weather prediction to become more extreme. For example, the scenario creator 1626 may cause the heat generation to increase more rapidly than expected (e.g. between the times 19:30 and 20:00 rather than a more gradual increase between 19:00 and 20:30).

The scenario creator 1626 may provide more than one scenario for the optimal allocator 1624. In some embodiments, the scenario creator 1626 may provide a number of historical heat generation time series from days similar to the current day. The historical heat generation time series may be adjusted (e.g., scaled, etc.) in order to further modify the time series to account for the conditions of the current day.

### Allocating Computer Hardware and Heat Rejection Equipment

In some embodiments, the control constraints of the constraint generator 1650 include terms related to the amount of heat that is generated by CPUs and/or the amount of heat that is generated by GPUs. For example, as previously mentioned, it may be desirable to allocate heat generated by the CPUs to be rejected by higher temperature water and/or by air. The operational efficiency of the equipment may be improved by operating at the higher temperatures. Given that the constraints may account for the amount of heat generated from GPUs and the amount of heat generated by CPUs, the outcome of any control, allocation, or optimization process satisfying such constraints will be influenced by the distribution of heat generation and, consequently, the allocation of compute tasks across the various servers and/or computer racks.

In some embodiments, the data center cooling control system 1600 may simultaneously allocate tasks to different computers, racks, and/or rack groups. For example, the data center cooling control system 1600 may allocate a portion of inbound compute tasks to the GPUs and/or computers (e.g., or racks or rack groups) with GPUs and a portion of the inbound compute tasks to the CPUs and/or computers without GPUs. Depending on the constraints of the heat rejection system, the heat generated by the CPUs may be rejected more efficiently, for example, at an elevated temperature or with cooled air.

In some embodiments, the objective generator 1630 may generate an objective function including the cost and/or resource expenditure of performing the inbound computational task by CPUs and/or GPUs. For example, the objective generator 1630 may generate an objective function that includes a penalty score associated with how long the inbound compute task will take to complete. Tasks that complete within a desired time frame (e.g., before a deadline) may not contribute to the penalty regardless of the amount of time the task takes to complete. Additionally or alternatively, an inbound task may receive a penalty that is a function of the time to completion (e.g., linear, quadratic, etc.). The objective function may also include the cost or amount of electricity consumed to perform the compute tasks and/or the cost or amount of electricity consumed to reject the heat generated by performing the compute tasks. Additionally or alternatively, the objective function may include other resources consumed to reject the generated heat (e.g., water, etc.) and/or production of undesirable pollutants (e.g., CO2, etc.).

In some embodiments, the optimal allocator 1624 may use an objective function and constraints that couple the decisions related to allocating the heat generated to various systems for heat rejection with the decisions related to allocating the inbound compute tasks. For example, the optimal allocator 1624 may solve a coupled problem including both decisions to generate the allocations for the task and the heat rejection allocations simultaneously. Additionally or alternatively, the optimal allocator 1624 may perform a cascaded optimization procedure where the decisions related to allocating the inbound compute tasks are determined prior to allocating the generated heat to various systems. The optimal allocator 1624 may, for example, use an objective function generated by the objective generator 1630 that has a simplified cost for rejecting the heat allocated to different systems of the cooling equipment 1316. While cascading the allocation problems may result in a suboptimal solution, the difference between the coupled allocation problem and the cascaded allocation problem may be small or insignificant. For example, if the difference is small the cost of computing the actual optimal solution (e.g., in power used to perform the computations and to reject the heat of the additional computations) may outweigh the benefits of reaching an optimal solution. It is noted that while a better solution may exist performing cascaded optimization or other heuristic schemes used to reduce the number of computations to achieve a near-optimal solution may still be considered “optimizing” or “performing an optimization process.”

The objective generator 1630 may generate an objective function that considers a shorter horizon than the optimal heat allocation problem. In some embodiments, the optimal allocator 1624 considers only the current time period when allocating the inbound compute tasks. For example, the optimal allocator 1624 may consider the current state of the system when allocating each inbound compute task as it arrives. The optimal allocator 1624 may decide whether to allocate the inbound compute tasks to either CPUs and/or GPUs. The optimal allocator 1624 may consider various factors while making the determination (e.g., by allocating the tasks according to objective functions or constraints including the various factors). For example, the optimal allocator 1624 may consider the total amount of heat generated using CPUs or GPUs. The optimal allocator 1624 may consider the total efficiency in rejecting the heat generated by the CPUs and/or GPUs. The optimal allocator 1624 may consider the amount of time required to complete the tasks using the CPUs and/or GPUs or whether completing the compute tasks is even feasible using the CPUs or the GPUs. In some embodiments, the systems to which inbound compute tasks are distributed may be divided by hardware groups other than GPUs and CPUs. For example, the tasks may be distributed across different hardware ages which may include more than two groups. Such embodiments should also be considered within the scope of the present disclosure.

In some embodiments, the constraint generator 1650 generates load balance or other constraints that include the dependence of the heat generation based upon the compute task allocation. For example, the load balance constraints previously described may be modified to include the dependence on the inbound task allocation. For example, the constraints may be written as:

$${ξ}_{rc , CPU} {l}_{r , CPU , t} ( {B}_{CPU , r , t} ) + {ξ}_{rc , GPU} {l}_{r , GPU , t} ( {B}_{GPU , r , t} ) = {\sum }_{s ∈ S} {ψ}_{src} {θ}_{sr , t} , or$$

$${ζ}_{rc , CPU} {l}_{r , CPU , t} ( {B}_{CPU , r , t} ) + {ζ}_{rc , GPU} {l}_{r , GPU , t} ( {B}_{GPU , r , t} ) \leq {\sum }_{s ∈ S} {υ}_{src} {θ}_{sr , t} ,$$

indicating the dependence of the load components on the utilization of the GPUs and/or CPUs. Similarly, linear constraints may be generated using a constant of proportionality (e.g., α_{GPU}, or α_{CPU} found as described in the section on heat generation prediction),

$${ξ}_{rc , CPU} {α}_{CPU} {B}_{CPU , r , t} + {ξ}_{rc , GPU} {α}_{GPU} {B}_{GPU , r , t} = {\sum }_{s ∈ S} {ψ}_{src} {θ}_{sr , t} , or$$

$${ζ}_{rc , CPU} {α}_{CPU} {B}_{CPU , r , t} + {ζ}_{rc , GPU} {α}_{GPU} {B}_{GPU , r , t} \leq {\sum }_{s ∈ S} {υ}_{src} {θ}_{sr , t} .$$

Additionally, or alternatively the dependence on heat generation may be based on values other than the utilization of GPUs and/or CPUs. For example, the heat generated may be based on the number of computations (e.g., flops, operations, etc.) to be performed by the different hardware classes and/or types.

### Flows of Operation

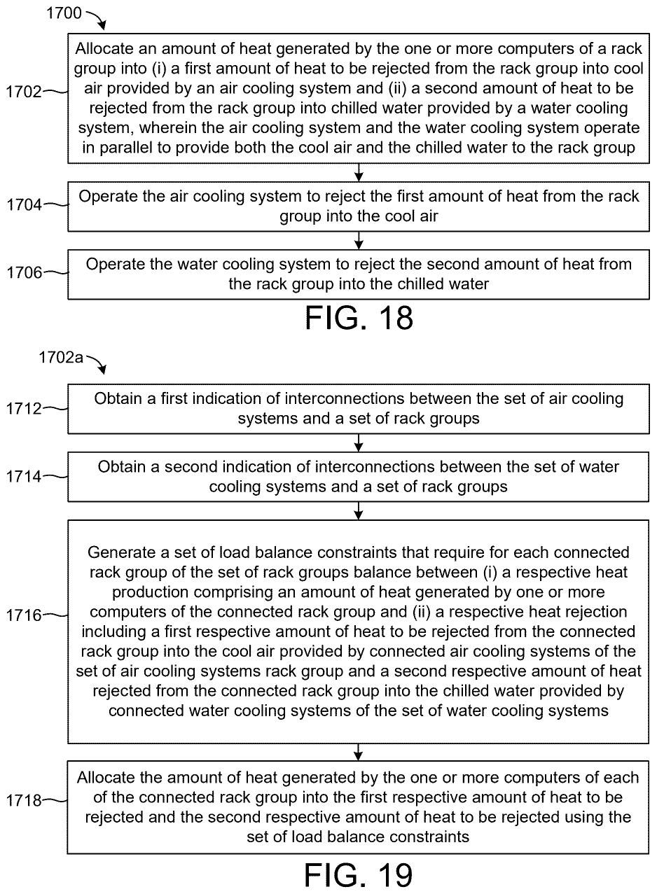

FIG. 18 shows a flow of operations 1700 for operating an air cooling system and a water cooling system according to allocations of heat generated by computers according to some embodiments. The flow of operations 1700 includes allocating an amount of heat generated by the one or more computers of a rack group into (i) a first amount of heat to be rejected from the rack group into cool air provided by an air cooling system and (ii) a second amount of heat to be rejected from the rack group into chilled water provided by a water cooling system, wherein the air cooling system and the water cooling system operate in parallel to provide both the cool air and the chilled water to the rack group. For example, the current heat generation can be estimated from computer utilization (e.g., processor utilization, computer power usage, etc.) of all the computers of the rack, rack group, and/or data center by the heat generation predictor 1622. In some embodiments, the heat generation is predicted and allocations are determined for future time instances as well. Allocation of the heat generation between the air cooling systems and/or the water cooling systems may be performed by the optimal allocator 1624 and/or the heuristic allocator 1625.

Optimal allocations of the heat generated by the computers between the water cooling systems 1502 and the air cooling systems 1402 of the data center may be determined by the optimal allocator 1624. Optimal allocations as used herein refer to allocations that are generated by finding a solution to an optimization problem (e.g., using gradient descent, linear programming, mixed-integer linear programming, nonlinear programming, neural networks, etc.). One skilled in the art will recognize that an optimal allocation found using optimization algorithms may not be the best (e.g., the optimal allocation may not be the most minimizing solution or the most maximizing solution). Some techniques (e.g., those relying on iterations) include various tolerances and stopping criteria to prevent utilizing computational resources to decrease cost and/or improve optimality by an insignificant amount. As used herein the scope of an optimal allocation includes any result (e.g., the allocations) found using an optimization algorithm or by solving an optimization problem including allocations for which a more optimal allocation can be found or that have been subsequently post-processed. In some embodiments, sub-optimal or rule-based allocations are found by the heuristic allocator 1625. The sub-optimal or rule-based allocations may be used as an alternative to the optimal allocations, for example, in a resource-limited environment or in addition to the optimal allocations, for example, in case of a lost connection with the computers performing the optimal allocation.

The optimal allocations may be based on a solution to an optimization problem. For example, the optimal allocations may be based on a solution to:

$${θ}^{*} = arg {min}_{θ} J ( θ ) , subject to$$

$$f ( θ ) \leq 0 , h ( θ ) = 0 ,$$

where J(θ) is the objective function, ƒ(θ) represents nonlinear (and/or linear) inequality constraints, and h(θ) represents nonlinear (and/or linear) equality constraints.

FIG. 19 shows a flow of operations 1702a for allocating heat generation between air and water cooling systems using load balance constraints, according to some embodiments. For example, the flow of operations 1702a may be used to implement operation 1702 of the flow of operations 1700. The flow of operations 1702a may include obtaining a first indication of interconnections between the set of air cooling systems and the set of rack groups in operation 1712 and obtaining a second indication of interconnections between the set of water cooling systems and the set of rack groups in operation 1714.

The flow of operations 1702a may include generating a set of load balance constraints in operation 1716. The load balance constraints may require that for each connected rack group of a set of rack groups there is balance between (i) a respective heat production including an amount of heat generated by one or more computers of the connected rack group and (ii) a respective heat rejection including a first respective amount of heat to be rejected from the connected rack group into the cool air provided by connected air cooling systems of the set of air cooling systems rack group and a second respective amount of heat rejected from the connected rack group into the chilled water provided by connected water cooling systems of the set of water cooling systems. In some embodiments, a portion of the heat rejected by an air cooling system is also rejected by a water cooling system. For example, a chiller providing chilled water to a CRAH.

The heat balance constraint generator 1652 may be configured to generate the load balance constraints. For example, the heat balance constraint generator 1652 may generate constraints of the form,

$${l}_{r , t} = {\sum }_{s ∈ S} {θ}_{sr , t} ,$$

where l_{r,t} is the heat generated (e.g., kW, etc.) by the r^{th} load (e.g., computer, computer rack, or rack group) and θ_{sr,t} is the amount of heat allocated from the r^{th} load to the s^{th} cooling system (e.g., θ_{sr,t} is the amount of heat from the r^{th} load that is to be rejected by the s^{th} cooling system). Such a constraint may be generated for each of the computers, computer racks, or rack groups (e.g., for each load r∈R) of the data center. In some embodiments, an inequality constraint (e.g., less than or equal to) may be used instead of the equality constraint allowing for the cooling systems to potentially underproduce cooling. Additionally or alternatively, the operation 1716 may include generating load balance constraints that are segmented between heat generated by GPUs and/or heat generated by CPUs as previously described herein.

Load balance constraints may also ensure the air cooling system 1402 and/or the water cooling system 1502 are operating to reject the total amount of heat allocated to the respective cooling system. For example, additional load balance constraints may be generated of the form,

$${P}_{s , t} = {\sum }_{r ∈ R} {θ}_{sr , t} ,$$

may be generated, where P_{s,t} is the total heat rejection (e.g., kW, etc.) by the s^{th} cooling system (e.g., air cooling system 1402 and/or the water cooling system 1502) and θ_{sr,t} is the amount of heat allocated from the r^{th} load to the s^{th} cooling system (e.g., θₛᵣ is the amount of heat from the r^{th} load that is to be rejected by the s^{th} cooling system). The heat balance constraint generator 1652 may generate a similar constraint for each of the cooling systems. In some embodiments, the equality constraint may be converted to an inequality constraint (e.g., greater than or equal to) to ensure that the heat rejection is at least as large as the load.

Additionally or alternatively, the one or more air cooling systems may use chilled water produced by a water cooling system (e.g., heat rejected by the air cooling system is transferred to the water cooling system through heat exchange). In some embodiments, the heat rejection constraints of the water cooling systems is of the form,

$${P}_{s , t} = {\sum }_{r ∈ R} {θ}_{sr , t} + {\sum }_{{s}^{′} ∈ {S}_{s}^{′}} {P}_{{s}^{′} , t} ,$$

where the constraint for P_{s,t} has been modified to include an allocation for the heat P_{s′,t} of all downstream cooling systems

$${s}^{′} ∈ {S}_{s}^{′}$$

of the s^{th} cooling system.

After generating the constraints, the flow of operations 1702a may include allocating the amount of heat generated by the one or more computers of each of the connected rack groups into the first respective amount of heat to be rejected and the second respective amount of heat to be rejected using the set of load balance constraints in operation 1718. For example, the allocations may be determined by the optimal allocator 1624 and/or the heuristic allocator 1625 as described herein.

Referring back to FIG. 18, the flow of operations 1700 may include operating the air cooling systems 1402 to reject the first amount of heat from the rack group into the cool air in operation 1704 and operating the water cooling system to reject the second amount of heat from the rack group into the chilled water in operation 1706. Operating the air cooling system 1402 and water cooling system 1502 to reject the heat generation may include communicating the allocations to the local controller 1606. In some embodiments, the local controller 1606 has an internal control process that is configured to operate the equipment according to set points provided by the heat allocator 1604. For example, the local controller 1606 may convert a heat allocation to a supply air temperature setpoint of the CRAC. The local controller 1606 may include the control that causes the CRAC to maintain the determined supply air temperature. In some embodiments, the heat allocator 1604 determines the temperature setpoints and communicates them to the respective local controller 1606. In some embodiments, the heat allocator 1604 directly determines the necessary fan speed and communicates the fan speed to the local controller.

In some embodiments, operating air cooling system 1402 and water cooling system 1502 to reject the heat generation includes operating simulated equipment. For example, the planning tool 902 may include simulated equipment that calculate the resource usage when for a given heat rejection setpoint (e.g., an allocation). During the operations 1704 and/or 1706, the heat allocator 1604 may communicate allocations to the equipment models 920 to simulate operations of the equipment and determine the resulting resource use. For example, the operations 1704 and/or 1706 may include determining the resource use by way of a steady-state equipment model and/or a dynamic model of the equipment.

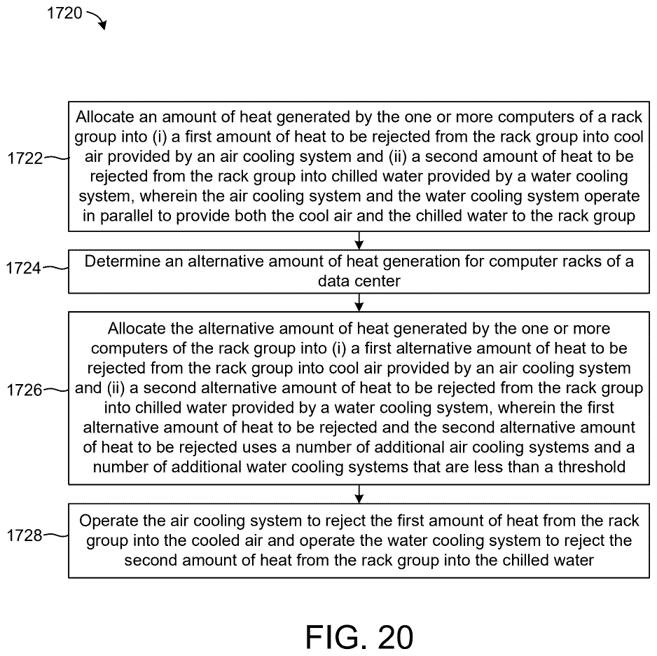

FIG. 20 shows flow of operations 1720 for allocating heat generation according to alternative heat generations that ensure reserve capacity. The flow of operations 1720 includes allocating an amount of heat generated by the one or more computers of a rack group into (i) a first amount of heat to be rejected from the rack group into cool air provided by an air cooling system and (ii) a second amount of heat to be rejected from the rack group into chilled water provided by a water cooling system, wherein the air cooling system and the water cooling system operate in parallel to provide both the cool air and the chilled water to the rack group in operation 1722. This operation may be similar to operation 1702; however, in some embodiments operation 1722 is performed simultaneously (e.g., while solving the same optimization problem) as later operations in the flow of operations 1720 that include allocating heat from an alternative amount of heat generation.

The flow of operations 1720 may include determining an alternative amount of heat generation for computer racks in operation 1724. For example, the scenario creator 1626 may be used to generate the additional heat generation and/or weather scenarios. Alternative heat generation predictions and/or current estimates may be created by modifying the predicted heat generation or the current heat generation. For example, the alternative heat generation may be determined by scaling the nominal prediction to reach a statistical target (e.g., 95^{th} percentile of total load over a time period or of the current load). Alternatively or additionally, an offset may be added to the nominal prediction such that the total heat generation over the next two days is in the upper tail of the distribution. Alternative heat generation predictions may also include modifications to cause other attributes (e.g., rate of change of heat generation, utilization, etc.) of the nominal prediction to become more extreme. In some embodiments, the alternative heat generation is selected from historical data based on a condition matching criteria (e.g., similar conditions, day of the week, etc. in the historical data and the current day). The abnormally high heat generations or other heat generations that may be particularly difficult to allocate (e.g., highest heat generation, second highest, 95^{th} percentile, most variation within the day, etc.) from days meeting the condition matching criteria may be selected.

The flow of operations 1720 may include allocating the alternative amount of heat generated by the one or more computers of the rack group into (i) a first alternative amount of heat to be rejected from the rack group into cool air provided by an air cooling system and (ii) a second alternative amount of heat to be rejected from the rack group into chilled water provided by a water cooling system in operation 1726. To ensure that reserve capacity is available with minimal switching of the cooling systems (e.g., the water cooling systems and/or the air cooling systems) that are allocated to perform the heat rejection constraints may be added such that the first alternative amount of heat to be rejected and the second alternative amount of heat to be rejected uses a number of additional air cooling systems and a number of additional water cooling systems that are less than a threshold compared to the nominal heat allocation. For example, the heat allocator 1604 may add additional constraints using the reserve capacity constraint generator 1660 as in,

$${λ}_{r , t} = {\sum }_{s ∈ S} {θ}_{sr , t} ,$$

where λ_{r,t} is the alternative (e.g., increased) heat generation from the computers under the increased utilization. Variables for alternative operating states of the cooling systems, χ_{s,t}, are also generated. The reserve capacity constraint generator 1660 may add linking constraints that link the alternative allocations for the increased load to the original allocations. For example, the reserve capacity constraint generator 1660 may limit the net number of cooling systems that can be turned on by generating the constraint,

$${\sum }_{s ∈ S} {X}_{s , t} - {𝒳}_{s , t} \leq {π}_{net , t}^{′} .$$

Additionally or alternatively, the maximum number of equipment turned on at any given time element may be constrained by introducing new variables representing a change between the original allocations and the alternative allocations:

$${δ}_{s , t}^{′} \geq {X}_{s , t} - {𝒳}_{s , t} , {δ}_{s , t}^{′} \geq 0$$

where δ′_{s,t} represents switching the system s on at time t in the alternative plan. The total number of cooling systems additionally selected to be operating in the alternative allocation may be limited using the defined switching variables in:

$${\sum }_{s ∈ S} {δ}_{s , t}^{′} \leq {π}_{+ , t}^{′} .$$

In some embodiments, the flow of operations 1720 includes operating the air cooling system to reject the first amount of heat from the rack group into the cooled air and operating the water cooling system to reject the second amount of heat from the rack group into the chilled water in operation 1728. For example, the allocation of the nominal heat generation is communicated to the local controller 1606 and used to operate the equipment and the inclusion of the alternative heat generation serves to ensure that if the computer utilization increases rapidly (resulting in an increase in heat generation) the air and/or water cooling systems could reject the additional heat with minimal disturbance to the operating systems.

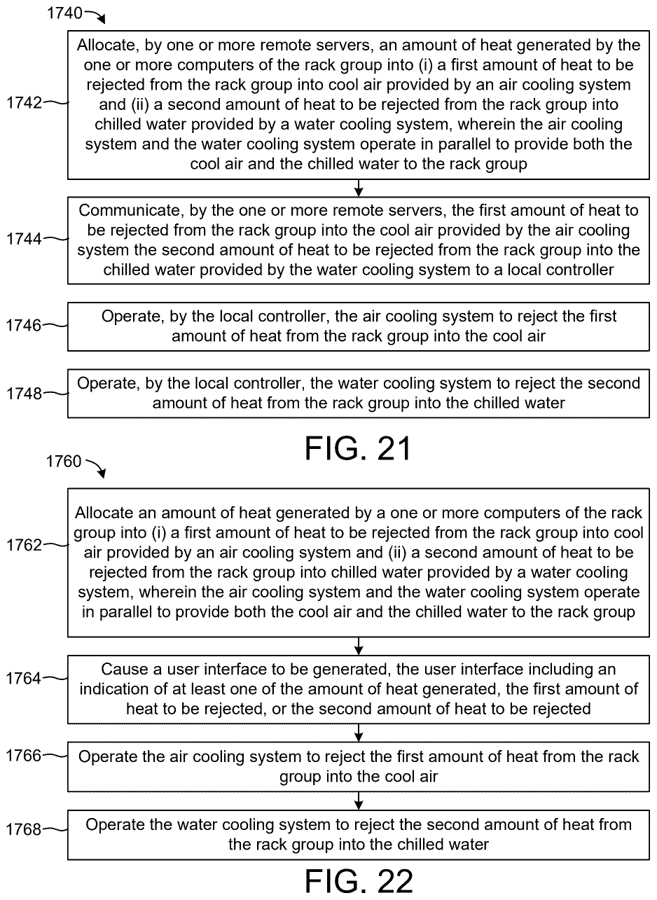

FIG. 21 shows a flow of operations 1740 for operating an air cooling system and a water cooling system according to allocations of heat generated by computers using an edge controller, according to some embodiments. The flow of operations 1740 includes allocating, by one or more remote servers, an amount of heat generated by the one or more computers of the rack group into (i) a first amount of heat to be rejected from the rack group into cool air provided by an air cooling system and (ii) a second amount of heat to be rejected from the rack group into chilled water provided by a water cooling system, wherein the air cooling system and the water cooling system operate in parallel to provide both the cool air and the chilled water to the rack group in operation 1742. For example, the heat allocator 1604 may be disposed on a remote server 1602.

In some embodiments, the flow of operations 1740 includes communicating, by the one or more remote servers, the first amount of heat to be rejected from the rack group into the cool air provided by the air cooling system and the second amount of heat to be rejected from the rack group into the chilled water provided by the water cooling system to a local controller in operation 1744. The local controller may be configured to: (i) operate the air cooling system to reject the first amount of heat from the rack group into the cool air in operation 1746 and (ii) operate the water cooling system to reject the second amount of heat from the rack group into the chilled water in operation 1748. For example, the heat allocator 1604 disposed on the remote server 1602 may communicate the allocations to respective local controllers 1606 to operate the equipment. The local controllers 1606 may include an internal control process that is configured to operate the equipment according to set points provided by the heat allocator 1604. For example, the local controller 1606 may convert a heat allocation to a supply air temperature setpoint of the CRAC. The local controller 1606 may include the control that causes the CRAC to maintain the determined supply air temperature (e.g., a PID controller or other feedback control system).

FIG. 22 shows a flow of operations 1760 for operating an air cooling system and a water cooling system according to allocations of heat generated by computers and generating a user interface indicating the allocations, according to an exemplary embodiment. The flow of operations 1760 may include allocating an amount of heat generated by one or more computers of the rack group into (i) a first amount of heat to be rejected from the rack group into cool air provided by an air cooling system and (ii) a second amount of heat to be rejected from the rack group into chilled water provided by a water cooling system, wherein the air cooling system and the water cooling system operate in parallel to provide both the cool air and the chilled water to the rack group in operation 1762. Operation 1762 may be substantially similar to operation 1702.

In some embodiments, the flow of operations 1760 includes causing a user interface to be generated, the user interface including an indication of at least one of the amount of heat generated, the first amount of heat to be rejected, or the second amount of heat to be rejected in operation 1764. For example, the interface generator 1628 may provide instructions (e.g. JavaScript, Cascading Style Sheets) to the client device 1612 that instruct the client device 1612 how to generate the user interface within a client application (e.g., an internet browser, a proprietary application, etc.). The user interface may be used to display the amount of heat generated by the various computers of the data center and/or the allocations to the various air or water cooling systems. For example, the interface generator 1628 may generate a floor plan of the data center as shown in FIG. 13. Color overlays may be used to indicate computer and/or rack temperature. Additionally or alternatively, color overlays may be used to indicate heat generation. In some embodiments, the heat allocator 1604 provides the interface generator with predictions of the heat generation and the user can view future expected performance (e.g., heat generation, temperatures, utilization, etc.) of the data center in the future. In addition to the heat generation, the allocations of the heat generation to the water cooling systems 1502 and or the air cooling systems 1402 may be included on the user interface. The allocation may be shown in total (e.g., the total amount of heat rejected by each of the cooling systems) and/or an indication of the connections between computer rack and cooling system may be included on the user interface and individual allocations may be shown as associated with the connection. The estimated cost of cooling the computers of the data center may be calculated from the optimal objective functions and added to the user interface. The estimated cost may be calculated at the data center (e.g., whole facility) level, for each rack, for each cooling system, for each computer, or at any combination of granularities.

The flow of operations 1760 may include operating the air cooling systems 1402 to reject the first amount of heat from the rack group into the cool air in operation 1704 in operation 1766 and operating the water cooling system to reject the second amount of heat from the rack group into the chilled water in operation 1768. Operating the air cooling system 1402 and water cooling system 1502 to reject the heat generation may include communicating the allocations to the local controller 1606. In some embodiments, the local controller 1606 has an internal control process that is configured to operate the equipment according to set points provided by the heat allocator 1604. For example, the local controller 1606 may convert a heat allocation to a supply air temperature setpoint of the CRAC. The local controller 1606 may include the control that causes the CRAC to maintain the determined supply air temperature. In some embodiments, the heat allocator 1604 determines the temperature setpoints and communicates them to the respective local controller 1606. In some embodiments, the heat allocator 1604 directly determines the necessary fan speed and communicates the fan speed to the local controller.

In some embodiments, allocations are found (e.g., determined, optimized, etc.) for a first time period of a longer planning time period. For example, using the flow of operations 1700 or any other systems and/or methods described herein. The time period may be shifted forward an amount of time to determine allocations for a second time period (e.g., within the greater planning period) and performed again. For example, repeated iterations of the determining allocations may be performed within the planning tool 902. With each iteration of the optimization process, planning tool 902 selects an optimization period (i.e., a portion of the planning period) over which the optimization is performed. For example, planning tool 902 may select the first time period for the first iteration. Once the optimal allocation (e.g., of heat generation and/or compute tasks) has been determined, the planning tool 902 may store a portion allocation (e.g., as part of the final plan). The portion may be the first b time steps of allocation. The planning tool 902 may shift the time period forward in time, resulting in the second optimization period. The amount by which the prediction window is shifted may correspond to the duration of time steps b. Planning tool 902 may repeat the optimization process for entire planning period to determine the optimal allocations. Once the allocations are stored for the entire simulation period, the results may be sent to reporting applications 930 (e.g., a user interface or display), results database 928, and/or client device 922, as described with reference to FIG. 9.

Although the systems and methods of the present disclosure are primarily described as allocating cooling loads across a water cooling system and an air cooling system, it is contemplated that any number and/or type of cooling systems could be used. The cooling systems can use any type of coolants (e.g., water, glycol, air, CO2, refrigerant, any liquid coolant, any gas coolant, any fluid coolant, etc.). For example, the systems and methods described herein can allocate cooling loads across two or more liquid coolants having different temperatures (e.g., high-temperature liquid coolant and low-temperature liquid coolant) supplied by one or more liquid cooling systems at different temperatures and/or two or more liquid coolants of different types (e.g., water, glycol, CO2, etc.). Similarly, the systems and methods described herein can allocate cooling loads across two or more gas coolants having different temperatures (e.g., high-temperature air or vapor and low-temperature air or vapor) supplied by one or more gas cooling systems at different temperatures and/or two or more gas coolants of different types (e.g., air, refrigerant vapor, etc.). It is contemplated that any number of fluid coolants (e.g., liquid coolants, gas coolants, vapor coolants, etc.) of any number of types can be used without departing from the teachings of the present disclosure.

### Configuration of Exemplary Embodiments

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

The present disclosure contemplates methods, systems and program products on memory or other machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products or memory comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

As used herein, the term “circuit” may include hardware structured to execute the functions described herein. In some embodiments, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some embodiments, a circuit may take the form of one or more analog circuits, electronic circuits (e.g., integrated circuits (IC), discrete circuits, system on a chip (SOCs) circuits, etc.), telecommunication circuits, hybrid circuits, and any other type of “circuit.” In this regard, the “circuit” may include any type of component for accomplishing or facilitating achievement of the operations described herein. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on).

The “circuit” may also include one or more processors communicably coupled to one or more memory or memory devices. In this regard, the one or more processors may execute instructions stored in the memory or may execute instructions otherwise accessible to the one or more processors. In some embodiments, the one or more processors may be embodied in various ways. The one or more processors may be constructed in a manner sufficient to perform at least the operations described herein. In some embodiments, the one or more processors may be shared by multiple circuits (e.g., circuit A and circuit B may comprise or otherwise share the same processor which, in some example embodiments, may execute instructions stored, or otherwise accessed, via different areas of memory). Alternatively or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. Each processor may be implemented as one or more general-purpose processors, application specific integrated circuits (ASICs), field programmable gate arrays (FPGAs), digital signal processors (DSPs), or other suitable electronic data processing components structured to execute instructions provided by memory. The one or more processors may take the form of a single core processor, multi-core processor (e.g., a dual core processor, triple core processor, quad core processor, etc.), microprocessor, etc. In some embodiments, the one or more processors may be external to the apparatus, for example the one or more processors may be a remote processor (e.g., a cloud based processor). Alternatively or additionally, the one or more processors may be internal and/or local to the apparatus. In this regard, a given circuit or components thereof may be disposed locally (e.g., as part of a local server, a local computing system, etc.) or remotely (e.g., as part of a remote server such as a cloud based server). To that end, a “circuit” as described herein may include components that are distributed across one or more locations. The present disclosure contemplates methods, systems and program products on any machine-readable media for accomplishing various operations. The embodiments of the present disclosure can be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures may show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

What is claimed is:

1. A controller configured to serve a cooling load of a data center facility comprising one or more computers in a rack group of one or more computer racks, the controller comprising one or more processing circuits configured to:
allocate an amount of predicted heat generation by the one or more computers of the rack group into (i) a first amount of heat to be rejected from the rack group into a first coolant provided by a first cooling system and (ii) a second amount of heat to be rejected from the rack group into a second coolant provided by a second cooling system, wherein the first cooling system and the second cooling system operate in parallel to provide both the first coolant and the second coolant to the rack group, wherein the predicted heat generation is based upon types of the one or more computers;
operate the first cooling system to reject the first amount of heat from the rack group into the first coolant; and
operate the second cooling system to reject the second amount of heat from the rack group into the second coolant.

2. The controller of claim 1, wherein:
the second cooling system comprises a chiller;
the first cooling system comprises at least one of a computer room air conditioner or a computer room air handler; and
the chiller is configured to provide cooling to the rack group and to the first cooling system.

3. The controller of claim 1, the one or more processing circuits further configured to:
obtain a load balance constraint that requires balance between (i) a heat production comprising the amount of heat generated by the one or more computers of the rack group and (ii) a heat rejection comprising the first amount of heat to be rejected from the rack group into the first coolant provided by the first cooling system and the second amount of heat to be rejected from the rack group into the second coolant provided by the second cooling system; and
allocate the amount of heat generated into the first amount of heat to be rejected and the second amount of heat to be rejected using the load balance constraint.

4. The controller of claim 3, wherein the first cooling system is of a plurality of first cooling systems, the second cooling system is of a plurality of second cooling systems, the rack group is of a plurality of rack groups,
wherein the one or more processing circuits are further configured to:
obtain a first indication of interconnections between the plurality of first cooling systems and the plurality of rack groups;
obtain a second indication of interconnections between the plurality of second cooling systems and the plurality of rack groups;
generate a plurality of load balance constraints that require for each connected rack group of the plurality of rack groups balance between (i) a respective heat production comprising an amount of heat generated by one or more computers of the connected rack group and (ii) a respective heat rejection comprising a first respective amount of heat to be rejected from the connected rack group into the first coolant provided by connected first cooling systems of the plurality of first cooling systems rack group and a second respective amount of heat rejected from the connected rack group into the second coolant provided by connected second cooling systems of the plurality of second cooling systems; and
allocate the amount of heat generated by the one or more computers of each of the connected rack group into the first respective amount of heat to be rejected and the second respective amount of heat to be rejected using the plurality of load balance constraints.

5. The controller of claim 1, wherein the amount of heat generated, the first amount of heat to be rejected, and the second amount of heat to be rejected are specific to a time instance and the controller is configured to determine values of the amount of heat generated, the first amount of heat to be rejected, and the second amount of heat to be rejected at a plurality of future time instances.

6. The controller of claim 5, wherein the amount of heat generated at the plurality of future time instances is determined using a computer utilization ratio of the rack group and a model trained with training data comprising training samples comprising a total cooling load of the second cooling system and the first cooling system and computer utilization ratios of a plurality of rack groups including the rack group.

7. The controller of claim 1, the one or more processing circuits further configured to:
generate a reserve capacity constraint that requires an amount of heat rejection capability be available;
generate a timer constraint that requires at least one of:
a currently operating equipment of the second cooling system or the first cooling system remain operating for a first period of time; or
an equipment currently not operating of the second cooling system or the first cooling system remain not operating for a second period of time;
generate a switching constraint that, for an equipment of the second cooling system or the first cooling system, requires at least one of:
the equipment of the second cooling system or the first cooling system transitions from operating to not operating a first number of times less than a switching threshold during a third time period; or
the equipment of the second cooling system or the first cooling system transitions from not operating to operating a second number of times less than the switching threshold during the third time period; and
allocate the amount of heat generated into the first amount of heat to be rejected and the second amount of heat to be rejected using the reserve capacity constraint, the timer constraint, and the switching constraint.

8. A method to serve a cooling load of a data center facility comprising one or more computers in a rack group of one or more computer racks, the method comprising:
allocating, by one or more processors, a first amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system, wherein:
the first cooling system and the second cooling system operate in parallel to provide both the first coolant and the second coolant to the rack group,
the first amount of heat to be rejected and the second amount of heat to be rejected satisfy one or more constraints comprising a second amount of heat generated by central processing units of the one or more computers and a third amount of heat generated by graphics processing units of the one or more computers, and
the first amount of heat generated comprises the second amount of heat generated and the third amount of heat generated; and
communicating, by the one or more processors, the first amount of heat to be rejected from the rack group into the first coolant provided by the first cooling system the second amount of heat to be rejected from the rack group into the second coolant provided by the second cooling system to a local controller configured to:
operate the first cooling system to reject the first amount of heat from the rack group into the first coolant; and
operate the second cooling system to reject the second amount of heat from the rack group into the second coolant.

9. The method of claim 8, wherein the one or more constraints comprise a cooling constraint that requires at least one of:
the second amount of heat to be rejected into the second coolant be greater than or equal to the third amount of heat generated by the graphics processing units; or
the second amount of heat to be rejected into the second coolant be equal to the third amount of heat generated by the graphics processing units.

10. The method of claim 8, wherein the one or more constraints comprise:
a first load balance constraint that requires balance between (i) the second amount of heat generated by the central processing units and (ii) a third amount of heat to be rejected from the rack group into the second coolant provided by the second cooling system at a first temperature, wherein second amount of heat to be rejected comprises the third amount of heat to be rejected; and
a second load balance constraint that requires balance between (i) the third amount of heat generated by the graphics processing units and (ii) a fourth amount of heat to be rejected from the rack group into the second coolant provided by the second cooling system at a second temperature, wherein second amount of heat to be rejected also comprises the fourth amount of heat to be rejected.

11. The method of claim 8, wherein allocating the first amount of heat generated into the first amount of heat to be rejected and the second amount of heat to be rejected comprises determining a solution to an optimization problem subjected to the one or more constraints.

12. The method of claim 8, further comprising:
determining, by the one or more processors, a first allocation of inbound compute tasks to the central processing units and a second allocation of the inbound compute tasks to the graphics processing units; and
allocating, by the one or more processors, the inbound compute tasks to the central processing units and the graphics processing units according to the first allocation and the second allocation.

13. The method of claim 12, wherein the one or more constraints comprise the second amount of heat generated by the central processing units based at least on the second allocation and the third amount of heat generated by the graphics processing units based at least on the second allocation.

14. The method of claim 8, wherein the second cooling system comprises a chiller and the first cooling system comprises at least one of:
a computer room air conditioner; or
a computer room air handler.

15. A method to serve a cooling load of a data center facility comprising one or more computers in a rack group of one or more computer racks, the method comprising:
allocating, by one or more processors, a first amount of heat generated by the one or more computers of the rack group into (i) a first amount of heat to be rejected from the rack group into a first coolant provided by a first cooling system and (ii) a second amount of heat to be rejected from the rack group into a second coolant provided by a second cooling system, wherein the first cooling system and the second cooling system operate in parallel to provide both the first coolant and the second coolant to the rack group;
causing, by the one or more processors, a user interface to be generated, the user interface comprising an indication of a second amount of heat generated by central processing units and a third amount of heat generated by graphics processing units, wherein the first amount of heat generated comprises the second amount of heat generated and the third amount of heat generated;
operating, by the one or more processors, the first cooling system to reject the first amount of heat from the rack group into the first coolant; and
operating, by the one or more processors, the second cooling system to reject the second amount of heat from the rack group into the second coolant.

16. The method of claim 15, wherein the first amount of heat rejected and the second amount of heat rejected satisfy one or more constraints comprising the second amount of heat generated and the third amount of heat generated by the graphics processing units of the one or more computers.

17. The method of claim 16, further comprising:
determining, by the one or more processors, a first allocation of inbound compute tasks to the central processing units and a second allocation of the inbound compute tasks to the graphics processing units; and
allocating, by the one or more processors, the inbound compute task to the central processing units and the graphics processing units according to the first allocation and the second allocation,
wherein the one or more constraints comprise the heat generated by the central processing units based at least upon the second allocation and the heat generated by the graphics processing units based at least on the second allocation.

18. The method of claim 16, wherein allocating the first amount of heat generated into the first amount of heat to be rejected and the second amount of heat to be rejected comprises determining a solution to an optimization problem subjected to the one or more constraints.

19. The method of claim 18, wherein the first amount of heat generated is predicted over a plurality of future time periods and the method further comprises:
generating, by the one or more processors, an objective function for the optimization problem comprising resources used for supplying the second coolant and the first coolant to reject the first amount of heat rejected and the second amount of heat rejected over a subset of the plurality of future time periods; and
repeatedly determining, by the one or more processors, a solution to the optimization problem for the subset of the plurality of future time periods to determine an allocation for the plurality of time periods.

20. The method of claim 19, wherein the objective function comprises at least one of:
a first amount of electrical energy consumed by the first cooling system and a second amount of electrical energy consumed by the second cooling system;
a first amount of water consumed by the first cooling system and a second amount of water consumed by the second cooling system; or
a first amount of greenhouse gas emissions caused by operating the first cooling system and second amount of greenhouse gas emissions caused by operating the second cooling system.
